(19) United States
(12) Patent Application Publication
(10) Pub. No.: US 2024/0322529 A1
(43) Pub. Date: Sep. 26, 2024

(54) SPATIAL AND TEMPORAL ADJUSTMENT OF LASER DEVICE DRIVE CURRENT USING ASIC DRIVES

(71) Applicant: Freedom Photonics LLC, Goleta, CA (US)

(72) Inventors: Michelle Helena Labrecque, Goleta, CA (US); Jenna Nicole Campbell, Santa Barbara, CA (US); Paul Orville Leisher, Livermore, CA (US); Jason Matthew Eichenholz, Orlando, FL (US); Lawrence Shah, Winter Park, FL (US)

(21) Appl. No.: 18/612,981

(22) Filed: Mar. 21, 2024

Related U.S. Application Data
(60) Provisional application No. 63/491,728, filed on Mar. 22, 2023.

(51) Int. Cl. H01S 5/50; H01S 5/026; H01S 5/042; H01S 5/068; H01S 5/10

(52) U.S. Cl. CPC H01S 5/50; H01S 5/026; H01S 5/04254; H01S 5/04256; H01S 5/06808; H01S 5/06821; H01S 5/1014; H01S 3/2308; H01S 5/024; H01S 5/0427

(57) ABSTRACT

Various semiconductor laser and optical amplifier designs and drive current control methods are disclosed that enable spatial and temporal control of a distribution of the injection current in an active optical waveguide of the laser or the optical amplifier. Such configurations can be used to improve the performance the laser or the optical amplifier and the quality of an optical beam output by the laser or the optical amplifier. The electrodes of the laser or the optical amplifier may be segmented to provide controlled drive current distribution in an optical gain layer of the laser or the optical amplifier.

### INCORPORATION BY REFERENCE TO ANY PRIORITY APPLICATIONS

This application claims the benefit of priority of U.S. Provisional Application No. 63/491,728 titled “SPATIAL AND TEMPORAL ADJUSTMENT OF LASER DEVICE DRIVE CURRENT USING ASIC DRIVES” (Docket No. FREDOM.037PR), which was filed on Mar. 22, 2023, the entire disclosure of which is expressly incorporated herein by reference.

### BACKGROUND

### Field of the Invention

Various embodiments of this application relate to the field of semiconductor lasers and optical amplifiers and more particularly semiconductor optical amplifiers integrated with the lasers.

### Description of the Related Art

Semiconductor lasers and optical amplifiers are widely used in telecommunications, sensing, test and measurement, pumping other lasers, light detection and ranging (LIDAR), as well as other applications. Some such applications may benefit from lasers and optical amplifiers having high efficiency, high stability, high output power, and high beam quality. Although it may be advantageous to increase the efficiency, stability, output power, or beam quality of lasers and optical amplifiers, it may also be beneficial to increase two or three of these together.

### SUMMARY

Example embodiments described herein have several features, no single one of which is indispensable or solely responsible for their desirable attributes. A variety of example systems and methods are provided below.

Various embodiments in this application relate to independently controlling drive currents provided to different regions of an optical gain layer in an optical device, to improve a performance of the optical device or a quality of a light beam output by the optical device. An application-specific integrated circuit (ASIC) provides drive signals to electrically isolated electrode segments of a segmented electrode of the optical device to control spatial and temporal distribution of drive current, and thereby spatial and temporal distribution of optical gain in the optical gain layer.

In one aspects, an optical system includes: an optical device configured to provide optical gain, the optical device including: an active optical waveguide extending in a longitudinal direction between a first end and a second end, wherein said active waveguide includes a semiconductor optical gain layer configured to provide optical gain to light propagating within said active optical waveguide, said active optical waveguide having a waveguide length along the longitudinal direction and a waveguide width along a lateral direction perpendicular to the longitudinal direction; and a segmented electrode disposed with respect to the active optical waveguide said electrode including a plurality of separate electrically isolated electrode segments configured to provide individual drive currents to corresponding regions of the semiconductor optical gain layer; and an electronic control system configured to provide a plurality of individually controlled drive signals to different electrode segments to generate a controlled distribution of drive currents in the semiconductor optical gain layer, and controlling a magnitude of a first drive signal provided to a first electrode segment to be above a first threshold level during a first period and a magnitude of a second drive signal provided to a second electrode segment to be above a second threshold level during a second period after the first period.

In another aspects, a method of providing drive signals to an optical device configured to provide optical gain, the optical device including an active optical waveguide and a segmented electrode disposed with respect to the active optical waveguide, said segmented electrode including a plurality of separate electrically isolated electrode segments; the method including: by a processor of an electronic system: providing a plurality of individually controlled drive signals to different electrode segments to generate a controlled distribution of drive currents in a semiconductor optical gain layer of the active optical waveguide, and controlling a magnitude of a first drive signal provided to a first electrode segment to be above a first threshold level during a first period and a magnitude of a second drive signal provided to a second electrode segment to be above a second threshold level during a second period after the first period.

### BRIEF DESCRIPTION OF THE DRAWINGS

In the following description of the various embodiments, reference is made to the accompanying drawings which form a part hereof, and in which is shown by way of illustration various embodiments of the device. It is to be understood that other embodiments may be utilized and structural changes may be made.

FIG. 1A illustrates a top cross-sectional view of an example semiconductor laser (or optical amplifier).

FIG. 1B illustrates a top view of the semiconductor laser (or optical amplifier) shown in FIG. 1A.

FIG. 2A illustrates side cross-sectional view of an example semiconductor laser (or optical amplifier) shown in FIG. 1A depicting different layers of the semiconductor laser (or optical amplifier).

FIG. 2B illustrates side cross-sectional view of another example of a semiconductor laser (or optical amplifier) shown in FIG. 1A depicting different layers of the semiconductor laser (or optical amplifier).

FIG. 3A illustrates a side-view cross-section of the active waveguide and the distribution of current density along the length of the active waveguide for a semiconductor laser similar to the semiconductor laser shown in FIG. 1A.

FIG. 3B illustrates a top view of an example of a longitudinally segmented top electrode having rectangular segments (e.g., equally spaced segments) disposed on a semiconductor laser or optical amplifier.

FIG. 3C illustrates a top view of another example of longitudinally segmented top electrode having segments (e.g., equally spaced segments) with triangular (e.g., saw tooth) shape lateral edges, disposed on a semiconductor laser or optical amplifier.

FIG. 4A illustrates top views of examples of laterally segmented longitudinal electrode segments disposed on a semiconductor laser or optical amplifier.

FIG. 4B illustrates a top view of an example of longitudinally and laterally segmented top electrode with segments having rectangular shape lateral and longitudinal segments, disposed on a semiconductor laser or optical amplifier.

FIG. 4C illustrates a top view of another example of longitudinally and laterally segmented top electrode including segments with triangular (e.g., sawtooth) shape lateral edges, disposed on a semiconductor laser or optical amplifier.

FIG. 5 illustrates a three-dimensional view of a semiconductor optical amplifier or a broad area semiconductor laser having a segmented top electrode mounted on a submount that supports controlling the current provided to individual segments or different groups of segments.

FIG. 6A illustrates a top view of an example of a longitudinally segmented top electrode disposed on a flared semiconductor laser or optical amplifier.

FIG. 6B illustrates a top view of an example of a longitudinally segmented top electrode having longitudinal segments with protrusions on the lateral edges, e.g., triangular shape lateral edges, disposed on a flared semiconductor laser or optical amplifier.

FIG. 7A illustrates a top view of an example of longitudinally and laterally segmented top electrode disposed on a flared semiconductor laser or optical amplifier.

FIG. 7B illustrates a top view of an example of longitudinally and laterally segmented top electrode having longitudinal segments with protrusions on the lateral edges, e.g., triangular shape lateral edges, disposed on flared semiconductor laser or optical amplifier.

FIG. 8 illustrates top view diagrams of four MOPA devices, having different combinations of flared and rectangular laser and amplifier sections, which may be pumped using a segmented electrode fed by individually controlled drive signals.

FIG. 9 illustrates additional lasers, optical amplifiers, and MOPA designs that may be pumped using a segmented electrode fed by individually controlled drive signals.

FIG. 10A is a schematic diagram illustrating an optical device configured as a master oscillator power amplifier (MOPA). The left panel illustrates a top view of the MOPA. The right panel illustrates two vertical cross-sections of the MOPA shown in the left panel.

FIGS. 10B-10C are schematic diagrams illustrating MOPAs having a segmented electrode controlled by an Application Specific Integrated Circuit (ASIC). (B) A MOPA with a flared optical amplifier having two electrically isolated electrode segments configured to independently control the oscillator and the optical amplifier sections. (C) A MOPA with a flared optical amplifier having a plurality of electrically isolated longitudinal electrode segments configured to independently control the oscillator, and five longitudinal subsections of the optical amplifier section.

FIG. 10D is a schematic diagram illustrating a MOPA with a flared optical amplifier having a laterally and longitudinally segmented electrode configured to provide independent drive currents to different regions of the flared optical amplifier.

FIG. 11A is a schematic diagram illustrating example pulse shapes that may be supplied by an ASIC to one or more segments of a segmented electrode (e.g., segmented electrodes shown in FIG. 3B-3C, 4B-4C, 5, 6A-6B, 7A-7B, 10B-C, or 10D) disposed on an optical device.

FIG. 11B is a schematic diagram illustrating example drive currents that may be supplied by an ASIC to five different segments of a segmented electrode (e.g., segmented electrodes shown in FIG. 3B-3C, 4B-4C, 5, 6A-6B, 7A-7B, 10A-C, or 10D), and a resulting optical pulse output by the corresponding optical device.

FIG. 12 is a schematic diagram illustrating an example optical system including an optical device and an ASIC that provides controlled or adjusted drive currents to electrode segments of the optical device.

FIG. 13 is a schematic diagram illustrating an example segmented electrode configuration for controlling and/or adjusting drive current distribution in optical gain layer of an optical device.

### DETAILED DESCRIPTION

Although certain preferred embodiments and examples are disclosed below, inventive subject matter extends beyond the specifically disclosed embodiments to other alternative embodiments and/or uses and to modifications and equivalents thereof. Thus, the scope of the claims appended hereto is not limited by any of the particular embodiments described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain embodiments; however, the order of description should not be construed to imply that these operations are order dependent. Additionally, the structures, systems, and/or devices described herein may be embodied using a variety of techniques including techniques that may not be described herein but are known to a person having ordinary skill in the art. For purposes of comparing various embodiments, certain aspects and advantages of these embodiments are described. Not necessarily all such aspects or advantages are achieved by any particular embodiment. Thus, for example, various embodiments may be carried out in a manner that achieves or optimizes one advantage or group of advantages as taught herein without necessarily achieving other aspects or advantages as may also be taught or suggested herein. It will be understood that when an element or component is referred to herein as being “connected” or “coupled” to another element, it can be directly connected or coupled to the other element or intervening elements may be present therebetween. For clarity of description, “reflector” or “mirror” can be used interchangeably to refer to an optical element and/or a surface having a reflectivity greater than or equal to about 5% and less than or equal to 100%. For example, an optical element and/or a surface having a reflectivity greater than or equal to about 5% and less than or equal to 99%, greater than or equal to about 10% and less than or equal to 90%, greater than or equal to about 15% and less than or equal to 80%, greater than or equal to about 20% and less than or equal to 70%, greater than or equal to about 30% and less than or equal to 60%, or any value in any range/sub-range defined by these values can be considered as a reflector or mirror. It will be understood that “light having single wavelength”, “light beam having single wavelength”, “laser light having single wavelength”, “single wavelength light” or “single wavelength laser light”, can be light comprising wavelengths within a continuous wavelength or frequency band (e.g., a narrowband) centered at a center wavelength (or center frequency).

A semiconductor optical device can be a semiconductor optical device that generates and/or amplifies light propagating in an optical waveguide (a semiconductor waveguide) using one or more pumped semiconductor optical gain layers within the optical waveguide. An optical gain layer can be pumped, e.g., by electric drive currents (also referred to as injection currents) provided to the optical gain layer. A semiconductor optical device may comprise one or both of a semiconductor laser (e.g., an edge-emitting diode laser) and a semiconductor optical amplifier (SOI).

Master Oscillator Power Amplifier (MOPA) is an integrated optical device comprising an optical oscillator (laser) optically connected to an optical amplifier. A MOPA may provide power scalability by amplifying the power of light generated by the oscillator using the optical amplifier section. In some cases, the optical amplifier may preserve the spectral and/or spatial properties of a light beam received from the laser while amplifying its optical power or energy. In some examples, a MOPA can be a semiconductor MOPA comprising a semiconductor laser and a semiconductor optical amplifier.

In some cases, temporal and/or spatial distributions of optical gain, optical power, temperature, and carrier properties (e.g., density and lifetime), in a pumped region of an optical gain layer of a semiconductor laser (a diode laser) and/or a semiconductor optical amplifier, are considered to be uniform (e.g., to simplify for mathematical modeling of an optical device). However in practice, one or more of these parameters may be distributed nonuniformly in temporal and/or spatial domain. In some cases, a nonuniform spatial distribution may comprise nonuniformities long both a longitudinal direction (direction of propagation of light) and a lateral direction (perpendicular to the longitudinal direction and parallel to corresponding optical waveguide). In some cases, distribution of carrier properties may comprise a distribution of carrier density in a gain structure (e.g., a quantum well) and/or carrier life time, and distribution of optical power may comprise distribution of photon density. In some cases, optical gain, optical power, temperature, carrier properties, and possibly other parameters associated with the optical gain layer, are interdependent and interact with each other in a complex and time dependent manner, e.g., in the presence of heating or with changing atmospheric conditions. In lasers and optical amplifiers, having longer cavities or waveguides, and those that generate and/or amplify higher levels of optical power, the non-uniformities described above can be more significant and may result in effects such as filamentation and thermal lensing within the optical waveguide. The non-uniformities and the corresponding effects can reduce any one or more of the efficiency, output power, and stability of the optical device, and/or may increase heat generation in the optical device.

In some cases, the non-uniformities and the corresponding effects may degrade the quality of output light beam generated or amplified by the optical device. For example, they can cause optical aberrations in the output light beam, reduce the beam quality, e.g., in the slow axis direction, reduce the efficiency optical power delivery to a target in the far-field or any combinations thereof. High-power MOPAs can be susceptible to the non-uniformities described above due to their higher power, longer cavity lengths, or wider optical mode widths close to the output port (output facet) of the optical amplifier section or any combination of these factors.

In some aspects, the device designs, and methods described herein may be used to stabilize one or more parameters of a semiconductor laser, optical amplifier, or MOPA and/or maintain a high beam quality, e.g., during optical amplification. In some cases, the beam quality may be quantified using various metrics such as beam propagation factor (M²) or power in the bucket (PIB). In some cases, beam stability may include maintaining beam quality through an operating period of the optical device and/or under different environmental and/or drive conditions. M² is a unitless parameter with values greater than or equal to 1 with higher beam quality corresponding to lower M² where a perfectly diffraction-limited beam having an M² of 1. In some examples, M² of a light beam output by the optical devices described here can be less than 5, less than 4, less than 3, less than 2, or any other value from 1 to 5. PIB can be defined as the percentage or ratio of optical power in a specified area (e.g., user specified area) of a light beam, with values less than or equal to 100%, where a higher beam quality corresponding to a larger PIB. In some examples, the PIB of a light beam output by the optical devices described here can be larger than 70%, larger than 80%, larger than 90%, or larger than any other value from 70% to 95%.

In some embodiments, different non-uniformities and/or the resulting adverse effects may be mitigated by spatially and/or temporally engineering and/or controlling a drive current provided to an optical gain layer of the laser, optical amplifier, or MOPA. For example, longitudinal segmentation of an electrode (e.g., a thick conductive layer) on the p-side of the laser cavity can enable tailoring and/or controlling a current density profile or a drive current profile in the corresponding optical gain layer such that a higher drive current or current density is provided to a region of the laser cavity or the optical amplifier having an electrical-to-optical (EO) efficiency (optical amplification efficiency) larger than that of the other regions. In some cases, a spatially tailored or controlled drive current distribution may comprise a drive current distribution proportional to electrical-to-optical (EO) efficiency within an optical gain layer.

In some of the device designs, and methods described herein the distribution of drive current in the optical gain layer of a laser, an optical amplifier, or MOPA may be controlled by an application specific integrated circuit (ASIC). In some cases, the ASIC may be integrated with the optical device in a common enclosure. In various implementations, using an ASIC may remove certain constraints on a power supply that provides the electric power to the optical device. In some cases, using ASIC may automatically provide and adjust multiple drive currents (e.g., time varying drive currents) to different electrode segments of an optical device and thereby eliminate the need for a user to have bias a multi-channel current source, which could be very complex and may require advance knowledge. Advantageously, an ASIC could be positioned very close to the corresponding electrode (e.g., a segmented electrode) of the optical device to reduce parasitic inductances, capacitances associated with long conductive lines (e.g., used to connect the ASIC to the electrode) and thereby enable higher frequency operation.

An electronic control system (e.g., an ASIC) may control a spatial distribution and/or temporal variation of a plurality of drive currents provided to optical gain layer of an optical device (e.g., a laser, an optical amplifier, or a MOPA), to improve a performance of the optical device, e.g., by increasing optical output power, optical power stability, phase stability, output light beam stability or any combination thereof, and/or improving the output beam quality of the optical device, thereby benefiting any one or more of the above-mentioned applications. In some cases, the electronic control system may control the drive current in a manner so as to reduce, and/or control astigmatism of the output light beam.

In some cases, the semiconductor sources (e.g., diode lasers and amplifiers) described here can directly generate high quality (e.g., diffraction limited light beam) and high power laser beams eliminating the need for a brightness-converter (such as a fiber, or a solid-state laser pumped by the semiconductor source).

In some other cases, an optical device driven by spatially tailored and/or temporally controlled drive currents over its gain layer, may be used to optically pump lasers and amplifiers that can generate diffraction limited light beams. In some cases, such optical device can generate a light beam having a larger overlap with a fundamental mode of a fiber-optic or a solid-state laser that is being pumped, compared to a light beam generated by another optical device that does not benefit from spatially tailored and/or temporally controlled distribution of drive currents. In some cases, these improved optical devices may reduce the number of optical devices used for pumping a fiber laser or a solid-state laser, without reducing an output power or degrading a performance of the pumped laser. Reducing a number of optical devices used to optically pump a high-power laser can facilitate thermal management of the high power laser.

The optical devices disclosed here, and/or the laser and optical amplifiers pumped by these optical devices, may be used in applications like directed energy, time-of-flight and FMCW LiDAR, power beaming, free space optical communications, industrial applications, and medical applications among other applications.

In some implementations, spatial and/or temporal control of drive current distribution in optical gain layer of an optical device may be used to: steer the output light beam, tune the beam parameter of the output light beam, generate optical patterns or any combination of these, which could be useful in variety of applications including but limited to those mentioned above.

In most lasers and amplifiers, the distribution of light intensity and the corresponding photon density along the amplifier between an input port and an output port, and along the laser cavity between a front reflector and a back reflector, is nonuniform. In some cases, this nonuniform distribution of light intensity is a result of a difference between the reflectivity of the front reflector (e.g., front mirror) and the back reflector (e.g., back mirror) of the laser cavity. For example, the front reflector may have lower reflectivity to allow a portion of laser light recirculating inside the cavity to be transmitted outside of the cavity. In some cases, the nonuniform distribution of light intensity is a result of light amplification along the amplifier from the input port (e.g., rear facet) to the output port (front facet).

Similar to other lasers, semiconductor lasers may have an asymmetric design (e.g., asymmetric optical design), where the reflectivity of a front reflector is low and the reflectivity of a back reflector is high. In some cases, the semiconductor laser, may be an edge emitting laser such a Fabry-Perot laser, a Distributed Feed Back (DFB) Laser, a Distributed Bragg Grating (DBR) laser, or other types of semiconductor laser.

Optically or electrically pumping the optical gain medium (e.g., a gain layer of an active waveguide) of an optically asymmetric semiconductor laser may result in a nonuniform distribution of optical intensity (or photon density), carrier density, and gain along the length of the device between the front and back reflectors. In some cases, the optical intensity may be larger closer to the front reflector of the semiconductor laser. In some cases, the optical intensity may be larger closer to the output port of a semiconductor amplifier.

In some cases, in the regions of the gain medium where the light intensity is larger, the effective carrier lifetime can be much lower due to increased stimulated emission. For example, when the gain layer of semiconductor laser or optical amplifier is activated or pumped (e.g., by providing an electric current to the gain layer), the carrier lifetime near the output port or front reflector of the laser may be reduced. In some cases, where a uniform voltage is applied along the length of the optical amplifier or laser cavity (e.g., along a longitudinal direction extending between the front and back reflectors or between input and output ports), the local reduction of carrier lifetime may result in nonuniformity of the distribution of injection current density (e.g., injected electrical current density across the gain layer), along the optical amplifier or the laser cavity. In some cases, a nonuniform distribution of longitudinal injection current density along the optical amplifier and the laser cavity may comprise accumulation of current near a region where the optical intensity is large in the gain layer. This effect that is sometimes referred to as “longitudinal current crowding effect” may limit the efficiency of a semiconductor laser or optical amplifier and/or the optical output power generated by the semiconductor laser or optical amplifier. In some cases, the longitudinal current crowding effect may reduce the quality of the laser or light beam output by the semiconductor laser or optical amplifier.

In some cases, for example, when a length of the laser cavity or the optical amplifier is long and/or an average magnitude of the injection current density along the laser cavity or the amplifier is large, the excessive asymmetry of photon density, carrier density, and gain along the laser cavity or the optical amplifier may result in current crowding near the front reflector of the semiconductor laser. In some cases, when the laser cavity is long (e.g., in long cavity laser chips), the current crowding near or in a cavity region closer to the front reflector may reduce the current density in a cavity region closer to the rear portion of the laser (near or closer to the back reflector) and result in reduction of optical gain in the rear portion of the semiconductor laser. As such, longitudinal current crowding in a laser may limit the scaling of the laser cavity length while maintaining a certain level of efficiency (e.g., slope efficiency). Similarly, when an optical amplifier is long, the current crowding in a waveguide region closer to the output port may reduce the current density in a waveguide region closer to the output port (rear portion) and result in reduction of optical gain in the rear portion of the optical amplifier. Hence, the amount of optical output power that may be extracted from a gain layer (e.g., of a laser or an optical amplifier) with a certain efficiency may be limited by the current longitudinal crowding effect.

In some cases, the longitudinal current crowding effect may reduce the output power and/or efficiency of a semiconductor laser or optical amplifier by generating excessive heat near the output port or the front reflector. In some such cases, the excessive heat may increase the average junction temperature of the gain layer and the strength of a thermal lens formed inside the active waveguide or laser cavity. In some cases, the increased average junction temperature may reduce the efficiency and output power while a stronger thermal lens may reduce the quality of the light beam or laser beam output by the laser or the optical amplifier (e.g., due to increased slow axis blooming).

In some cases, a local wall-plug efficiency of laser light generation or amplification in a portion of the gain layer near the front reflector or output port can be relatively low due to strong gain saturation. As such, for a given amount of local pump energy provided (e.g., electrical power delivered to the semiconductor laser or optical amplifier), the portion of gain layer near the front reflector may produce less laser light compared to regions of the gain layer located farther from the front reflector or the output port (along the laser cavity, or the optical amplifier). In some cases, the asymmetric distribution of laser light intensity along the laser cavity, may increase optical absorption near the front reflector. As such, even light generated in more efficient regions of the gain layer may experience more loss as it is recirculated in the cavity. In various implementations, the magnitudes of these adverse effects may increase by increasing the pump power provided to the active waveguide. In some cases, the above-mentioned effects (caused by the longitudinal current crowding), may reduce the injection current at which the peak efficiency of laser light generation occurs. As such, the semiconductor laser may generate a lower level output power at its peak efficiency.

One possible use of the design concepts discussed herein can be to reduce the nonuniformity of current distribution along an active waveguide or the cavity of a laser, in a longitudinal direction from an input port to an output port or from a front reflector to a back reflector. In some cases, the laser can be a semiconductor laser and the optical amplifier can be a semiconductor optical amplifier. In some cases, the semiconductor laser, may be a Fabry-Perot laser, a Distributed Feed Back (DFB) Laser, or Distributed Bragg Grating (DBR) laser. In some such cases, the semiconductor laser can be an edge emitting laser such as a single mode ridge waveguide laser, a broad area laser, a flared or tapered laser, or other types of edge emitting semiconductor lasers. In some cases, the semiconductor optical amplifier or the semiconductor laser may comprise an active waveguide having a tapered or flared region. The tapered or flared region of the active waveguide may have a width along a lateral direction perpendicular to a longitudinal direction (e.g., a direction extending between the back reflector or input port and the front reflector or output port), where the width increases at least along a portion of the active waveguide in the longitudinal direction. In some examples, the width of a flared active waveguide may increase nonlinearly at least along a portion of length of the active waveguide.

In some cases, the proposed configurations disclosed herein may enable controlling the longitudinal injection current distribution along the waveguide (e.g., active waveguide) of a semiconductor optical amplifier or a cavity of a semiconductor laser using a longitudinally segmented electrode to provide independently controlled currents to different longitudinal regions of the gain layer by applying different voltages on different longitudinal electrode segments. The longitudinal direction may be a direction from the back reflector (or input port) to the front reflector (or output port) along the laser cavity and/or the active waveguide of the laser or amplifier, and may be parallel to the z-axis shown in the drawings in some cases. The longitudinally segmented electrode may comprise two or more electrically isolated longitudinal electrode segments. For example, a longitudinally segmented electrode may comprise a first longitudinal electrode segment and a second longitudinal electrode segment, with the first longitudinal electrode segment closer to the front reflector than the second longitudinal electrode segment and the second longitudinal electrode segment closer to the back reflector than the first longitudinal electrode segment. Moreover, the first longitudinal electrode segment may extend from a first end to a second end along the amplifier waveguide or the laser cavity, with the first end closer to the output port or the front reflector, and the second longitudinal electrode segment (separate from the first longitudinal segment) may extend from a third end to a fourth end along the amplifier waveguide or the laser cavity, with the fourth end closer to the input port or the back reflector than the third end such that a longitudinal distance between the first end and the output port or the front reflector is smaller than a longitudinal distance between the third end and the output port or the front reflector. Of course, the longitudinally segmented electrode may comprise more than two longitudinal electrode segments in various implementations. In some examples, the current and/or voltages provided to individual longitudinal electrode segments may be controlled (e.g., by an electronic control system or control electronics) and may in various implementations thereby tailor a distribution of the current and/or current densities injected to respective longitudinal segments of a gain layer in the active waveguide of the semiconductor laser or optical amplifier. Such control over the longitudinal injection current profile may be used in some cases to mitigate longitudinal current crowding in the amplifier waveguide or the laser cavity and potentially its impact on the efficiency of the laser light generation or light amplification by the active waveguide. In some cases, the longitudinal electrode segments may be further segmented in a lateral direction, e.g., possibly perpendicular to the longitudinal direction, to influence and/or control a lateral distribution of the current injected to the respective longitudinal segments of the gain layer. In some such cases, individual lateral segments of a longitudinal electrode segment may be electrically isolated. In some implementations, the current and/or voltage provided to individual lateral segments may be controlled by an electronic system or electronics, e.g., to influence and/or control a mode profile (e.g., a lateral mode profile) of laser light circulating within the laser cavity, a laser beam generated by the semiconductor laser, light propagating and amplifier along the amplifier waveguide, or an amplified light beam output by the optical amplifier.

In various implementations, a segmented electrode may be a top electrode disposed above the active waveguide of the semiconductor laser or optical amplifier, or a bottom electrode disposed below the active waveguide of the semiconductor laser or optical amplifier. The top and bottom electrodes may comprise one or more conductive layers (e.g., metallic layers). In some implementations, the top and the bottom electrodes may be both segmented. In some cases, the segmented top and bottom electrodes may have the same number of segments such that a pair of longitudinal segments comprising a top longitudinal segment and a bottom longitudinal segment control the current injected to the same region of the gain layer. In some such cases, the electronic system/electronics may individually control the voltage applied (and therefore current following) between a longitudinal segment of the top electrode and the respective longitudinal segment of the bottom electrode.

In some cases, the proposed configurations disclosed herein may enable controlling the longitudinal injection current distribution along the waveguide of an optical amplifier or the cavity of a semiconductor laser using a submount comprising a plurality of conductive pads (e.g., metallic pads) configured to be electrically connected to different regions or different segments of an electrode disposed above or below the gain layer of a semiconductor laser or optical amplifier. In some cases, the electrode (e.g., the top electrode or the bottom electrode) may be a single element electrode comprising a uniform conductive layer. In some such cases, individual conductive pads may be in electrical contact with different regions or areas of the electrode that are located at a distance from each other, e.g., at least in the longitudinal direction. For example, a first region or area of the electrode extends from a first end to a second end along the length of the electrode and a second region or area of the same electrode (different from the first area) may extend from a third end to a fourth end along the length of the electrode such that a longitudinal distance between the first end and the front reflector is smaller than a longitudinal distance between the third end and the front reflector. The first region or area, for example, could be closer to the front reflector (or the output port) than the second region and the second region or area can closer to the back reflector (or the input port) than the first region or area. In some examples, the current and/or voltage provided to individual conductive pads may be controlled (e.g., by an electronic control system or control electronics), to provide different currents and/or voltages thereto, and may in various implementations thereby tailor a distribution of the current and/or current densities injected to longitudinal regions of a gain layer below the respective electrode regions. Such control over the longitudinal injection current profile may, in some cases, be used to mitigate longitudinal current crowding in the laser cavity and possibly its impact on the efficiency of the laser light generation by the active waveguide.

In some implementations, the longitudinal current distribution along the laser cavity (e.g., in the gain layer), may be further tailored by tailoring a current control layer between an electrode of the laser and the gain layer. For example, a current control layer may be tailored to provide electrical isolation between regions of the semiconductor laser below longitudinal electrode segments and/or below electrode regions in contact with different conductive pads.

In some cases, a longitudinal injection current distribution along an amplifier waveguide or a laser cavity may be tailored using a longitudinally segmented top electrode, a longitudinally segmented bottom electrode, longitudinally segmented top and bottom electrodes, uniform top and/or bottom electrode where the top and/or the bottom electrode are in electrical contact with multiple conductive pads of a submount or any combination of these. An electronic control system or control electronics may individually control the currents and/or voltages provided to individual longitudinal segments or conductive pads, for example, possibly to generate a longitudinal injection current distribution in the gain layer that can be more uniform than a longitudinal injection current distribution that may be generated by providing a longitudinally uniform voltage along the amplifier waveguide or laser cavity.

In some examples, the current and/or voltage provided to individual conductive pads may be controlled (e.g., by an electronic control system or control electronics), to provide different currents and/or voltages to an active waveguide of a laser or an amplifier, to increase an output power generated by the laser or the optical amplifier (e.g., by mitigating current crowding effect).

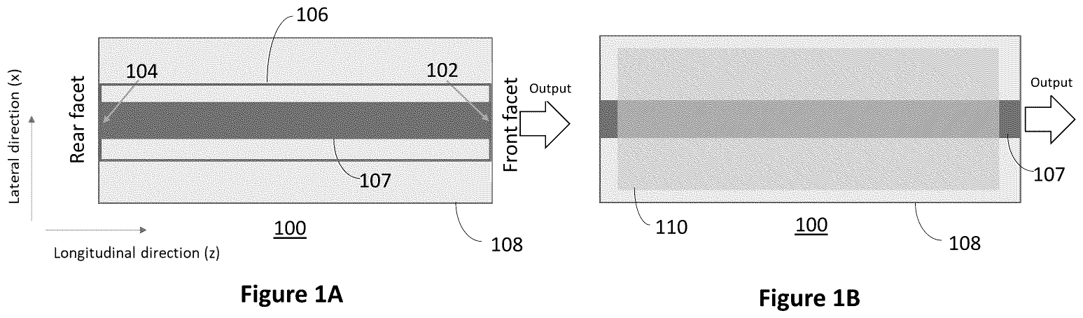

FIG. 1A illustrates a top cross-sectional view of an example semiconductor laser 100. In some cases, the semiconductor laser 100 can be a broad area laser. In some cases, the semiconductor laser 100 can be a Fabry-Perot laser. The semiconductor laser 100 may comprise a substrate 108, a front optical reflector 102, a back optical reflector 104, an active waveguide 106 extended in a longitudinal direction (e.g., parallel to the z-axis shown in FIG. 1A) between the front optical reflector 102 and the back optical reflector 104. In some cases, the active waveguide 106 can be a ridge waveguide. In some cases, the active waveguide can be a buried waveguide. In some other cases, the active waveguide 106 can be a slab waveguide having width in the lateral direction (parallel to x-axis) substantially equal to the width of the substrate 108. The front optical reflector 102 and the back optical reflector 104 may form a laser cavity that recirculates laser light generated and amplified by the active waveguide 106. In some cases, the laser light may comprise light having wavelengths within at least one bandwidth centered at or around a center laser wavelength. In some cases, the laser light may comprise light having wavelengths within multiple bandwidths centered at or around respective center laser wavelengths. The active waveguide 106 may include a gain layer that, when activated (e.g., electrically pumped), generates and amplifies laser light inside the laser cavity. In some cases, the front and the back reflectors 102, 104 can be cleaved facets. In some such cases, a cleaved facet may be coated with a metal layer or one or more dielectric layers. In some cases, the back reflector 104 can have high reflectivity within a wavelength range that comprises the wavelengths included in the laser light or within a gain bandwidth of the gain layer. In some cases, the reflectivity of the front reflector 102 can be lower than the reflectivity of the back reflector 104 for the wavelengths included in the laser light or within the gain bandwidth of the gain layer. In various implementations, the front and/or the back reflectors may comprise a distributed Bragg reflector (DBR), a sampled grating Bragg reflector (SGDBR), a cleaved facet, or a cleaved facet having a reflective coating. In some cases, the front reflector may comprise a cleaved facet having an anti-reflection (AR) coating.

In some cases, the structure shown in FIG. 1A may comprise a semiconductor optical amplifier. In some such cases, the back optical reflector 104 may comprise a low reflectivity rear facet serving as the input port of the optical amplifier and the front reflector 102 may comprise another low reflectivity facet serving as the output port of the optical amplifier. In various implementations, a low reflectivity facet may comprise a cleaved facet or a cleaved facet having an AR coating.

In some examples, the reflectivity of the back reflector can be from 50% to 80%, 80% to 95%, 95% to 97%, from 97% to 99%, from 99% to 99.9%%, from 99.9% to 99.99%, from 99.99% to 99.999% or any range formed by any of these values or large or smaller. In some examples the reflectivity of the front reflector can be from 0% to 1%, 1% to 5%, 5% to 15%, 15% to the 50%, from 50% to 90% or any range formed by any of these values or large or smaller.

In some examples, the reflectivity of the input port or the output port of an optical amplifier can be from 0% to 0.001%, 0.001% to 1% to 5%, 5% to 10%, 10% to 15%, from 15% to 20%, or any range formed by any of these values or large or smaller.

The active waveguide 106 may have a length (referred to as “waveguide length”) along the longitudinal direction (e.g., parallel to the z-axis), a width (referred to as “waveguide width”) along a lateral direction (e.g., parallel to the x-axis) that is perpendicular to the longitudinal direction and a thickness (referred to as “thickness”) along a vertical direction perpendicular to the longitudinal and lateral directions (e.g., parallel to z-axis). In some cases, the waveguide length may be substantially equal to a distance between the front 102 and back 104 reflectors. In some cases, the gain layer may be extended along the entire waveguide length. In some other cases, the gain layer may be extended along a longitudinal portion of active waveguide 106 less than the full length of the waveguide. In some cases, the active waveguide 106 may confine laser light or amplified light in a vertical direction perpendicular to the top surface of the substrate. In some such cases, a lateral confinement of the laser light generated by the semiconductor laser 100 (or light amplified by an optical amplifier) may be provided by a guiding structure (e.g., a ridge) above the active waveguide 106. In some cases, the active waveguide 106 may confine the laser light generated by the semiconductor laser 100 (or light amplified by an optical amplifier) both in the vertical and lateral directions. In some cases, the laser light (or amplified light) inside the waveguide 106 may be laterally confined by the refractive index change induced by the injected current via thermal lensing effect.

In some cases, a top electrode may be disposed above the active waveguide 106 and a bottom electrode may be disposed below the active waveguide 106. For example, in various designs, the top electrode may be disposed on a top layer of the laser (or amplifier) 100 and the bottom electrode may be disposed on a bottom surface of the substrate 108. In some cases, the top and the bottom electrodes can be metallic layers comprising gold, copper, silver, or other metals or an alloy composed on any combination of these or other metals. In some cases, the top and the bottom electrodes may comprise a highly conductive alloy or material.

In some cases, current can be injected to a region 107 of the active waveguide 106 to pump or optically activate by applying a voltage difference between the top electrode and the bottom electrode. In some examples, the bottom electrode may be electrically connected to a ground potential and a voltage (with respect to the ground potential) may be applied on the top electrode. In some examples, the pumped region 107 (e.g., the region that receives injection current), may be a region of the active waveguide 106 determined by the top electrode and the active waveguide 106. In some examples, the pumped region 107, maybe a region of the active waveguide determined by a high conductivity layer positioned between the top electrode and the active waveguide. In some examples, the pumped region 107, may be a region of the active waveguide determined by a dielectric layer positioned between the top electrode and the active waveguide 106. The pumped region 107 may have a width in the lateral direction (parallel to x-axis), a thickness along a vertical direction (perpendicular to the top surface of the substrate 108), and a length along the longitudinal direction (parallel to z-axis). The length of the pumped region 107 may be equal or smaller than the distance between the front 102 and the back 104 reflectors. In some cases, the thickness of the pumped region 107 may be substantially equal to the waveguide thickness. In some cases, a width of the pumped region 107 may be substantially equal to the width of the active waveguide. In some other cases, a width of the pumped region 107 may be smaller than the width of the active waveguide.

FIG. 1B illustrates a top view of the semiconductor laser (or optical amplifier) 100 with a top electrode 110 disposed above the active waveguide 106. In the example shown, the top electrode 110 has a rectangular shape longitudinally extending along the active waveguide from a first end near or closer to the front reflector 102 to a second end near or closer to the back reflector 104. The top electrode 110 may have a width along a lateral direction (e.g., along x-axis) and a length along the longitudinal direction (e.g., along z-axis). In some cases, the width of the top electrode 110 may be larger than the width of the active waveguide 106. In some cases, the width of the top electrode 110 may be larger than the width of the pumped region 107. In some cases, the length of the top electrode 110 can be smaller than or equal to the waveguide length. In some cases, a single element rectangular top electrode 110 may be used to apply a longitudinally uniform voltage or bias on the active waveguide (to the gain layer within the active waveguide). In the example shown, a patterned dielectric layer between the top electrode 110 and the active waveguide 106 may laterally limit the current injected to the active waveguide; as such, the width of the pumped region 107 can be smaller than the width of the top electrode 110.

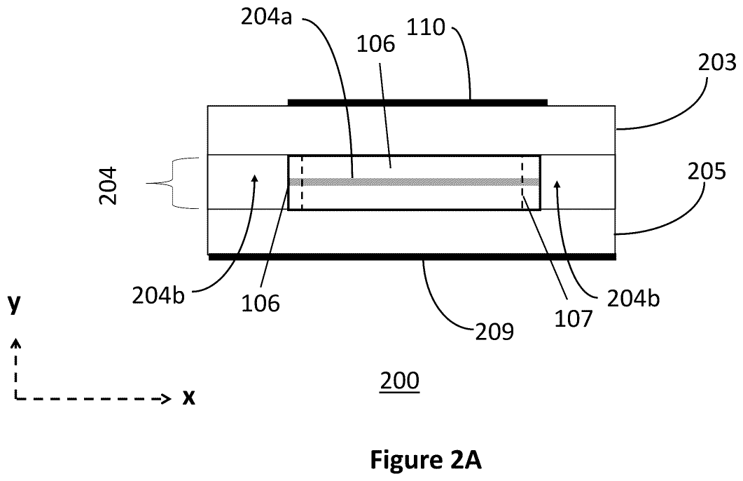

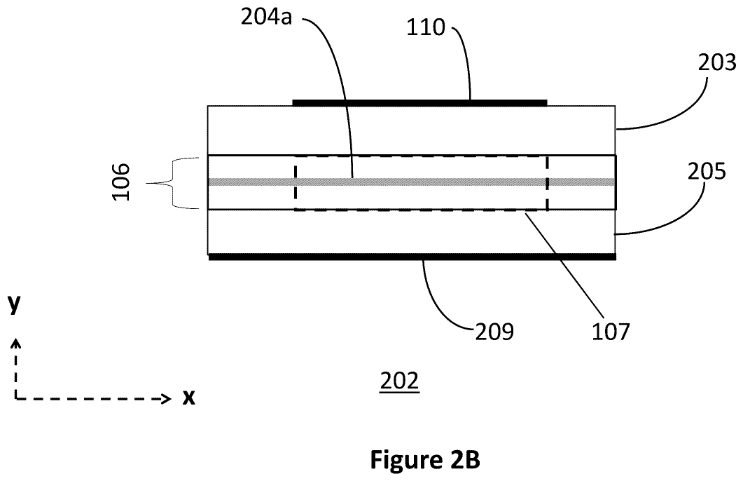

FIG. 2A shows an example vertical cross-section (e.g., cross-section through a plane orthogonal to length of the active waveguide or parallel to x-y plane) of a semiconductor laser or semiconductor amplifier 200 having a buried active waveguide 106. In some cases, the vertical direction (y-axis) may be the growth direction of the active waveguide 106. In some cases, the vertical cross-section shown in FIG. 2A can be a vertical cross-section of the semiconductor laser 100. In the example shown, the semiconductor laser or optical amplifier comprises: a top electrode 110, a top layer 203, a middle layer 204, a bottom layer 205, and a bottom electrode 209. The middle layer 204 may comprise the active waveguide 106, and two dielectric sections 204b. In some cases, an optical refractive index of waveguide 106 may be larger than the refractive index of the top layer 203, bottom layer 205, and the dielectric sections 204b. In some such cases, laser light (or amplified liht) may be vertically and laterally confined by the waveguide 106. The waveguide 106 may include the gain layer 204a or otherwise have gain material included in the waveguide. In some cases, one or more of the top layer 203, the middle layer 204 and/or the bottom layer 205 may comprise multiple sublayers. In some cases, the gain layer 204a may comprise one or more quantum well sublayers configured to provide optical gain upon being pumped by a current. In some cases, the gain layer 204a may include one or more quantum wire sublayers or quantum dot sublayers. In various designed, a thickness and refractive index of the sublayers of the middle layer 204 may be tailored to increase the overlap between the guided optical wave and the gain layer.

FIG. 2B shows an example vertical cross-section (e.g., cross-section through a plane orthogonal to length of waveguide or parallel to x-y plane) of a broad arca semiconductor laser 202. In some cases, the semiconductor laser 202 may comprise one or more of the features described above with the respect the semiconductor laser or optical amplifier 200. In some cases, the vertical cross-section shown in FIG. 2B can be a vertical cross-section to the semiconductor laser 100. In the example shown, the semiconductor laser comprises: a top electrode 110, a top layer 203, an active waveguide 106, a bottom layer 205, and a bottom electrode 209. In some cases, an optical refractive index of active waveguide 106 may be larger than the refractive index of the top layer 203, and the bottom layer 205. In some such cases, laser light may be vertically (parallel to y-axis) confined by the waveguide 106. The waveguide 106 may include the gain layer 204a or otherwise have gain material included in the waveguide. In some cases, one or more of the top layer 203, the active waveguide 106, and/or the bottom layer 205 may comprise multiple sublayers. In some cases, a region of the top layer 203 may be etched to laterally confine the laser light propagating in the waveguide 106. In some cases, the top layer 203 may include one or more lateral sections configured to confine the laser light propagating in the waveguide 106 in the lateral direction. For example, the top layer 203 may include a high index section between two low index regions.

In some cases, a width of the pumped region 107 of the active waveguide 106 of the semiconductor laser or optical amplifier 200 or the semiconductor laser 202, may be substantially equal to a width of a low resistivity section (e.g., comprising a highly doped p-type semiconductor), of the top layer 203. In some other cases, a width of the pumped region 107 of the active waveguide 106 of the semiconductor laser or optical amplifier 200 or the semiconductor laser 202, may be substantially equal to a width of the top electrode 110. In some case, the width if the top electrode 110 can be larger than the waveguide width and/or the width of the pumped region 107.

In some examples, the bottom layer 205 of the semiconductor laser or optical amplifier 200 may comprise the substrate 108 of the semiconductor laser 100.

In some examples, the top electrode 110 may be disposed on the top layer 203 (e.g., top surface of the top layer 203) and the bottom electrode 209 may be disposed on the bottom layer (e.g., bottom surface of the bottom layer 205). In some such examples, the top layer may comprise a highly doped semiconductor material (e.g., a p-type material). Other configurations, however, are possible. For example, one or more intermediate layers or sublayers may be included between the electrode and the top layer 203 and bottom layer 205, respectively. In some cases, the width of the top electrode 110 may be larger than that width of the active waveguide. In some cases, the pumped region 107 of the active waveguide 106 may have a thickness that is substantially equal or smaller than the waveguide thickness. In some cases, the pumped region 107 of the active waveguide 106 may have a width that is substantially equal or smaller than the waveguide width.

In certain implementations, the bottom electrode 209 may be an electrically conductive layer in electrical contact with the bottom layer 205 and the top electrode 110 may be another electrically conductive layer in electrical contact with the top layer 203. In some examples, the top electrode 110 and/or bottom 209 electrodes may comprise metal. In some examples, the top electrode 110 and/or bottom 209 electrodes may comprise one or more materials selected from the group: aluminum, gold, copper, tin, germanium, titanium, platinum, nickel, or any conductive alloy of these and other materials. Other materials may also be used. A thickness of any of the electrically conductive layers may be from 0.001 to 0.1 microns, 0.1 to 1 micron, from 1 to 2 microns, from 2 to 4 microns, from 4 to 6 microns, from 6 to 20 microns, or any range formed by any of these values or large or smaller.

A voltage difference between the top electrode 110 and the bottom 209 electrode, or a voltage applied on the top electrode 110 when the bottom electrode 209 is grounded or vice versa, may generate a current distribution within the gain layer 204a. An active region of the gain layer 204a that is activated by the current, may provide optical gain to at least a portion of the laser light that partially overlaps with the gain layer as the laser light wave propagates in the active waveguide 106 (e.g., along a direction parallel to the z-axis).

In some cases, a current control layer may be included as a sublayer between the top electrode 110 and the gain layer 204a. The current control layer may have low resistivity (e.g., a highly doped semiconductor layer) or high resistivity (e.g., a dielectric layer) or be somewhere in between (e.g., a doped semiconductor layer). Ion implanting of semiconductor may also be used to increase resistivity and/or reduce conductance. In some cases, a high resistivity current control layer may be patterned to isolate current flow across different regions of the gain layer 204a. For example, a current control layer can be an ion implanted layer where high resistivity ion implanted semiconductor regions divide the current control layer into electrically isolated regions. In some cases, the electrically isolated regions of a current control layer may facilitate control (possibly independent control) over current injected to different regions of the gain layer. Different current levels may thereby be injected into different locations of the gain layer 204a as a result of the current control layer.

A spatial distribution of the current in the gain layer 204a may be referred to herein as the “injection current profile”. Accordingly, a lateral distribution of injected current in the gain layer (along the waveguide width, e.g., parallel to the x-axis) may be referred to herein as the “lateral injection current profile” and a longitudinal distribution of injected current in the gain layer (along the length of the waveguide, e.g., parallel to the z-axis) may be referred to herein as the “longitudinal injection current profile”.

In some cases, the top layer 203, the middle layer 204 and/or the bottom layer 205 may comprise semiconductor materials. In some cases, the top layer 203, the middle layer 204 and/or the bottom layer 205 may comprise doped semiconductor material (e.g., p-type or n-type doped semiconductor material). The sublayers in each layer may comprise different types of semiconductor materials and may have different doping levels. In some cases, the top layer 203 may comprises a highly doped semiconductor layer (e.g., p-type semiconductor layer) in contact with the top electrode 110.

In various implementations, materials used in the semiconductor laser or optical amplifier and the layers therein comprise III-V semiconductor materials. In some implementations, the top layer 203, the middle layer 204 or the bottom layer 205 can include one or more materials selected from the group: gallium arsenide (GaAs), indium phosphide (InP), sapphire, silicon, gallium antimonide (GaSb), or gallium nitride (GaN). In some cases, the layers or the sublayers may include binary, ternary, quaternary, and quinternary alloys formed from one or more of the following: Ga, As, In, P, N, Al, Sb. Other material, however, may be used.

The gain layer 204a can comprise one or more materials selected from the group: gallium arsenide (GaAs), Indium Gallium Arsenide (InGaAs), indium phosphide (InP), Aluminum Indium Arsenide (AlInAs), indium gallium arsenide phosphide (InGaAsP), any ternary from InGaAsP, aluminum gallium arsenide (AlGaAs), indium aluminum gallium arsenide (InAlGaAs), indium aluminum phosphide (InAIP), indium aluminum gallium arsenide phosphide (InAlGaAsP) or any other ternary, quaternary, or quinternary compound. However, other material may be used in different implementations.

In some cases, the gain layer 204a may comprise one or more quantum-well sub-layers. In some cases, the quantum-well sub-layers may be configured to support quantum cascade amplification. In some cases, the gain layer 204a may comprise one or more quantum-dot sub-layers or quantum wire sublayers.

The bottom layer 205 can comprise one or more materials selected from the group: gallium arsenide (GaAs), indium phosphide (InP), sapphire, silicon, or gallium nitride (GaN) although other material may be used.

In various implementations, a thickness of the top layer (in vertical direction) may be from 0.001 to 0.1 micrometers (microns), from 0.1 to 1 microns, from 1 to 2 microns, from 2 to 4 microns, or from 4 to 20 microns or any range formed by any of these values or large or smaller.

A thickness of the gain layer (in vertical direction) may be from 0.001 to 0.1 microns, from 0.1 to 1 micron, from 1 to 2 microns, from 2 to 4 microns, or from 4 to 20 microns or any range formed by any of these values or large or smaller.

A thickness of the bottom layer (in vertical direction) may be from 0.001 to 0.1 microns, from 0.1 to 1 micron, from 1 to 2 microns, from 2 to 4 microns, or from 4 to 20 microns or any range formed by any of these values or large or smaller. Other sizes, however, are possible.

In various implementations, the material and/or composition of any of the sublayers may be selected based on the input wavelength or a target laser wavelength generated in the active waveguide 105. In some cases, the gain layer 204a may be composed of: GaN based material (e.g., compounds), GaAs based material, InP based material, GaSb based material, and InP based material. In some such cases, the gain layer may amplify light having wavelength from 300 nm to 550 nm, from 600 nm to 1200 nm, from 1200 nm to 2100 nm, from 2100 nm to 3500 nm, from 2100 nm to 8000 nm, or any other wavelength range formed by any of these values or may be outside these ranges.

In some example designs, the top electrode 110 may be connected to a current source and the bottom electrode 209 may be connected to a ground potential to support current injection to the gain layer 204a resulting in activation of at least a region (e.g., a region containing quantum wells, quantum wires or quantum dots) of the gain layer 204a although other configurations are possible. A magnitude and a spatial distribution of current injected into the gain layer 204a may be controlled based at least in part on one or more of the following factors: the electrical properties of: the top layer 203, gain layer 204a, and/or bottom layer 205, a shape of the top electrode 110, a shape of the bottom electrode 209, a shape of a current control layer, location of the conductive lines or wires that provide voltage and/or current to the top or bottom electrodes, or current and/or voltages provided to different segments (e.g., electrically isolated segments) of the top or bottom electrodes.

In some cases, a semiconductor optical amplifier may comprise one or more features described above with respect to FIG. 2B and the broad area semiconductor laser 202.

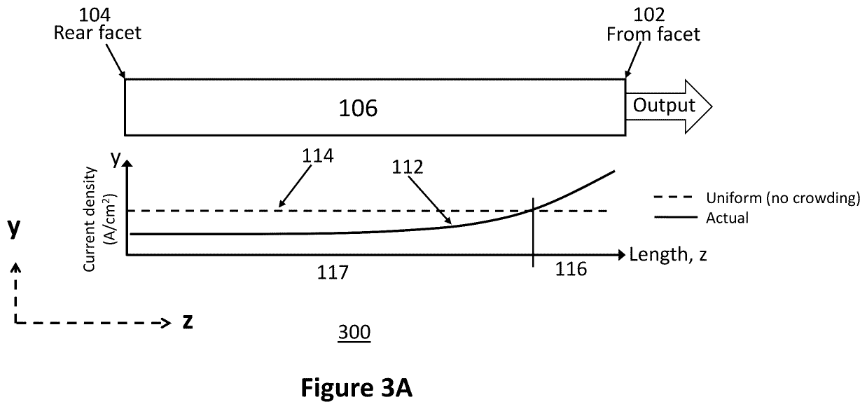

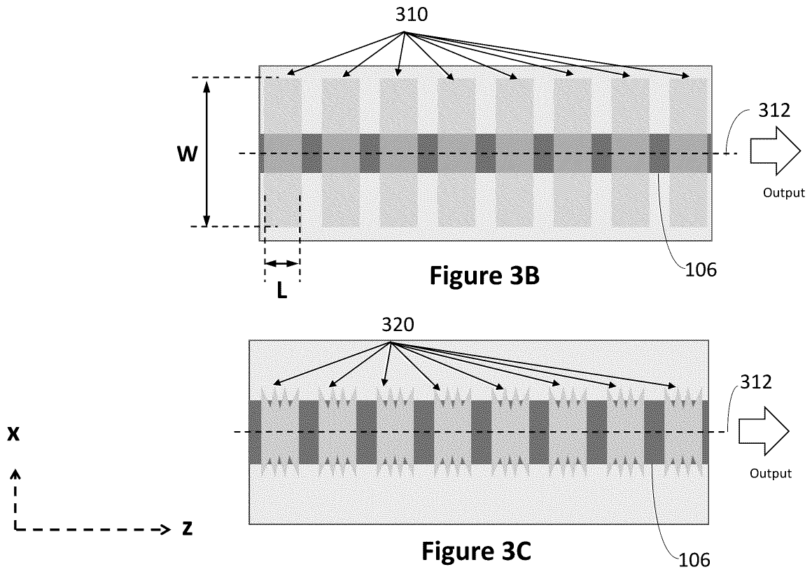

FIG. 3A illustrates a side-view of the active waveguide 106 and a schematic plot 300 showing calculated current density distributions 300 along the longitudinal direction of the laser cavity formed between the front reflector 102 and the back reflector 104 (e.g., parallel to the z-axis). In some examples, the calculated current density distribution 112 (solid line) may represent the longitudinal distribution of injection current density generated by applying a longitudinally uniform voltage on the active waveguide from the first reflector 102 to the second reflector 104 (e.g., using a single element top electrode similar to the single element top electrode 110). The current density distribution 112 (solid line) indicates that upon uniform electrical activation, the injection current density decreases (e.g., monotonically decrease) in the longitudinal direction from the front reflector 102 toward the back reflector 104 (e.g., along z-axis). A rate of change of the injection current density is larger near the front reflector 102 (e.g., close to an exponential decay rate) and gradually drops toward the back reflector 104 (e.g., close or a linear decay).

In some cases, when calculating the distribution of the injection current density along the laser cavity, the electronic properties of the active waveguide 106 (e.g., carrier recombination rate) can be decoupled from the intensity of laser light interacting with the active waveguide 106. In such cases, the calculated distribution of the injection current density along the laser cavity may become uniform or near uniform (e.g., the injection current density may stay substantially constant along z-axis). The current density distribution 114 (dashed line) is an example of such current distribution. In some cases, the parameter values used to calculate the current density distribution 112 and 114 may be identical except that for the uniform current distribution 114, the electrical properties of the gain layer may be decoupled or independent from the intensity of laser light circulating inside the laser cavity. A comparison between the current density distributions 114 and 112 indicates that the interaction of laser light, that is nonuniformly distributed along the waveguide 106, increases the current density within a first longitudinal section 116 of the active waveguide 106 and decreases the current density within a second longitudinal section 117 of the active waveguide. As described above, such nonuniform distribution of injection current density along the laser cavity, known as current crowding, may reduce the efficiency (e.g., slope efficiency) of the semiconductor laser or the efficiency of a semiconductor optical amplifier, in particular, when high current levels are provided to the laser to generate high power laser outputs.

Advantageously, as discussed herein, the injection current profile in the active waveguide 106 may be controlled by dividing the top electrode 110 and/or the bottom electrode 209 into two or more electrically isolated segments, and individually controlling the voltage and/or current provided to an individual electrode segment. In some implementations, a segmented top or bottom electrode may be disposed on the P-side of a semiconductor laser or optical amplifier. In some implementations, a segmented top or bottom electrode may be disposed on the N-side of a semiconductor laser or optical amplifier. Additionally, as discussed herein, the injection current profile in the active waveguide 106 may be controlled by controlling the voltage and/or current provided to different regions of a non-segment top or bottom electrode.

In some cases, the top or the bottom electrode may be longitudinally segmented along the laser cavity (e.g., parallel to the z-axis) or the optical amplifier to control the longitudinal injection current profile in the active waveguide 106 and the gain layer 204a. In some such cases, the voltage and/or current provided to individual longitudinal electrode segments may be controlled to generate a uniform or more uniform longitudinal injection current profile within the gain layer 204a along the length of the laser cavity or the optical amplifier. In some such cases, the voltage and/or current provided to individual longitudinal electrode segments may be controlled to generate a more uniform longitudinal injection current profile within the gain layer 204a along the length of the laser cavity or the optical amplifier, compared to an injection current profile generated by a non-segmented electrode.

In some cases, the voltage and/or current provided to individual longitudinal electrode segments may be controlled to increase efficiency or slope efficiency of the semiconductor laser or the optical amplifier.

In some cases, the voltage and/or current provided to individual longitudinal electrode segments may be controlled to increase the optical power of laser light output by a semiconductor laser (e.g., via the front reflector) or amplified light output by a semiconductor optical amplifier (e.g., via the output port).

In some implementation, a longitudinally segmented top or bottom electrode may allow generation of a user-defined injection current profile along the laser cavity and an optical amplifier. For example, more current can be applied to longitudinal sections of the gain layer 204a having higher efficiencies and less current may be applied to longitudinal sections of the gain layer 204a having lower efficiency. In some cases, the higher or lower efficiency of a longitudinal section of the gain layer 204a may be associated with the intensity of laser light (or amplified light) propagating within the longitudinal section. As discussed above, these longitudinal sections have different locations along the longitudinal axis (e.g., along the direction parallel to the z-axis), along the length of the laser cavity, or along the length of an amplifier waveguide.

A user defined injection current profile or a more uniform injection current profile may improve the efficiency of the semiconductor laser or optical amplifier and/or the level of optical power generated by the semiconductor laser or the optical amplifier, compared to that generated or amplified in a semiconductor laser or optical amplifier comprising a single element top electrode and/or a single element bottom electrode.

In some implementations, an electronic control system or control electronics may independently control the currents provided to the individual longitudinal electrode segments. For example, the electronic control system or control electronics may comprise a power supply or current source configured to apply individually controlled voltages using individual longitudinal segments to provide a set, desired or target current to an individual longitudinal electrode segment. The value of the set, desired or target current for an individual longitudinal electrode segment may be a user selected current or a value determined by a controller of the electronic control system. In some cases, the controller of the control electronics may determine the value of the set or target current based at least in part on a measured parameter of the semiconductor laser (e.g., an output power) that is controlled by the electronic control system or control electronics.

In some implementations, the current provided to an individual longitudinal section of the gain layer 204a may be dynamically controlled during the operation of the laser to generate a desired or target longitudinal current profile (e.g., a more uniform longitudinal current profile) based at least in part on a laser output power. For example, the voltages and current applied using individual longitudinal electrode segments may be selected to provide a first longitudinal injection current profile below and near a lasing threshold and dynamically adjusted to provide a second longitudinal injection current profile above the lasing threshold. In some cases, the transition from the first to the second longitudinal injection current profile can be a gradual and smooth transition. In some other cases, the transition may be a stepwise transition. In some examples, the power of laser light circulating inside the cavity may be assessed by a photodetector. For example, in some examples, the power of laser light output from the front reflector 102 may be measured by a photodetector that generates a corresponding detected voltage, which may be proportional to the measured power. In some examples, the power of amplified light propagating inside an optical amplifier may be assess by a photodetector, for example, configured to measure output from its output port. The photodetector may output a signal indicative of the measured optical power that may be used as a feedback signal to control one or more power supplies that provide voltage and/or current to longitudinal electrode segments. Other feedback and/or arrangements for controlling the voltage and/or current are possible. In some implementations the photodetector may receive light from the front reflector of the laser or the output port of the amplifier.

In some implementations, the electronic control system of a semiconductor laser (or optical amplifier) may provide individually controlled currents and voltages to the individual longitudinal segments of a segmented electrode of the semiconductor laser (or optical amplifier) based at least in part on the signal received from the photodetector. In some such cases, the voltage and/or current provided to individual longitudinal electrode segments may be controlled to increase efficiency or slope efficiency of the semiconductor laser or the optical amplifier or to increase the optical power of laser light (or amplified light) output by a semiconductor laser (or optical amplifier), via the front reflector (or the output port).

In some cases, a longitudinal electrode segment may have a length along the longitudinal direction, e.g., along the active waveguide 106 or laser cavity (e.g., parallel to the z-axis) and a width along a lateral direction perpendicular to the longitudinal direction (e.g., parallel to the x-axis). In some cases, individual longitudinal electrode segments may have equal or different lengths and widths. In some cases, individual longitudinal electrode segments may have equal lengths and widths. In some cases, individual longitudinal electrode segments may have equal lengths but different widths. In some cases, individual longitudinal electrode segments may have different lengths but equal widths. In some cases, individual longitudinal electrode segments may have different lengths and different widths. In some implementations, the longitudinal electrode segments may be equally spaced. In some other implementations, the spacing between longitudinal electrode segments may vary along the active waveguide. In some other implementations, the widths of the longitudinal electrode segments may vary along the active waveguide. In some other implementations, an average width or the widths of the longitudinal electrode segments may increase (e.g., linearly or nonlinearly) along the active waveguide from the back reflector (or input port) to the front reflector (or the output port). In some cases, two or more longitudinal electrode segments may have similar shapes. In some such cases, longitudinal electrode segments having similar shapes may be uniform in size. In some other cases, longitudinal electrode segments having similar shapes may be nonuniform in size. In some cases, the number of longitudinal electrode segments can be between 2 and 4, 4 and 6, 6 and 10, 10 and 20, or any in any range formed by any of these values or a number smaller or larger.

In various implementations, a longitudinal electrode segment may comprise a section having a rectangular shape, a diamond shape, a shape having curved lateral edges, a shape having triangular lateral edges, a shape having sawtooth shaped lateral edges, a shape having sinusoidal lateral edges or other shapes.

In some cases, individual longitudinal electrode segments may extend symmetrically in the lateral direction with respect to a centerline of the active waveguide 106.

FIG. 3B illustrates a top view of an example of a longitudinally segmented top electrode 310 having equally spaced rectangular longitudinal electrode segments disposed on a semiconductor laser (e.g., semiconductor laser 100). As illustrated, the electrode segments are arranged such that different segments are positioned at different longitudinal positions along the length of the active waveguide, gain medium, and/or laser cavity (e.g., parallel to the z-axis).

In the example shown, the length (L) of an individual segment is smaller than its width (W), different segments have identical lengths and widths, and are equally spaced. In some cases, the width (W) of a segment can be between 0.1 and 1 microns, 1 and 10 microns, 10 and 100 microns, 100 and 1000 microns, or any range formed by any of these values or larger or smaller. In some cases, the length (L) of an segment can be between 1 and 10 microns, 10 and 100 microns, 100 and 1000 microns, 1000 and 10000 microns, or any range formed by any of these values or larger or smaller. In some cases a spacing between the individual segments can be between 0.01 and 0.1 microns, 0.1 and 1 micron, 1 and 10 microns, 10 and 100 microns, 100 and 1000 microns, or any range formed by any of these values or larger or smaller.

FIG. 3C illustrates a top view of another example of a longitudinally segmented top electrode 320 having equally spaced longitudinal electrode segments with protrusions, namely triangular-shaped lateral edges in this example, disposed on a semiconductor laser. In the example shown, the width of an individual longitudinal electrode segments increases and decreases multiple times with position along the length of the segment (e.g., parallel to z-axis) forming triangular lateral edges. In some cases, the width of an individual longitudinal electrode segment (parallel to x-axis may increase and decrease multiple times with position along the length such that at least one lateral edge of the segment is triangular (e.g., sawtooth) shaped. In some examples, one lateral edge of a segment may have a triangular (e.g., sawtooth) shape and the other lateral edge may be straight (e.g., parallel to the active waveguide or z-axis).

In various implementations, a triangular (e.g., sawtooth) shape lateral edge of a longitudinal electrode segment may comprise equilateral or right triangles or equilateral triangles. Other uniform or non-uniform shapes are possible. In some cases, a triangular (e.g., sawtooth) shape lateral edge of a longitudinal electrode segment can may comprise 1, 2, 3, 4, 5, or 10 triangles or lateral protrusions having other shapes.

In some cases, the width of an individual longitudinal electrode segment may increase and decrease multiple times with position along the length such that at least one lateral edge of the segment comprises a nonlinear shape (e.g., a sinusoidal shape, a parabolic shape and the like).

In some cases, a lateral edge of an individual longitudinal electrode segment having a width that increases and decreases multiple times along the longitudinal direction, may provide an injection current distribution to the gain layer having an average width equal to the average width of the longitudinal electrode segment.

The individual longitudinal segments of the longitudinally segmented electrodes 310 and 320 extend symmetrically in the lateral direction (e.g., along x-axis) with respect to a centerline 312 of the active waveguide 106 such that respective portions of the segment on each side of the centerline are mirror images of each other with respect to the centerline 312. In some cases, an individual longitudinal electrode segment are not symmetric and may be positioned asymmetrically with respect to the centerline of the active waveguide.

In some implementations, in addition to longitudinal segments, a segmented top or bottom electrode may comprise electrically isolated lateral segments. Such electrode segments may be arranged such that different segments are positioned at different lateral positions along the width of the waveguide, gain medium, and/or laser cavity (e.g., parallel to the x-axis). In some cases, lateral segmentation of the top or the bottom electrode may allow controlling a lateral distribution of the injection current density in the gain layer and the active waveguide. In some implementations, this additional degree of freedom may be used to further improve the performance of the semiconductor laser. For example, lateral segmentation of the top or the bottom electrode may be used to control a lateral (or transverse) mode profile of the laser light sustained and output by the semiconductor laser.

In some cases, a lateral electrode segment may have a length along the longitudinal direction, e.g., along the active waveguide 106 or laser cavity (e.g., parallel to the z-axis), and a width along the lateral direction (e.g., parallel to the x-axis). In some such cases, lateral electrode segments may have equal or different lengths and widths. In some cases, lateral electrode segments may have equal lengths and widths. In some cases, lateral electrode segments may have equal lengths but different widths. In some cases, lateral electrode segments may have different lengths but equal widths. In some cases, lateral electrode segments may have different lengths and different widths. In some implementations, individual lateral segments of a longitudinal electrode segment may be equally spaced in the lateral direction. In some other implementations, the spacing between lateral segments of a longitudinal electrode segment may vary along the lateral direction. In some cases, two or more individual lateral segments of a longitudinal electrode segment may have similar shapes. In some such cases, lateral segments of a longitudinal electrode segment having similar shapes may be uniform in size. In some other cases, lateral segments of a longitudinal electrode segment having similar shapes may be nonuniform in size. In some cases, the number of lateral segments of a longitudinal electrode segment can be between 2 and 4, 4 and 6, 6 and 10, 10 and 20, or a number in any range formed by any of these values or a number that is smaller or larger.

In some cases, the lateral segments of a longitudinal segment can be positioned symmetrically in the lateral direction (e.g., along x-axis) with respect to a centerline of the active waveguide 106 such that respective lateral segments and respective portions the lateral segments on each side of the centerline are mirror images of each other with respect to the centerline. In some cases, lateral segments of an individual longitudinal segment may be positioned asymmetrically with respect to the centerline of the active waveguide.

In various implementations, a lateral segment may comprise a section having a rectangular shape, a shape having one or more curved lateral edges, a shape having one or more triangular lateral edges, a shape having one or more sinusoidal lateral edges or other shapes.

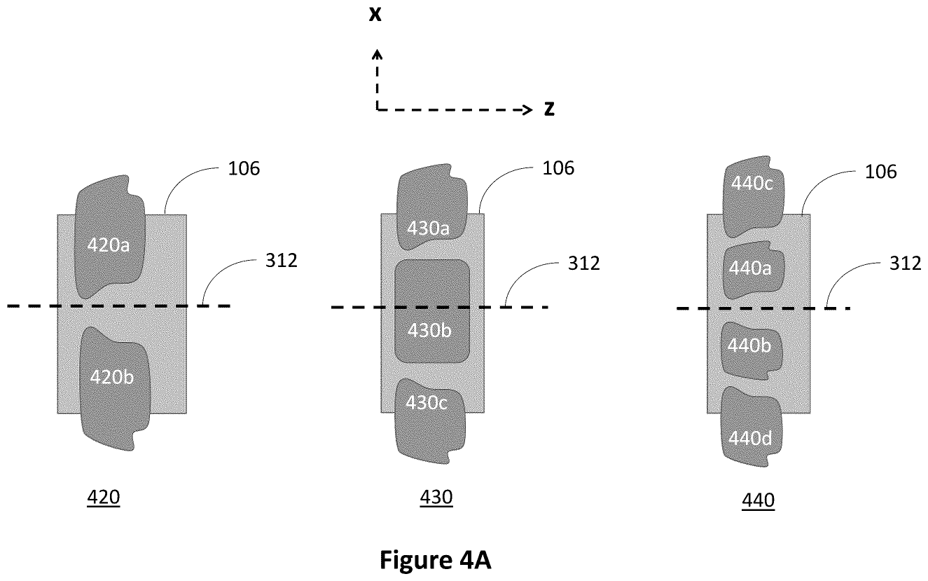

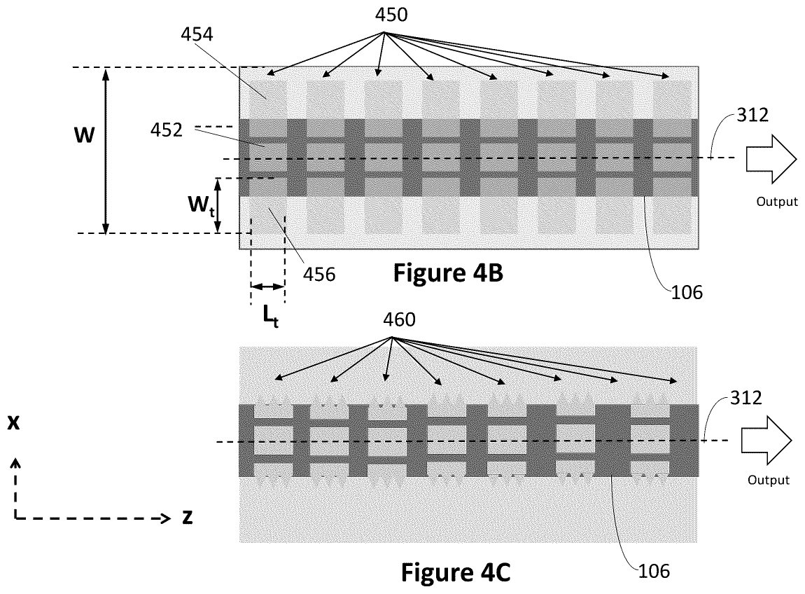

FIG. 4A illustrates top views of examples of laterally segmented longitudinal electrode segments 420/430/440 disposed on an active waveguide 106. As illustrated electrode segments may be arranged such that different segments are positioned at different lateral positions along the width of the waveguide, gain medium, and/or laser cavity (e.g., parallel to the x-axis).

The longitudinal segment 420 comprises two lateral segments 420a/420b that are poisoned symmetrically with respect to the centerline 312. In some cases, the lateral segments 420a/420b may have any shape and they may (or may not) be mirror images of each other with respect to the centerline 312.

The longitudinal segment 430 comprises three lateral segments 430a/430b/430c. The lateral segment 430b has symmetric shape and positioned symmetrically with respect to the centerline 312. The lateral segments 430a/430b may have any shape, and they may (or may not) be mirror images of each other and/or positioned symmetrically with respect to the centerline 312.

The longitudinal segment 440 comprises four lateral segments 434a/440b/440c/440d. The lateral segments 440a/440b may have any shape, and they may (or may not) be mirror images of each other and/or positioned symmetrically with respect to the centerline 312. Similarly, the lateral segments 440c/440d may have any shape, and they may (or may not) be mirror images of each other and/or positioned symmetrically with respect to the centerline 312.

FIG. 4B illustrates a top view of an example of longitudinally and laterally segmented top electrode 450 with segments having rectangular shape segments, disposed on a semiconductor laser. In the example shown, an individual longitudinal electrode segment comprises three lateral segments, a center (or central) segment 452, and two side segments 454 and 456. The lateral segments 452/454/456 may (or may not) be equally spaced and may (or may not) have substantially equal lengths (Lt) but different widths (Wt). For example, the width of the side lateral segments 454/456 may be larger than the width of the center segment 452 (although in other implementation different segments may have identical lengths and widths) and are equally spaced. In some cases, such as the example shown, Lₜ can be smaller than Wₜ. In other examples, Lₜ can be equal or larger than Wₜ.

In FIG. 4B, the lateral segments of an individual longitudinal segment of the top electrode 450, are positioned symmetrically in the lateral direction (e.g., along a direction parallel to the x-axis) with respect to a centerline 312 of the active waveguide 106 such that respective portions of the lateral segments on each side of the centerline are mirror images of each other with respect to the centerline 312.

In some cases, the width (W) of a segment can be between 0.1 and 1 microns, 1 and 10 microns, 10 and 100 microns, 100 and 1000 microns, or any range formed by any of these values or larger or smaller. In some cases the length (L) of an segment can be between 1 and 10 microns, 10 and 100 microns, 100 and 1000 microns, 1000 and 10000 microns, or any range formed by any of these values or larger or smaller. In some cases a spacing between the individual segments can be between 0.01 and 0.1 microns, 0.1 and 1 microns, 1 and 10 microns, 10 and 100 microns, 100 and 1000 microns, or any range formed by any of these values or larger or smaller.

FIG. 4C illustrates a top view of another example of longitudinally and laterally segmented top electrode including side lateral segments having protrusions, namely triangular lateral edges.

In the example shown, an individual longitudinal electrode segment comprises three lateral segments, a center segment 452, and two side segments 454 and 456. The lateral segments 452/454/456 may be equally spaced and may have identical lengths (L) but different widths (W). Other configurations and/or arrangement, however, are possible.

The discussion above may apply to the bottom electrode of a semiconductor laser in some implementations. For example, a shape, size, or other features of the bottom electrode may be similar to those of the top electrodes 310, 320, 450, or 460. In various implementations, the top and the bottom electrode of a semiconductor laser may be segmented electrodes.

In addition or alternative to segmenting the top or the bottom electrodes, in some implementations, the top layer 203 and/or the bottom layer 205 of the semiconductor laser 100 may be patterned to improve the electric isolation between individually controlled electrode segments (e.g., the longitudinal electrode segments). In some cases, by patterning the top layer 203 or the bottom layer 205 the current or current densities injected to a region of the gain layer 204a, below or above a longitudinal electrode segment, may become more independent from currents injected to the adjacent regions of the gain layer 204a located below adjacent longitudinal electrode segments. In some examples, the top layer 203 and/or the bottom layer 205 may be patterned by etching selected regions of top layer 203 (in a plane parallel to x-y plane) and/or the bottom layer 205 along a direction perpendicular to the top surface of the laser (parallel to y-axis). In some cases, the regions of the top layer 203 and/or the bottom layer 205 that are not covered by an electrode segment may be etched. In various implementations, the etch depth of the top layer 203 may extend to any vertical positon (parallel to y-axis) between the top surface of the top layer 203 and the middle layer 204 and/or the etch depth of the bottom layer 205 may extend to any vertical position between the bottom surface of the bottom layer 205 and the middle layer 204. In some implementations, a patterned top layer 203 or a patterned bottom layer 205 may have a shape that is similar to the shape of segmented top electrodes 310, 320, 450, or 460.

In some examples, the longitudinal distribution of the injection current along the cavity of a semiconductor laser having non-segmented top and bottom electrode, and a patterned or segmented top layer 203 and/or bottom layer 205, may be tailored (e.g., to make it a more uniform distribution), by individually controlling the current and/or voltages applied on different longitudinal regions of a non-segmented electrode.

In some implementations, the isolation between current injected by the different electrode segments (e.g., longitudinal electrode segments) to the corresponding longitudinal regions of the gain layer may be improved by a current control layer positioned between the top electrode 110 or the bottom electrode 209, and the gain layer 204a.

In some cases, the current control layer can be a patterned high resistivity layer. In some cases, the patterned high resistivity layer may include high resistivity regions configured to reduce or block current flow through the regions of the top layer 203 or the bottom layer 205 that are not below an electrode segment (e.g., a longitudinal electrode segment). In some cases, the high resistivity regions of the current control layer may form a shape that is complementary with respect to the segmented electrodes described above (e.g., patterned electrodes 310, 320, 450 or 452).

In some cases, a current control layer can be a patterned low resistivity layer or a patterned high conductivity layer. A low resistivity layer may be a highly doped layer (e.g., a p++ layer) in contact with the top electrode 110. In some such cases, the patterned low resistivity layer may have a shape that is similar to the shape of the segmented top electrodes 310, 320, 450, or 460. Such patterned low resistivity layer may improve the level of individual or independent control over the injection currents generated along different longitudinal regions of the gain layer 204a.

In some cases, a shape and/or composition of a current control layer may be configured to support a current supply distribution above the gain layer 204a similar to the current supply distribution supported by the segmented electrodes 310, 320, 450, or 460, but using a single element electrode.

In some examples, a patterned high resistivity layer may comprise an ion implanted layer where the high resistivity regions are ion implanted. The implant ions may include H+, O+, or any other molecule that increases the resistivity of the semiconductor material upon implantation. Any of these implementations may be done easily in a single lithography step during the wafer fabrication process.

In some implementations, a semiconductor laser or optical amplifier having a segmented electrode (e.g., segmented top or bottom electrode) may be mounted on and connected to a submount (or carrier), for example, for interfacing with test instrumentation. In some cases, the submount may comprise electrically isolated conductive pads configured to be electrically connected to the longitudinal and/or lateral segments of the top and/or the bottom electrodes of the semiconductor laser. In some other cases, the electrically isolated conductive pads may be configured to be electrically connected to different regions of a non-segmented top electrode and/or a non-segmented bottom electrode of the semiconductor laser. The electrically isolated conductive pads may themselves provide the individual voltage and/or current control.

In some cases, the conductive pads of the submount may be composed of any metal or ceramic material including Cu, BeO, AlN, CuW, or any combination thereof. In some examples, the submount may comprise pre-deposited metal layers and/or solder for device attachment. The metal layers may include Ti, Pt, Pd, Au, AuSn, In, Ag, or any combination thereof.

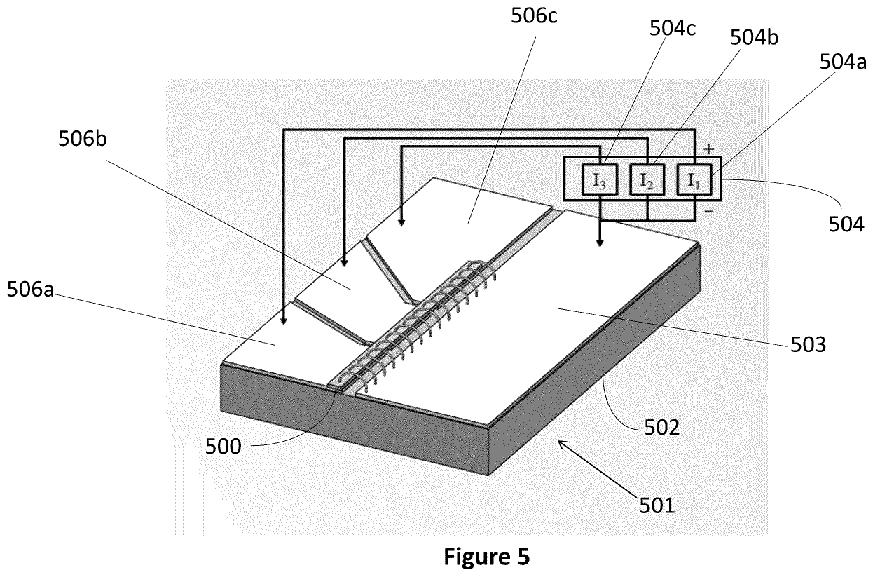

FIG. 5 illustrates a perspective view of a semiconductor laser or optical amplifier 500 (e.g., a broad area semiconductor laser) mounted on a submount 501 having four electrically conductive pads. In some cases, the semiconductor laser (or optical amplifier) 500 may have a longitudinally segmented top electrode. The submount 501 comprises a substrate 502, a reference conductive pad 503, e.g., serving as the ground plane (or ground potential), and three conductive pads 506a/506b/506c for providing individually controlled currents and/or voltages. In some cases, the semiconductor laser or optical amplifier 500 may comprise a non-segmented bottom electrode connected to the reference conductive pad 503 via series of conductive lines (e.g., wire bonds). In the example shown the semiconductor laser or optical amplifier 500 is mounted upside down with the non-segmented bottom electrode facing up. In some cases, individual conductive pads 506a/506b/506c may be electrically connected to individual longitudinal segments of the top electrode of the semiconductor laser (or optical amplifier) 500. In some other cases, individual conductive pad segments may be electrically connected to a group of longitudinal segments of the top electrode. In some cases, an electronic control system or control electronics 504 (e.g., a power supply or a current source) may control a voltage and/or a current provided to an individual conductive pad of the conductive pads 506a/506b/506c. For example, the electronic control system or control electronics 504 may control the voltage applied between the conductive pad 506a and the reference conductive pad 503 such that a current flowing through the pad 506a (to the semiconductor laser or amplifier 500) stays close or equal to a set current for the conductive pad 506a. In the example shown, three channels 504a/504b/504c of the electronic control system or control electronics 504 provide voltage and/or current to three conductive pads 506a/506b/506c, respectively. In some cases, a user may select or adjust the set or target current I₁, I₂, and I₃ for the channels 506a/506b/506c respectively. In some other cases, a controller of the electronic control system 504 may select or adjust the set or target currents I₁, I₂, and I₃. For example, the controller may adjust the set or target currents I₁, I₂, and I₃ based at least in part on a measured parameter (e.g., output power) of the laser light output via, e.g., the front reflector of the broad area semiconductor laser (or optical amplifier) 500.

As described above, in some cases, the longitudinal injection current distribution along a laser cavity may be tailored by controlling currents provided to different regions of the electrode (that are not electrically isolated). In some cases, the uniformity of the longitudinal injection current distribution along the laser cavity may be improved by connecting separate longitudinal regions of an electrode to separate current sources and independently controlling the currents provided to individual longitudinal regions of the electrode. For example, a first longitudinal region of the electrode may extend from a first end to a second end along the length of the electrode and a second region of the electrode (separate from the first region) may extend from a third end to a fourth end along the length of the electrode such that a longitudinal distance between the first end and the front reflector is smaller than a longitudinal distance between the third end and the front reflector. The first longitudinal region may, in some cases, be closer to the front reflector than the second longitudinal region and the second longitudinal region may be closer to the back reflector than the first longitudinal reflector. The first longitudinal region may be connected to a first current source (or a first channel of an electronic control system) having a first set or target current, and the second longitudinal region may be connected to a second current source (or a second channel of the electronic control system) having a second set or target current.

In some cases, the top electrode and the bottom electrodes of the semiconductor laser (or optical amplifier) 500 can be non-segmented electrodes. In some such cases, the first conductive pad 506a may be electrically connected to a first longitudinal region of the electrode, the second conductive pad 506b may be electrically connected to a second longitudinal region of the electrode, and the third conductive pad 506c may be electrically connected to a third longitudinal region of the electrode. By adjusting the set or target currents of the current channels 506a/506b/506c that supply individually controlled currents to the conductive pads 506a/506b/506c, the current injected to the gain layer by different longitudinal regions of the electrode may be tailored, for example, such that the resulting longitudinal injection current distribution along the laser cavity becomes more uniform (e.g., compared to that of similar semiconductor laser driven by a non-segmented electrode connected to a single current source via a single conductive pad).

In some implementations, the longitudinal injection current distribution along the cavity of a semiconductor laser may be tailored using a non-segmented electrode that is connected to a single current source via multiple conductive lines (e.g., wire bonds). For example, different longitudinal regions of the electrode may be connected to the current source via different groups of conductive lines comprising different numbers of conductive lines. In some cases, a current provided to a longitudinal region of the electrode by a group of conductive lines may be dependent on, e.g., proportional to, the number of conductive lines in the group. For example, a number of wire bonds in a group of wire bonds connecting a first longitudinal region of the electrode to the current source may be smaller than that of a second longitudinal region of the electrode that is farther from the front reflector compared to the first longitudinal region (or vice versa). In some implementations, an electronic control system may provide individual currents to individual longitudinal regions of the electrode via different groups of conductive lines comprising a number of wires (e.g., wire bonds), so as to increase uniformity of a longitudinal distribution of injection current provided to the gain layer of a semiconductor laser or optical amplifier. At least two groups of conductive lines may comprise different number of conductive lines. In some examples, the number of conductive lines of a first group of conductive lines providing current to a first longitudinal region closer to a front reflector of the laser (or an output port of the amplifier) may be lager than that of a second group of conductive lines providing current to a second longitudinal region closer to a back reflector of the laser (or an input port of the amplifier). In some other examples, the number of conductive lines of the first group of conductive lines can may be smaller than that of a second group of conductive lines.

In any of the configurations described above, a patterned current control layer may improve the level of individual or independent control over the injection currents generated along different longitudinal regions of the gain layer and therefore the uniformity of the resulting longitudinal injection current profile.

In various implementations, the longitudinal injection current distribution along the cavity of a semiconductor laser may be tailored by segmenting a conductive layer of a conductive pad of the submount that provides current to the laser, and/or segmenting a conductive (or a low resistivity) layer in the top layer 203 and/or the bottom layer 205 of the semiconductor laser 100, and providing individually controlled currents and/or voltages to the corresponding individual segments.

In some implementations, the methods and configurations described above may be used to provide a tailored non-uniform longitudinal injection current distribution along the cavity of a semiconductor laser (or optical amplifier). In some examples, the voltage and/or currents provided to longitudinal regions of a non-segmented electrode or longitudinal electrode segments of a segmented electrode may be controlled and/or selected to increase the injection current in the gain layer at one or more longitudinal positions closer to the back reflector of the semiconductor laser (or the input port of the semiconductor optical amplifier). The methods, configurations, and implementations, however, should not be so limited. In some cases, for example, the voltage and/or currents provided to longitudinal regions of a non-segmented electrode or longitudinal electrode segments of a segmented electrode may be controlled and/or selected to increase the injection current in the gain layer at one or more longitudinal positions closer to the front reflector of the semiconductor laser (or the output port of the semiconductor optical amplifier). Still other methods, configurations and implementations are possible, for example, the electronic control system can be configured to provide other current distributions.

In various implementations, the electronic control system that controls currents and/or voltages provided to different longitudinal and/or lateral segments of a top or bottom electrode of a laser or an amplifier, may comprise a programmable or power/current/voltage supply. In some cases, the electronic control system may comprise a field programmable gate array. In some examples, the electronic control system may be integrated with the laser or amplifier. In some cases, the electronic control system may comprise a user interface or be in communication with a user interface that allows a user to adjust one or more parameter of the electronic control system (e.g., a set point, a threshold value, and the like). In some cases, the electronic control system may receive a signal (e.g., a feedback signal) from the laser, amplifier, or a device (e.g., a photodetector, or other optical measurement devices) and control a voltage and/or a current provided to an electrode segment (e.g., longitudinal or lateral segment), based at least in part on the signal. In some cases, the electronic control system may comprise a feedback loop configured to control a voltage and/or a current provided to electrode segments (e.g., longitudinal or lateral segments), based at least in part on a feedback signal to maintain a measured parameter (e.g., optical output power or intensity) of the laser or the amplifier within a preselected range (e.g., a range selected by a user via a user interface).

Although various implementations described above comprise rectangular optical waveguides (e.g., active waveguides having a constant or nearly constant lateral width along the length of the waveguide), in some designs the waveguide need not be rectangular and its width may vary. In some cases, the semiconductor laser (or optical amplifier) may comprise a flared active waveguide extended in the longitudinal direction (e.g. along z-axis) between the back reflector (or the input port) and the front reflector (or the output port). A flared active waveguide can have a lateral width along a lateral direction (e.g., along the x-direction) perpendicular to the longitudinal direction (e.g., z-direction), where the lateral width increases along the longitudinal direction (e.g., from the back reflector or input port to the front reflector output port or alternatively, most this distance).

In some implementations, the top or the bottom electrode of a flared semiconductor laser or optical amplifier (e.g., having a flared active waveguide), may comprise a segmented electrode having one or more features (e.g., size, shape, segment arrangement and the like) described above with respect to the segmented electrodes 310, 320, 450, and 460. Additionally, a longitudinal segment of the top or the bottom electrode of a flared semiconductor laser or optical amplifier may comprise lateral segments similar to those described above with respect to the longitudinal electrode segments 420, 430, and 440. In some examples, a longitudinally and laterally segmented top or bottom electrode of a flared semiconductor laser or optical amplifier may comprise one or more features described above with respect to electrodes 450, and 460.

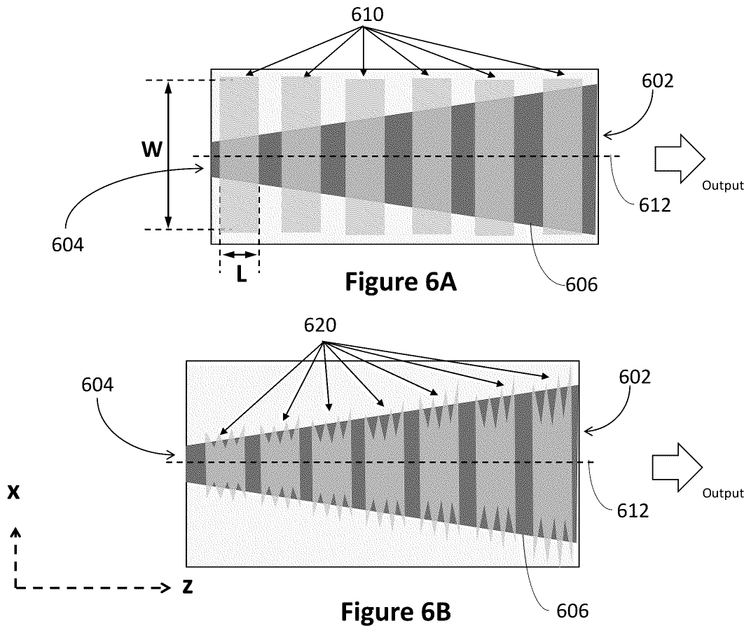

FIG. 6A illustrates a top view of an example of a longitudinally segmented (e.g., longitudinally segmented) top electrode 610 disposed on a semiconductor laser or optical amplifier having a flared active waveguide 606. The flared active waveguide 606 is extended in a longitudinal direction from an input port or back reflector 604 to an output port or front reflector 602. A width or an average width of flared active waveguide may increase from the input port or back reflector 604 to the output port or front reflector 602. In some examples, the segmented top electrode 610 may comprise equally spaced rectangular longitudinal electrode segments As illustrated, the electrode segments are arranged such that different segments are positioned at different longitudinal positions along the length of the waveguide, gain medium, and/or laser cavity (e.g., parallel to the z-axis). In the example shown, the length (L) of an individual segment is smaller than its width (W), different segments have identical lengths and widths, and are equally spaced. In some cases, the width (W) of a segment can be between 0.1 and 1 microns, 1 and 10 microns, 10 and 100 microns, 100 and 1000 microns, or any range formed by any of these values or larger or smaller. In some cases, the length (L) of a segment can be between 1 and 10 microns, 10 and 100 microns, 100 and 1000 microns, 1000 and 10000 microns, or any range formed by any of these values or larger or smaller. In some cases, a spacing between the individual segments can be between 0.01 and 0.1 microns, 0.1 and 1 micron, 1 and 10 microns, 10 and 100 microns, 100 and 1000 microns, or any range formed by any of these values or larger or smaller. In some cases, a width or an average width the longitudinal segments may vary along the longitudinal direction. For example, a longitudinal segment closer to the back reflector or input port 604 may have a width or an average width smaller than a second longitudinal segment closer to the front reflector or output port 602.

FIG. 6B illustrates a top view of another example of a longitudinally segmented top electrode 620 having equally spaced longitudinal electrode segments with protrusions at the edges, e.g., triangular-shaped lateral edges, disposed on a flared semiconductor laser or optical amplifier. An average lateral width (e.g., width along the x-axis) of the longitudinal electrode segments may vary in the longitudinal direction proportional to the lateral width of the corresponding flared active waveguide 606 in some implementations. In the example shown, the lateral width of the flared active waveguide 606 and the average lateral width of consecutive longitudinal segments increase from the back reflector or input port 604 to the front reflector or output port 602 although this is not required.

In the example shown, the lateral width of an individual longitudinal electrode segment increases and decreases multiple times with position along the length of the segment (e.g., parallel to z-axis) forming triangular lateral edges. In some cases, the width (e.g., parallel to x-axis) of an individual longitudinal electrode segment may increase and decrease multiple times with position along the length such that at least one lateral edge of the segment has protrusions, e.g., is triangular shaped. In some examples, one lateral edge of a segment may have a protrusion, e,g., triangular shape, and the other lateral edge may be straight (e.g., parallel to the active waveguide or z-axis).

In various implementations, a triangular shaped lateral edge of a longitudinal electrode segment may comprise equilateral or right triangles or equilateral triangles. Other uniform or non-uniform shapes are possible. In some cases, a lateral edge of a longitudinal electrode segment may comprise 1, 2, 3, 4, 5, or 10 triangles or lateral protrusions having other shapes.

In some cases, the width of an individual longitudinal electrode segment may increase and decrease multiple times with position along the length such that at least one lateral edge of the segment comprises a nonlinear shape (e.g., a sinusoidal shape, a parabolic shape and the like).

In some cases, a lateral edge of an individual longitudinal electrode segment having a width that increases and decreases multiple times along the longitudinal direction, may provide an injection current distribution to the gain layer having an average width equal to the average width of the flared active waveguide 606.

The individual longitudinal segments of the longitudinally segmented electrode 610 and 620 extend symmetrically in the lateral direction (e.g., along x-axis) with respect to a centerline 612 of the active waveguide 606 such that respective portions of the segment on each side of the centerline are mirror images of each other with respect to the centerline 612. In some cases, an individual longitudinal electrode segment may not be symmetric and/or may be positioned asymmetrically with respect to the centerline 612 of the flared active waveguide 606.

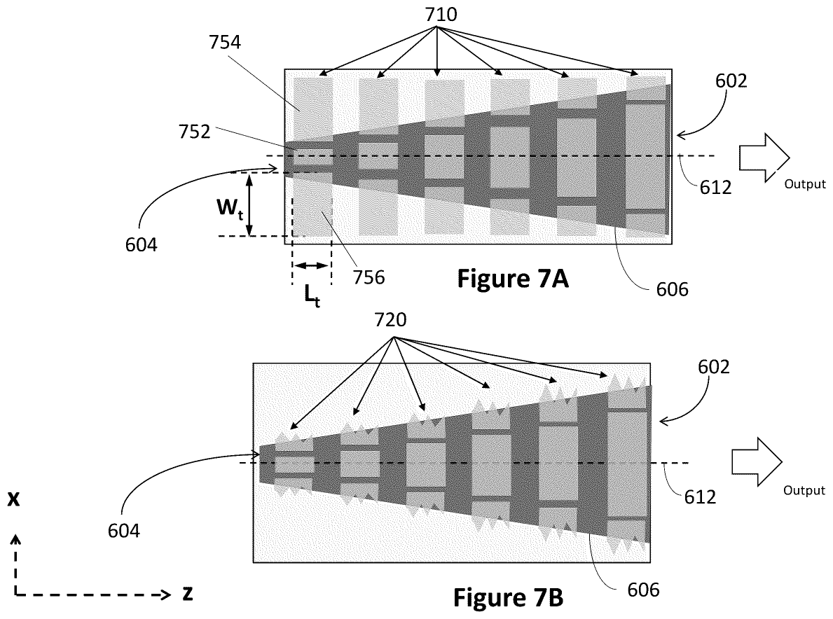

FIG. 7A illustrates a top view of an example of longitudinally and laterally segmented top electrode 710 with segments having rectangular shape segments, disposed on a flared semiconductor laser or optical amplifier 606. In the example shown, an individual longitudinal electrode segment comprises three lateral segments, a central segment 752, and two side segments 754 and 756. The lateral segments 752/754/756 may (or may not) be equally spaced and may (or may not) have substantially equal lengths (Lₜ) but different widths (Wₜ). For example, the width of the side lateral segments 754/756 may be different from the width of the central segment 752. In the example shown, the width of the side lateral segments 754/756 and/or the central segment 752 of the subsequent longitudinal segments may decrease and increase respectively, from the back reflector (or input port) 604 to the front reflector (or output port) 602 or a portion thereof such as most of this distance. In some examples, the width of the central segment 752 of the subsequent longitudinal segments may increase proportional to the lateral width of the flared active waveguide 606. Advantageously, tailoring the width of the side lateral segments 754/756 and/or the central segment 752 of the longitudinal segments of the electrode 710 according to the lateral width of the flared active waveguide 606 may facilitate controlling the lateral profile of the optical mode propagating along the flared waveguide 606. In some cases, such as the example shown, Lₜ can be smaller than Wₜ. In other examples, Lₜ can be equal or larger than Wₜ.

In FIG. 7A, the lateral segments of an individual longitudinal segment of the top electrode 750, are positioned symmetrically in the lateral direction (e.g., along a direction parallel to the x-axis) with respect to a centerline 712 of the active waveguide 606 such that respective portions of the lateral segments on each side of the centerline are mirror images of each other with respect to the centerline 712.

In some cases, the width (Wₜ) of a segment can be between 0.1 and 1 microns, 1 and 10 microns, 10 and 100 microns, 100 and 1000 microns, or any range formed by any of these values or larger or smaller. In some cases, the length (L) of an segment can be between 1 and 10 microns, 10 and 100 microns, 100 and 1000 microns, 1000 and 10000 microns, or any range formed by any of these values or larger or smaller. In some cases a spacing between the individual segments can be between 0.01 and 0.1 microns, 0.1 and 1 microns, 1 and 10 microns, 10 and 100 microns, 100 and 1000 microns, or any range formed by any of these values or larger or smaller.

FIG. 7B illustrates a top view of another example of longitudinally and laterally segmented top electrode including side lateral segments having protrusions, e.g., triangular lateral edges, disposed on the flared waveguide 606 of a flared semiconductor laser or optical amplifier. In this example, the average width of the side lateral segments and the central segment of the subsequent longitudinal segments may both increase from the back reflector (or input port) 604 to the front reflector (or output port) 602. In some examples, the width or the average width of one or both the central segment and the lateral segments of the subsequent longitudinal segments may increase proportional to the lateral width of the flared active waveguide 606. Advantageously, the protrusion, e.g., triangular lateral edges, of the side lateral segments and their tailored average width (e.g., based on the width of the active waveguide 606) may facilitate controlling the lateral profile of the optical mode propagating along the flared waveguide 606.

The discussion above may apply to the bottom electrode of a semiconductor laser or optical amplifier in some implementations. For example, a shape, size, or other features of the bottom electrode may be similar to those of the top electrodes 610, 620, 710, or 720. In various implementations, the top and the bottom electrode of a semiconductor laser may be segmented electrodes.

In various implementations, the longitudinally segmented top and/or bottom electrode designs described above may be used for providing a tailored, for example, a uniform or near uniform injection current distribution along length of the active waveguide of a semiconductor laser or optical amplifier. In some examples, the number of longitudinal segments, the geometrical characteristics of a longitudinal segments, a number and geometrical characteristics of lateral segments of a longitudinal segment, and the position of a longitudinal segment with respect to the front reflector or output port, or with respect to the back reflector or input port, or any combination of these, may be determined based on the characteristics of the semiconductor laser or optical amplifier.

In various implementations, a master oscillator power amplifier (MOPA) device may comprise a semiconductor laser and a semiconductor amplifier where at least one of them comprise a segmented (e.g., longitudinally segmented) top and/or bottom electrode. In some examples, one or both master oscillator (laser) and power amplifier (optical amplifier), may comprise a flared active waveguide. As described above, when the active waveguide is flared and one of the top or bottom electrode is flared, the widths or average widths of the corresponding longitudinal segments may be tailored according to the shape of the flared active waveguide.

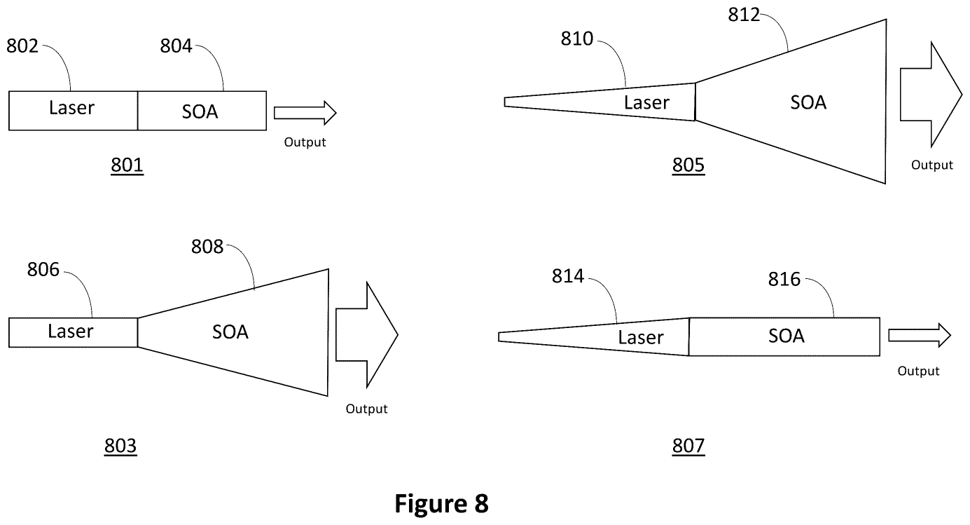

FIG. 8 illustrates top view diagrams of four different optical devices 801, 803, 805, and 807 that may be pumped using the temporally and/or spatially tailored or controlled drive currents (e.g., drive currents provided via a segmented electrode). In some cases, the (e.g., semiconductor MOPAs) The MOPA 801 comprises a laser section 802 (a semiconductor laser) and an optical amplifier section 804 (e.g., a semiconductor optical amplifier or SOA). The laser section 802 and the SOA 804 may comprise a rectangular shape or non-flared pumped optical gain region in some designs. In some examples, the rectangular shape pumped optical gain region may include a rectangular shape active waveguide (e.g., a ridge waveguide, a buried waveguide, or a slab waveguide) and a rectangular shape electrode. In some examples, one or both the laser section 802 may comprise a single mode waveguide (a waveguide having a single lateral mode). In some cases, one or both the laser 802 and the SOA 804 may comprise longitudinally segmented electrodes similar to the electrodes 310, 320 (shown in FIGS. 3B-3C) or longitudinally and laterally segmented electrodes similar to the electrodes 450, or 460 (shown in FIGS. 4B-4C).

The MOPA 803 comprises a semiconductor laser section 806 and a flared semiconductor optical amplifier (SOA) region (or section) 808. In some cases, the laser section 806 may comprise a non-flared (e.g., rectangular shape) pumped gain region. In some examples, the pumped gain region may comprises a single mode (e.g., single lateral mode) waveguide. In some cases, the flared optical amplifier region 808 may comprise a flared pumped gain region. The flared pumped gain region can comprise a flared waveguide and a flared or non-flared electrode, or a non-flared waveguide and a flared electrode. For example, the flared optical amplifier region 808 may comprise a slab waveguide, and a flared electrode disposed on the slab waveguide that generates the flared pumped gain region within the slab waveguide. In some implementations, the laser section 806 and the SOA (e.g., SOA region) 808 may comprise the same gain material. In some cases, one or both the laser section 806 and the SOA (e.g., SOA region) 808 may comprise longitudinally segmented electrodes. The laser section 806 may comprise longitudinally segmented electrodes similar to the electrodes 310, 320, 610, or 620 (in FIGS. 3B-3C, and 6A-6B), or longitudinally and laterally segmented electrodes similar to the electrodes 450, 460, 710, or 720 (in FIGS. 7A-7B).

The MOPA 805 comprises a flared laser section 810 and a flared optical amplifier section 812 comprising flared pumped gain regions. In some examples, the flared pumped gain regions may comprise flared waveguides and/or flared electrodes. In some implementations, the laser (e.g., flared laser section) 810 and the SOA 812 may comprise the same gain material. In some cases, one or both the laser section 810 and the optical amplifier section 812 may comprise longitudinally segmented electrodes similar to the electrodes 610, 620 (shown in FIGS. 6A-6B) or longitudinally and laterally segmented electrodes similar to the electrodes 710, or 720 (shown in FIG. 7A-7B).

The MOPA 807 comprises a flared laser section 814 comprising a flared pumped gain region and/or a flared waveguide and a semiconductor optical amplifier (SOA) 816 comprising a rectangular active waveguide. In some implementations, the laser 814 and the SOA 816 may comprise the same gain material. In some cases, one or both the laser 814 and the SOA 816 may comprise longitudinally segmented electrodes. The laser 814 may comprise longitudinally segmented electrodes similar to the electrodes 610, 620 (in FIGS. 6A-6B) or longitudinally and laterally segmented electrodes similar to the electrodes 710, or 720 (in FIG. 7A-7B). The SOA region 808 may comprise longitudinally segmented electrodes similar to the electrodes 310, 320 (in FIGS. 3B-3C), or longitudinally and laterally segmented electrodes similar to the electrodes 450, or 460 (in FIGS. 4B-4C).

In various implementations, one or more electronic systems may provide currents and/or voltages to the longitudinally segmented electrodes of the laser 802/806/810/814 and/or the SOA regions 804/808/812/816. The one or more electronic systems may include, single channel or multichannel voltage or current sources. In some cases, the one or more electronic systems may comprise at least one non-transitional memory storing machine-executable instructions and at least one processor configured to execute the machine-executable instructions to control currents and/or voltages provided to the longitudinal electrode segments of the laser and/or SOA.

In some implementations, the laser sections 802, 806, 810, or 804 may be replaced by an additional optical amplifier configured to pre-amplify light received from a optical device and provide the resulting pre-amplified light to the SOA regions 804, 808, 812, or 816 respectively (for further power amplification).

In some implementations, the laser sections 802, 806, 810, or 804 may be replaced by a passive waveguide configured to receive light from a optical device and provide a light beam having a single lateral mode profile to the SOA (e.g., SOA regions) 804, 808, 812, or 816, respectively.

Accordingly, in some cases, the optical devices 801, 803, 805, and 807 can function as optical amplifiers.

In various implementations, a rectangular shape pumped gain region can be a gain layer pumped by a rectangular electrode and a flared pumped gain region can be gain layer pumped by a flared electrode. In some, examples, the rectangular electrode or the flared electrodes may comprise segmented electrodes. In some, cases a flared electrode may comprise a patterned electrode, e.g., having a lateral width that undulates along the longitudinal direction (e.g., parallel to a direction of propagation of light in the optical device), and an average width that monotonically increases along the longitudinal direction.

### Additional Embodiments for Spatial and Temporal Control of Drive Currents

Some of the designs and methods disclosed herein pertains to controlling (e.g., individually controlling) one or more drive currents provided to one or more regions or sections of an optical gain layer in an optical gain device (herein referred to as optical device) that provides optical gain. In various implementations, an optical device can be a semiconductor laser, an optical amplifier, or a MOPA. In some cases, the optical amplifier may comprise a pre-amplifier section and a power amplifier section. In some examples, the pre-amplifier section may comprise a non-flared optical gain section, and the power amplifier section may comprise a flared optical gain section. In some cases, a pumped region of the optical gain layer may comprise any shape including a shape that is flared, non-flared, or undulating, along a longitudinal direction parallel to the direction of propagation of light in the optical device.

In some cases, the one or more drive currents may be provided to one or more regions or sections of the optical gain layer via individual electrode segments of a segmented electrode disposed above and/or below the optical gain layer. In some cases, a current provided to a section or region of the optical gain layer may be temporally controlled.

In some cases, one or more drive signals may be supplied to one or more electrode segments of an optical device by an application-specific integrated circuit (ASIC) to generate a drive current distribution over the corresponding optical gain layer. Advantageously, an ASIC can be a customized circuit having a smaller size and a more stable performance. In some cases, an ASIC can provide more accurate and customizable distribution of drive currents to the corresponding optical gain layer in spatial domain, time domains, or both as compared to other electronic control systems. The drive currents may vary by electrode segments of a segmented electrode (adjusted spatial distribution), and/or may vary in time (adjusted temporal distribution). Spatial and/or temporal adjustment of the drive current(s) may allow an optical device to be scaled to longer lengths and provide higher levels of optical power while potentially maintaining a high beam quality, e.g., under varying external conditions (environmental condition such as temperature, humidity, and the like).

In some cases, a drive current or drive current distribution provided to a high power optical device (e.g., a MOPA) may be spatially tailored and/or temporally controlled to provide an output power and/or a conversion efficiency similar to a conventional broad area laser, however unlike the conventional broad area laser, an output light beam of such optical device can be a diffraction-limited or near diffraction limited light beam. In some cases, an optical gain layer of the conventional broad area laser and that of the optical device (e.g., pumped by a controlled drive current distribution) may have a substantially equal length and thickness, or volume.

In various implementations, a drive current distribution in an optical gain layer of an optical device may be temporally and/or spatially tailored or controlled to: improve an efficiency (e.g., slope efficiency or electrical-to-optical conversion efficiency) of the optical device, reduce a threshold current of the optical device, reduce, modify, or tailor the heat generation or thermal profile in the optical device, improve the stability of a parameter of the optical device (e.g., efficiency, temperature, temperature distribution, optical gain spectrum, and/or spatial modes, or other parameters), improve a quality of a light beam generated by the optical device, or improve the stability of various parameters of a light beam generated by the optical device (e.g., spatial intensity distribution, spectrum, optical power, polarization, or other parameters) or any combination of these.

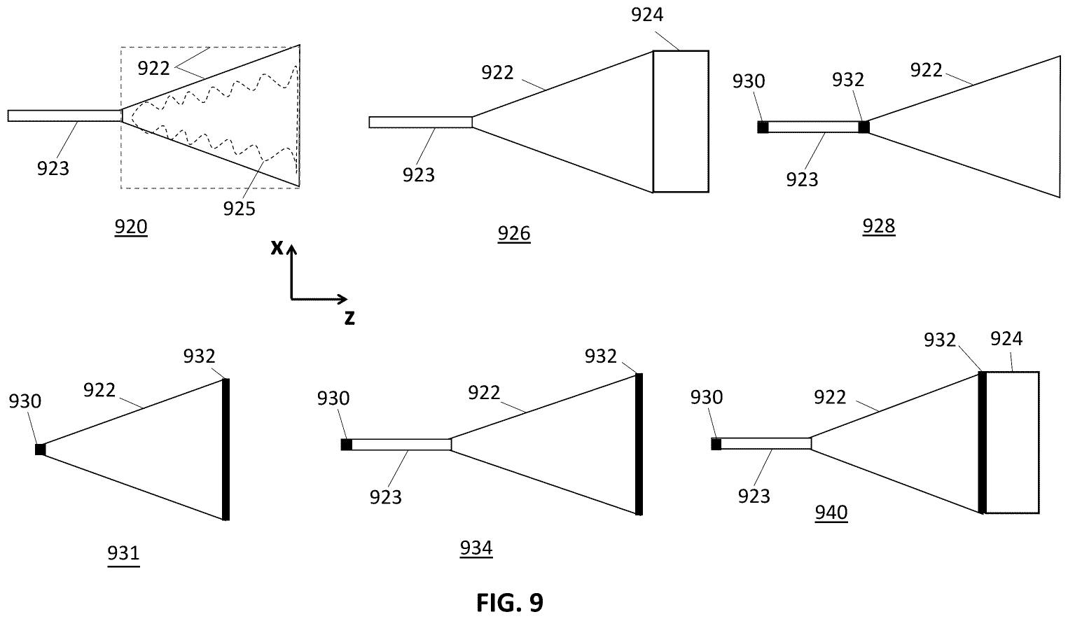

FIG. 9 illustrates additional optical device designs (e.g., laser, optical amplifier, and MOPA designs), which may be pumped using a drive current distribution tailored or controlled in one or both spatial and temporal domains. In some cases, the drive current distribution may be generated by individual segments of a segmented electrode disposed above and/or below a region of the optical device designs shown in FIG. 9, upon receiving individually controlled drive signals from an electronic control circuit (e.g., an ASIC). Each optical device design may include at least a first optical waveguide region 922 that can provide optical gain upon being pumped by an injection current distribution over the first waveguide region. The first optical waveguide region 922 that extends from an input port to an output port in a longitudinal direction (e.g., z-direction) may comprise a flared optical gain region. In some examples, the flared optical gain region may have a lateral width, in a lateral direction (e.g., x-direction) perpendicular to the longitudinal direction. In some cases, the waveguide region 922 is flared and its lateral width may increase (linearly or non-linearly) from the input port to the output port. In some other cases, the waveguide region 922 is non-flared and its lateral width may remain constant from the input port to the output port. For a given operational wavelength of the optical array 902, the lateral width of the first waveguide region 922 can be large enough to support propagation of at least one high order lateral optical mode. In various implementations, a pumped region of the first waveguide region 922 may be configured to provide more optical gain to a fundamental lateral mode compared to higher order lateral modes. For example, a pumped region of the first waveguide region 922 can be flared. In some cases, a pumped region of a non-flared waveguide region can be flared. The pumped region may be a region receiving injection current from a patterned (e.g., flared) electrode and/or via a patterned (e.g., flared) dielectric layer. A flared electrode or dielectric layer pumped region may have a lateral width (or an average lateral width) that increases (linearly or non-linearly) from the input port to the output port of the first waveguide region 922. In some cases, a flared electrode can be a flared segmented electrode where at least some of different segments are configured to provide different injection current/voltage to a corresponding pumped segments of the first waveguide region 922. In some cases, a flared electrode can be a top or bottom electrode.

In some cases, a flared electrode can be a flared patterned electrode 925 configured to generate an injection distribution across the first waveguide region 922 that selectively amplifies a fundamental lateral mode of the first waveguide region 922. For example, a lateral width of the flared patterned electrode 925 may undulate along a longitudinal direction (parallel to the direction of propagation of light in the optical device), while its average lateral width increases along the longitudinal direction. The flared patterned electrode 925 may comprise electrically isolated electrode segments.

In some examples, the first waveguide region 922 may comprise any shape having a lateral width (e.g., parallel to x-axis) that varies or undulates along the longitudinal direction (e.g., parallel to z-axis).

In some cases, an optical device may comprise a second waveguide region 923 that is not flared or does not include a flared pumped region. The second optical waveguide region 923 may be optically connected to the input port of the first waveguide region 922. For example, the second waveguide region 923 may extend from a first end to a second end, and the first waveguide region 922 may extend from the second end to a third end (output port) where the second end or the interface between the first and second waveguide regions 922, 923, is the input port of the first waveguide region 922. The second waveguide region 923 can be an active waveguide capable of providing optical gain, or a passive waveguide. In some cases, a reflector may be disposed at the first end of the second waveguide region 923, at the interface between the first and the second waveguide regions 922, 923, or at the output port of the first waveguide region 922. In some cases, the first and/or the second waveguide regions 922, 923 may include a phase section. A phase section can be a section that thermo-optically or electro-optically controls the light (e.g., the phase of the light) passing through the phase section based on a control signal received from the feedback control section 910. The phase section may, for example, introduce a phase shift that can be varied based on the signal applied to the phase shift section. The phase section may include an electrode (e.g., disposed above or near the region waveguide), which is electrically connected to a feedback control circuit (e.g., an ASIC).

The optical devices 920 and 926 can be an optical amplifier. The optical amplifier 920 includes a first waveguide region 922 that provides gain and a second waveguide region 923 that may or may not provide optical gain. The optical amplifier 926 includes a first wave guide region 922 that provides gain, a second waveguide region 923 that may or may not provide optical gain, and a third waveguide region 924 that provides optical gain (upon being pumped). The first waveguide region 922 can be a flared waveguide region or include a flared optical gain region, the second waveguide region 923 is a non-flared waveguide region. In some cases, the second waveguide region 923 comprises an optical pre-amplifier and the first and the third waveguide regions 922, 924 comprise power optical amplifiers. In some cases, the optical amplifiers 920, 926, may not include the second waveguide 923.

The optical device 928 can be a MOPA. MOPA 928 includes a first wave guide region 922 and a second waveguide region 923 that both provide optical gain upon being pumped. The MOPA 928 further includes a first reflector 930 disposed at the first end of the second waveguide region 923, and a second reflector 932 at the interface between the first and the second waveguide regions 922, 923. The first reflector 930, the second waveguide region 923, and the second reflector 932 form a laser (e.g., a master oscillator) and the first wave guide region 922 serves as an optical amplifier.

The optical device 931 can be a flared laser. The flared laser 931 includes a first wave guide region 922 a first reflector 930 and a second reflector 932 disposed at the input and output ports of the first wave guide region 922, respectively. The flared laser 934 includes a first wave guide region 922 that provides optical gain (upon being pumped), and a second waveguide region 923 that may or may not provide optical gain. The flared laser 934 further includes a first reflector 930 disposed at the first end of the second waveguide region 923, and a second reflector 932 disposed at the output port of the first waveguide region 922. In some cases, the flared laser 934 may be configured to sustain and amplify light having a fundamental lateral mode profile by filtering out the high order lateral modes, using a selective optical loss mechanism that reduces a power of the high order lateral modes along the cavity formed between the first and the second mirrors 930, 932. The MOPA 940 includes the flared laser 934 optically connected to a non-flared optical amplifier 924.

In various implementations, the first waveguide region 922 of any of the amplifiers, lasers, or MOPAs described above may comprise patterned, segmented, or patterned and segmented electrode. A patterned electrode can have a lateral width that changes (e.g., undulates, increase, or decreases) along the longitudinal direction. A flared electrode can have a lateral width or an average with that increases (e.g., monotonically) in a longitudinal direction (parallel to the direction of propagation of light). A segmented electrode may comprise a plurality of longitudinal or lateral electrode segments, or both. As such a patterned electrode can be a patterned flared electrode, can be a patterned segmented electrode, or a patterned, flared and segmented electrode.

Additionally or alternatively, the first waveguide region 922 may comprise a patterned, segmented, or patterned and segmented current control layer. In various examples, a patterned electrode or current control layer may comprise any shape including a flared shape having a lateral width or an average lateral width that increases along the longitudinal direction, a shape having a lateral width undulating along the longitudinal direction, or other shapes. A current control layer may comprise a dielectric layer or ion implanted layer, and/or a conductive layer configured to provide a current distribution across an optical gain layer of the flared waveguide region 922 such that the optical gain layer selectively provides more gain to the fundamental lateral mode of the flared waveguide layer 922 compared to higher order lateral modes.

In some cases, the second waveguide section (or region) 923 may comprise a longitudinally segmented electrode. Such a longitudinally segmented electrode may be used to independently control the longitudinal injection current distribution along the second waveguide section (or region) 923 to increase the efficiency of the master oscillator (laser), e.g., by mitigating longitudinal current crowding in the laser cavity such as, for example, described above.

As described above, drive currents provided to an optical device may be varied by individual optical gain sections or regions (spatial adjustment) and/or may be varied in time (temporal adjustment), to improve a performance (e.g., higher efficiency, higher output power, etc.) or stability (e.g., more stable output power) of the optical device, and/or a quality of a light beam generated by the optical device (e.g., spatial distribution of an optical intensity in et light beam). In some cases, improving a performance, or beam quality may comprise maintaining a performance, or beam quality under varying environmental condition or in the presence of change in a power supply that provides electrical power to the optical system comprising the optical device and the electronic control system (e.g., ASIC). In some cases, varying drive currents in time or spatial domain may comprise dynamically and/or adaptively controlling the drive signals (e.g., based on a sensor signal). A drive signal applied to an electrode segment generates a drive current in a corresponding region of the optical gain layer. In some cases, a drive signal may comprise the drive current. In some cases, a drive signal can be a voltage or current (e.g., equal or different from the drive current).

In some cases, spatial adjustment of drive currents comprise driving a single semiconductor laser or optical amplifier with more than one drive signal generating circuit using a multi-channel ASIC and/or multiple ASIC chips. In some cases, these drive signal generating circuits may generate drive signals that differ from each other. In some examples, however drive signals generated by two or more channels, or drive current generating circuits, may be substantially equal. A drive signal (and the corresponding drive current) can be a continuous wave (CW) or a pulsed signal having any pulse shape, duty cycle, and pulse duration. The individual drive signal generating circuits or channels may be electrically connected to different individual electrode segments of a segmented electrode disposed above or below the laser or the optical amplifier. In some cases, an individual drive signal generating circuit or channel may be electrically connected to a single non-segmented electrode of the laser or the optical amplifier. In some case, two or more electrode segments can be electrically connected to the same signal generating circuit or channel. In some cases, fabrication of the segmented electrode may comprise, for example, patterning gaps in a metal electrode (e.g., a thick metal electrode) disposed on the p-side (above) or n-side (below) of the laser or the optical amplifier, etching into the upper conductive layers of the epi to electrically isolate different segments, or etching through the QWs to optically and electrically isolate the corresponding regions of the optical gain layer. In various implementations, forming a segmented electrode comprises selective regrowth, ion implantation, tailoring an etch depth profile, or other growth or fabrication method that may electrically isolate the electrode segments and the corresponding regions of the laser or optical amplifier. In some cases, a corresponding region of the laser or optical amplifier may comprise a region (e.g., in the active layer) below an electrode segment where the region is a projection of the electrode segment and thereby has substantially the same shape, area, and size as the electrode segment (e.g., to within a tolerance possibly affected by distance of active layer from the electrode segment). In some cases, a corresponding region of the laser or optical amplifier may comprise a region below an electrode segment that is configured to receive drive current from the electrode segment. In some cases, the segmented electrode can be in contact with a substrate or heat sink on which the laser or optical amplifier in is mounted. An example of such a configuration was shown in FIG. 5 above where the laser or optical amplifier 500 was mounted on a submount 501 having a segmented electrode (e.g., segmented p-side electrode, or segmented n-side electrode) comprising three electrically isolated segments (506a, 506b, 506c). In some cases, individual conductive pads 506a/506b/506c may be electrically connected to individual longitudinal segments of the top electrode of the laser or optical amplifier 500. In some cases, the electronic control system 504 that provides drive signals (e.g., drive voltage and/or a currents) to electrode segments 506a/506b/506c may comprise an ASIC. The segmentation of electrode and/or the corresponding regions of the laser or optical amplifier may comprise segmentation in lateral and/or longitudinal directions and may comprise any shape, pattern, or periodicity. The longitudinal direction can be a direction parallel to a direction of propagation of light in the laser or optical amplifier (e.g., parallel to z-axis), and the lateral direction can be a direction perpendicular to the longitudinal direction and parallel to a major surface of an optical gain layer of the laser or optical amplifier (e.g., parallel to x-axis).

In some cases, the electronic control system (ASIC) 504 can be programmed to provide three different currents (I₁, 12, and 13) to three different longitudinal sections of the semiconductor laser (or optical amplifier) 500 to engineer a thermal profile, a carrier density profile, or other parameters along the laser cavity. Similarly, a laterally segmented electrode may provide different drive currents to different lateral regions of the laser cavity to engineer a lateral thermal profile, or lateral carrier density profile within the laser cavity. In some cases, the lateral and/or longitudinal thermal and carrier density profile may be engineered to control, reduce, or prevent thermal and carrier density lensing effects within a laser or an optical amplifier, e.g., when as an optical mode propagates and expands along a flared waveguide or a flared optical gain region (a pumped region).

In some cases, temporal adjustment or control of drive currents may comprise changing a drive signal or current (e.g., an individual drive signal provided to an electrode segment or to a plurality of electrode segments) over a time period. In some examples, drive currents generated by one or more drive current generating circuits can be time varying or temporally adjusted. In some cases, a circuit (e.g., a channel of an ASIC) may provide a constant drive signal to an electrode segment or segments of an optical device while another circuit (e.g., another channel of an ASIC) provides a pulsed drive signal to another electrode segment or segments of the same lights source. In some cases, drive signals provided by two circuits (e.g., two channels of an ASIC) may be time varying and may have different temporal profiles (e.g., pulse width, period, amplitude, etc.).

In some implementations, the temporal control or adjustment of the drive currents may comprise open-loop control where the ASIC adjusts the drive currents without using any feedback signal associated with real-time measurements. For example, the ASIC may adjust the drive currents based on preprogrammed instructions (e.g., machine readable instructions stored in a non-transitory memory of the ASIC). In some other implementations, the temporal adjustment of the drive currents may comprise closed-loop control, where the ASIC adjusts the drive currents in response to at least one feedback signal associated with a real-time measurement of a parameter of the optical device, of the light beam generated by the optical device, or an environment of the optical device, or any combination thereof. For example, the measured parameter can include optical power generated by an optical device (e.g., laser, optical amplifier, or MOPA), a beam parameter indicative of a quality of a light beam generated by the optical device, for example, spatial intensity distribution in the light beam, a phase of the light beam, a spectrum of the light generated by the optical device, a linewidth of the light generated by the optical device, a difference between a target wavelength and measured wavelength of the light generated by the optical device, a voltage drop across the optical device, a measured temperature (e.g., temperature of the optical device or the surrounding medium), or atmospheric conditions such as temperature, radiation, or humidity, or any combination thereof or possibly other parameters not listed above.

The closed-loop adjustment can be used to stabilize a parameter of the optical device, or the light beam generated by the optical device, which would otherwise vary without temporal adjustment of the drive current (e.g., a parameter that may be unstable due to heating, various non-uniformities in the laser or amplifier, or changing atmospheric conditions). Using this approach, the optical device may be directly adjusted to compensate for a varying condition, e.g., atmospheric turbulence or scintillation. Accordingly, the measured parameter may include a stability parameter indicative of stability of any one or more of the above parameters during a measurement period. In some cases, these on-chip corrections may reduce or eliminate the need for adaptive optics or other compensation techniques that are employed in high power laser applications.

Alternatively or in addition, the ASIC may be programed to modulate or change a parameter of the optical device over a time period. For example, the ASIC may adjust drive currents provided to the optical device to change a wavelength (e.g., a centroid wavelength), an optical output power of the optical device, or steer the light beam generated by the optical device over time. In various implementations, the ASIC may adjust or control drive currents provided to the optical device to spatially and/or temporally modulate a parameter of the light beam generated by the optical device.

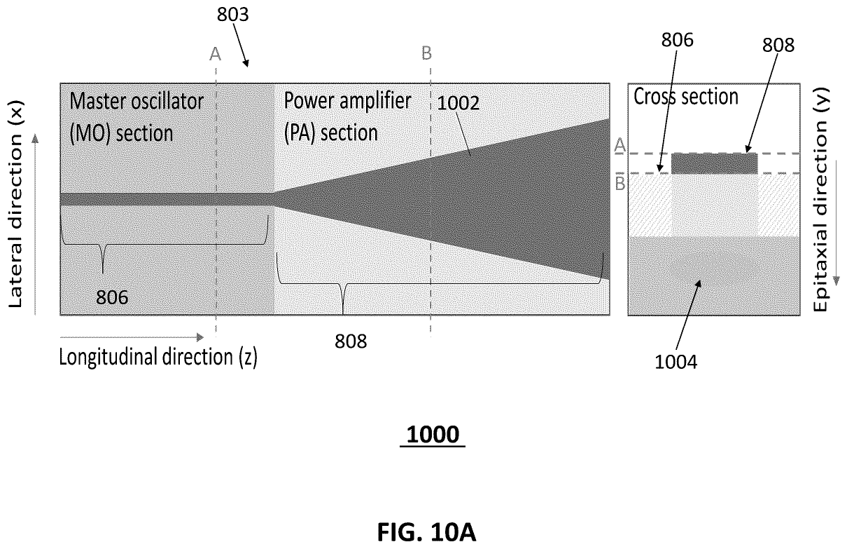

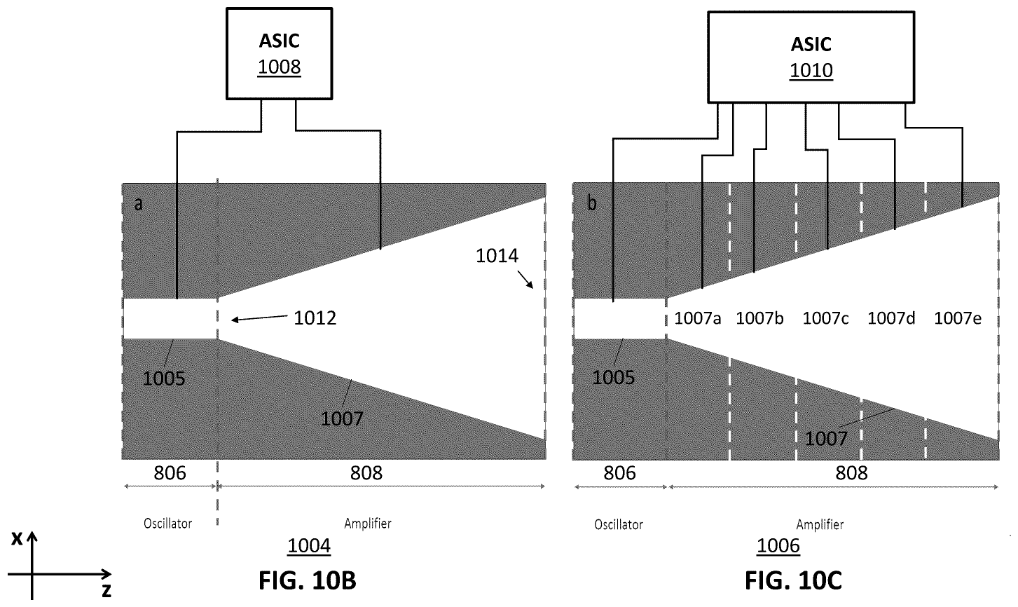

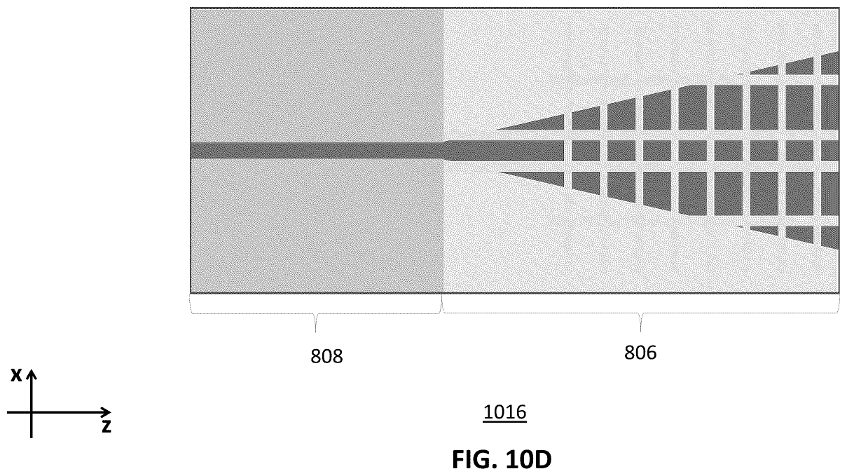

FIG. 10A is a schematic diagram illustrating the MOPA 803 having a longitudinally segmented electrode configured to provide independent drive currents (injection currents) to a laser section 806 and an amplifier section (or region) 808 of the MOPA 803. The left panel illustrates a top view of the MOPA 803. The right panel illustrates two vertical cross-sections of the MOPA 803 at two different longitudinal positions A and B along the MOPA 803, showing a cross-section of the laser section 806 and the optical amplifier section 806, respectively. In some examples, single-mode laser oscillation occurs within an etched ridge waveguide of the master oscillator (MO) section 806 (laser section). Light from the MO section 806 is then provided to a power amplifier (PA) section (e.g., SOA region) 808. In some cases, the PA section 808 may comprise an unetched section (e.g. a slab waveguide) where the optical mode freely expands in the lateral (parallel to x-direction) and longitudinal (parallel to z-direction) directions. An electrode (an electrically conductive layer) 1002 is used to electrically pump a region of the optical gain layer below the electrode 1002 to amplify the optical mode as it propagates. In some cases, the electrode 1002 can be a flared electrode as described above. The light beam provided from the MO section 806 to the PA section 808 can have a single mode lateral distribution and comprise a substantially diffraction limited beam. In some cases, the electrode 1002 may be configured to amplify the light beam received from the MO section 806 while preserving a high-beam quality of the mode, e.g., by outputting an amplified light beam having a single lateral mode and a diffraction limited beam profile.

FIGS. 10B-10C are schematic diagrams illustrating MOPAs having segmented electrodes controlled by an Application Specific Integrated Circuit (ASIC).

FIG. 10B shows a MOPA 1004 similar to MOPA 803 comprising a laser section 806 and a flared optical amplifier section 808. Two electrically isolated electrodes 1005, 1007 provide independently controlled drive currents to the laser section (oscillator) 808 and the optical amplifier section (808). In some cases, the laser section 806 comprises a rectangular waveguide (e.g., a single mode waveguide) and the optical amplifier section 808 comprises a slab waveguide that supports multiple lateral modes. In some such cases, the second electrode 1007 is a flared electrode configured to pump a flared region of the slab waveguide.

In some examples, when the MOPA 1004 is a pulsed optical device, an ASIC 1008 may adjust a drive current provided to the laser (oscillator) section 806 to produce an output light (optical) pulse with “clean” temporal, spatial, and spectral properties. In some examples, an output light pulse with “clean” temporal properties may comprise a light pulse having a spectral and/or spatial properties that change minimally throughout the duration of the pulse or through time after multiple pulses, and an output light pulse with “clean” spatial and spectral properties may comprise a light pulse having one or few spatial modes and/or modes having different spectral properties. The timing, duration, and/or magnitude of the output light (optical) pulse generated by the laser section 806 can be limited by the constraints on temporal and spectral properties of the output light pulse.

In some examples, the ASIC 1008 may tailor or control a drive current distribution over the optical gain layer of an optical amplifier section 808 such that a beam of light (e.g., a pulsed or CW beam of light) that is received from an input port 1012 of the optical amplifier section 806, and is amplified as it propagates in the optical amplifier, reaches a maximum power or energy at an output port 1014 of the optical amplifier section 808 and not in a longitudinal position before the output port 1014. In some cases, controlling individual drive currents provided to individual longitudinal sections of the optical amplifier section 808 may cause or enhance amplification of a power or energy of a beam of light substantially along the entire optical path from the input port 1012 to the output port 1014.

FIG. 10C shows a MOPA 1006 similar to the MOPA 1004 but with five electrically isolated longitudinal electrode sections (1007a-1007e) over the optical amplifier section 808 for independently controlling five corresponding longitudinal sections of the optical amplifier section 806. In some cases, for example when the laser section 806 comprises a pulsed laser, if a light pulse is excessively amplified in the amplifier sections closer to the input port 1012, it may reach a peak energy while still propagating in the amplifier section 806. In some such cases, a portion of the pulse energy may be absorbed before the light pulse reaches the output port 1014, leading to lower efficiency and possibly failure of the MOPA 1006. Advantageously, an ASIC 1010 may be used to adjust or controls, for example, five individual drive signals provided to the electrode sections 1007a-1007e (and thereby drive current provided to the corresponding longitudinal sections), such that the energy of a light pulse received from the laser section 806 and propagating in the optical amplifier section 808 reaches its maximum energy at the output port 1014 of the optical amplifier section 806. In some examples, the drive signals provided to electrode sections (or segments) 1007a-1007e of the flared electrode 1007 may be adjusted such that the resulting drive currents provided to the corresponding subsections of the optical amplifier section 808 increase from the input port to the output port along the longitudinal direction (e.g., parallel to z-axis), e.g., to account for the increase in active volume (pumped region) of the optical amplifier associated with the flared electrode 1007.

FIG. 10D is a schematic diagram illustrating a MOPA 1016 similar to MOPA 1004 but having a laterally (e.g., parallel to x-axis) and longitudinally (e.g., parallel to z-axis) segmented electrode disposed over the optical amplifier section 806. Such segmented electrode can be configured to provide independent drive currents to different lateral and longitudinal regions of the flared optical amplifier section 806. In some implementations, the drive currents may be longitudinally tailored such that a level of optical gain provided by an individual longitudinal subsection of the optical amplifier section 808 is adjusted according to the energy or power of light received by that individual longitudinal subsection. In some examples, the drive currents may be laterally tailored such that a level of optical gain provided to an individual lateral subsection of the optical amplifier section 808 is adjusted according to a portion of the energy or power of a fundamental lateral mode of the flared optical amplifier section 808 light that passes through the individual lateral subsection.

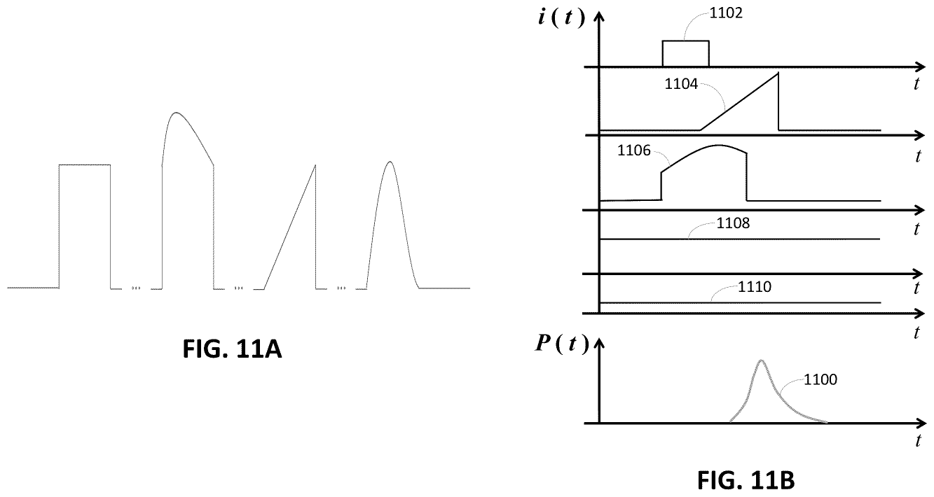

For applications where one or more sections of a laser, amplifier, or MOPA are pulsed, the pulses supplied by the ASIC can have any arbitrary shape, duration, and/or duty cycle, and the pulse and/or pulse train characteristics can vary from one electrode to another electrode segment. In some cases, the individual drive signals provided to individual electrode segments can be adjusted to control a beam shape, a temperature profile, a refractive index profile, an optical absorption profile, an optical gain profile, a carrier dynamic profile, or any combination thereof or possibly a distribution of other parameters. FIG. 11A is a schematic diagram illustrating example pulse shapes that may be supplied, e.g., by an ASIC, to one or more segments of a segmented electrode (e.g., the segmented electrodes shown in FIG. 3B-3C, 4B-4C, 5, 6A-6B, 7A-7B, 10A-C, or 10D).

The drive signals provided to electrode segments (e.g., by different channels of an ASIC or by different ASICs) may comprise pulses, or CW signals. For example a portion of the drive signals may be pulsed and the rest can be CW. In some cases, all the drive signals can be pulsed or CW. FIG. 11B is a schematic diagram illustrating example drive signals (e.g., drive currents) 1102-1110 that may be supplied to five different electrode segments of a segmented electrode disposed on an optical device (e.g., a laser, optical amplifier, a laser section of a MOPA, or an optical amplifier section of a MOPA), and a resulting optical pulse 1100 output by the corresponding optical device. For example, the drive signals 1102-1110 may be provided to different segments of the segmented electrodes shown in FIG. 3B-3C, 4B-4C, 5, 6A-6B, 7A-7B, 10A-C, or 10D. In some cases, magnitude of the drive signals 1108/1110, the amplitudes, and pulse shapes of the drive signals 1102/1104/1106 and their relative delays or any combination of these, may be adjusted to maintain a shape, an amplitude, a bandwidth, or combination thereof or possibly other parameters of the optical pulse 1100 within a target rage. In some cases, the target range can be a predefined range or a range determined based on a sensor signal (e.g., indicative of a laser temperature or environmental condition).

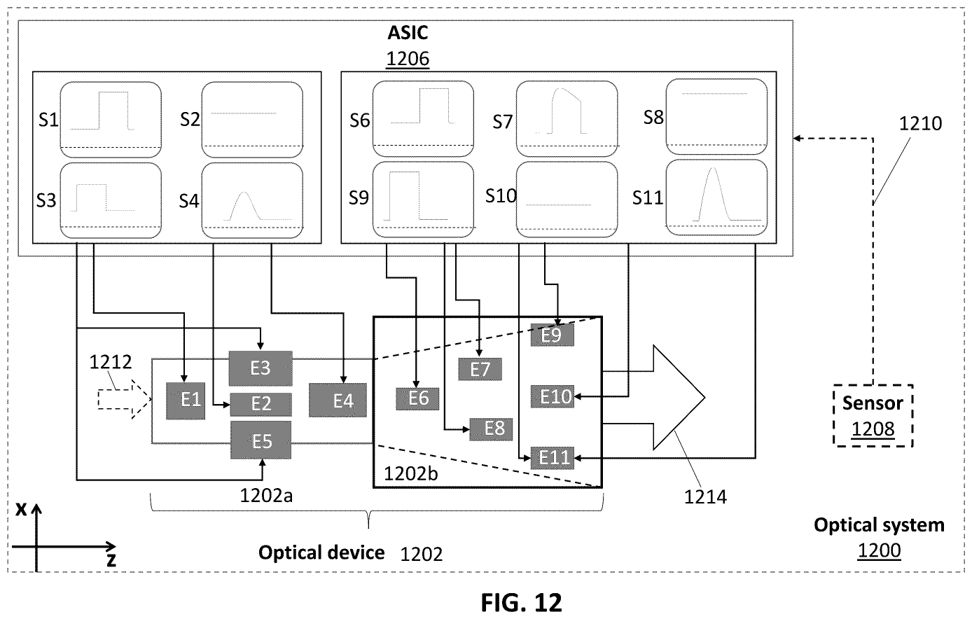

FIG. 12 is a schematic diagram illustrating an example optical system 1200 including an optical device 1202 and an ASIC 1206 that provides controlled drive signals to electrode segments E1-E11 of the optical device 1202. The optical device 1202 includes a first section 1202a and a second section 1202b. In some cases, the first section 1202a comprises an optical pre-amplifier, the second section 1202b comprises an optical amplifier (e.g., an optical power amplifier), and the optical device 1202 comprises an optical amplifier configured to receive an input light beam 1212 and generate an amplified light beam 1214. In some cases, the first section 1202a comprises a laser, and the second section 1202b comprises an optical amplifier, and the optical device 1202 comprises a MOPA configured to generate an output light beam 1214.

While in the example shown, both the first section 1202a and the optical amplifier section 1202b are driven using segmented electrodes, in some implementations, one of them may have a non-segmented electrodes. In some examples, an individual electrode segment may receive an individual drive signal generated by an individual channel or output of the ASIC 1206. In some examples, two or more electrode segments may receive a drive signal generated by an individual channel or output of the ASIC 1206.

In the example shown, four individual electrode segments (E1-E4) of the first section 1202a receive four individual drive signals (S1-S4) from four individual channels of the ASIC 1206. In some cases, the four individual channels may be controlled independently. The four individual drive signals (S1-S4) may comprise constant or time varying signals. The four individual drive signals (S1-S4) may have different amplitudes and/or different temporal behaviors. An individual drive signal may be determined based on one or more of the location, shape, size and/or other characteristic(s) of the corresponding electrode segment that receives the individual drive signal.

In the example shown, a first segmented electrode independently controls drive currents provided to three longitudinal regions of the first section 1202a. The first segmented electrode controls the drive current in the first longitudinal region using a first electrode segment (E1) closer to a back reflector of the first section 1202a, controls the drive current in the second longitudinal region using second, third, and fifth electrode segments (E2, E3, E5) where each electrode segment controls the drive current in a different lateral section of the second longitudinal region, and controls the drive current in the third longitudinal region using a fourth electrode segment (E4) closer to a front reflector of the first section 1202a. In the example shown, the electrode segments E3 and E5 are driven by the same drive signal (S3), and the electrode segments E1, E2, and E4 are driven by three different drive signals S1, S2, and S5 respectively. The drive signal S2 has a constant amplitude, while drive signals S1, S3, and S4 comprise time varying signals having different amplitudes and temporal behaviors. In some cases, the drive signals (S1-S4) may be configured to cause generation of a laser pulse by the first section 1202a. In some cases, the drive signals (S1-S4) may be configured to cause generation of a periodic laser pulse train comprising substantially similar laser pulses, where at least one of the drive signals (S1-S5) comprise a period signal having a period substantially equal to the periodic of the laser pulse train.

With continued reference to FIG. 12, a second segmented electrode independently controls drive currents provided to three longitudinal regions of the optical amplifier section 1202b. The second segmented electrode comprises five individual electrode segments (E6-E11) that receive five individual drive signals (S6-S11) from five individual channels of the ASIC 1206. In some cases, the five individual channels may be controlled independently. The five individual drive signals (S6-S11) may comprise constant or time varying signals. The five individual drive signals (S6-S11) may have different amplitudes and/or different temporal behaviors. An individual drive signal may be determined based on one or more of a location, shape, or size or other characteristic(s) of the corresponding electrode segment that receives the individual drive signal.

In some cases, the ASIC 1206 adjusts or controls the drive current in the first longitudinal region using a sixth electrode segment (E6) closer to an input port of the reflector of the optical amplifier section 1202b, controls the drive current in the second longitudinal region using seventh and third eight electrode segments (E7-E8) where each electrode segment controls the drive current in a different lateral section of the second longitudinal region, and controls the drive current in the third longitudinal region using ninth, tenth, and eleventh electrode segments (E9-E11), disposed closer to an output port of the optical amplifier section 1202b, where each electrode segment controls the drive current in a different lateral section of the third longitudinal region. In some cases, the electrode segments E6-E11 are configured to provide a flared drive current distribution along optical amplifier section 1202b. In some cases, a width of the flared drive current distribution along a lateral direction may increase along a longitudinal direction extending from the input port to the output port of the optical amplifier section 1202b. In the example shown, the electrode segments E6-E11 are driven by the drive signals S6-S11 respectively. The drive signal S10 has a constant amplitude, while drive signals S6-S9, and S11 comprise time varying signals having different amplitudes and temporal behaviors.

In some implementations, the optical system 1200 can be a pulsed optical device of an emission system, e.g., emission system of a time-of-flight LiDAR. In some such implementations, the ASIC 1206 may be programmed to dynamically control the drive currents in sync with the propagation of the light pulse through the optical device. For example, as the light pulse propagates longitudinally through the optical device 1202, the longitudinal sections of the optical device 1202 may be powered one at a time in sequence, rather than all at once. Such sequential activation of gain sections may reduce the power consumption of the optical system 1200 (or the total current provided to the optical device 1202), by providing the electrical power to an individual section of the optical device when optical pulse is propagating in the individual section.

In some cases, a magnitude of a first drive signal provided to first electrode segments can be above a first threshold level during a first period and a magnitude of a second drive signal provided to a second electrode segment can be above a second threshold level during a second period after the first period. In some cases, the first threshold level and second threshold levels can be threshold levels for generating drive currents sufficient for providing an optical gain larger than 1 in the corresponding regions of the gain layer below the first and the second electrode segments respectively. In some cases, the ASIC 1206 may determine a delay between the first and the second periods based at least in part on a longitudinal distance between the first and the second electrode segments. In some cases, the first threshold level and the second threshold level can be substantially equal. In some cases, the first threshold level can be larger than the second threshold level.

In some implementations, the ASIC 1206 may adjust, or control drive currents provided to the electrode segments E1-E11 to spatially and/or temporally modulate a parameter of a light beam generated by the optical device 1202. For example, the ASIC 1206 may adjust drive currents provided to the electrode segments E1-E11 to change any one or more of a wavelength (e.g., a centroid wavelength) of the light beam, an optical output power of the light beam, a direction of propagation of the light beam (e.g., to steer the light beam), a polarization of the light beam, a divergence of the light beam, or spatial distribution of optical intensity across the light beam.

In some implementations, e.g., when the ASIC 1206 adjusts the drive signals provided to the electrode segments (E1-E11) of the optical device 1202 in a closed-loop control mode, the optical system 1200 may include at least one sensor 1208 for measuring at least one parameter of the optical system 1200 and/or its surrounding environment. The at least one sensor 1208 can generate at least one sensor signal 1210 indicative of a measured value of the parameter(s), and transmit the sensor signal(s) 1210 to the ASIC 1206. The ASIC 1206 may adjust or control at a least one drive signal provided to one or more electrode sections based at least in part the sensor signal(s) 1210. Accordingly, in some cases, the sensor(s) 1208 may comprise a plurality of sensors configured to measure a plurality of parameters of the optical system 1200 and/or its surrounding environment, and the sensor signal 1210 may comprise a plurality of sensor signals different signals indicative of a measured value of a different parameter of the plurality of parameters.

In various implementations a parameter can include one or more of the following: optical power generated by the optical device 1202, a beam parameter indicative of a quality of a light beam generated by the optical device 1202 (e.g., indicative of a spatial intensity distribution in the light beam), a phase or phase noise of the light beam, a spectrum of the light beam, a center wavelength and/or a linewidth of the light beam, a voltage drop across the optical device 1202, a measured temperature of the optical device 1202, a temperature and/or a condition (e.g., humidity) inside an enclosure of the optical system 1200, a temperature and/or a condition (e.g., humidity, pressure, radiation) inside an enclosure of the optical system 1200, a temperature and/or a condition (e.g., humidity, pressure, radiation) of medium surrounding the optical system 1200.

In some cases, the ASIC 1206 may adjust or control the individual drive signals provided to different electrode segments possibly to maintain an optical output power, a beam parameter of the a light beam generated by the optical device 1202, a temperature profile a refractive index profile, an optical absorption profile, an optical gain profile, a carrier dynamic profile, or a distribution of other parameters in the optical device 1202.

In some cases, as the ASIC 1206 adjusts the drive currents using open or closed-loop control, it may generate a distribution of drive currents in the optical device 1202 that is non-uniform along one or both lateral and longitudinal directions. In some cases, such non-uniform of distribution of drive currents may improve an efficiency of the optical device 1202, the quality of the output optical beam (e.g., amplified light beam) 1214, or other aspects of optical device 1202 performance, as compared to a drive current distribution that is uniform along one or both lateral and longitudinal directions.

In some examples, at least two drive signals of the drive signals S1-S4, and S6-S11 can have different magnitudes or temporal profiles.

In various implementations, the optical device 1202 and the ASIC 1206, may be enclosed in an enclosure (a common enclosure) of the optical system 1200. In some cases, the sensor 1208 can be enclosed in the enclosure, mounted on an outside surface of the enclosure. In some cases, a volume of the enclosure can be from 100 cm³ to 200 cm³, from 200 cm³ to 300 cm³, from 300 cm³ to 400 cm³, from 400 cm³ to 500 cm³, from 400 cm³ to 500 cm³, from 500 cm³ to 1000 cm³, or any range formed by these values or lager or smaller.

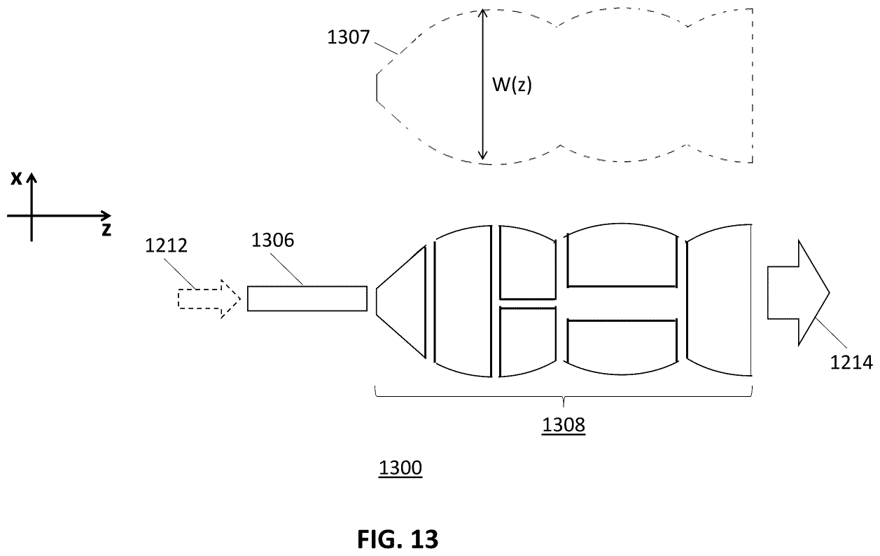

FIG. 13 is a schematic diagram illustrating an example segmented electrode configuration for controlling and/or adjusting drive current distribution in optical gain layer of an optical device 1300. In some cases, the optical device 1300 may comprise a first optical gain region pumped using a first electrode 1306 and a second region pumped by a second electrode 1308 (e.g., a segmented electrode). In some examples, the first region comprises a laser, the second region comprises an amplifier, and the optical device 1300 is a MOPA configured to generate an output light beam 1214. In some examples, the first region comprises an optical pre-amplifier, the second region comprises an optical power amplifier, and the optical device 1300 comprises an optical amplifier configured to receive an input light beam 1212 and generate an amplified light beam 1214.

In various implementations, the second electrode 1308 can comprise a segmented electrode having an envelope 1307 defined by a lateral width W(2) of the second electrode 1308 at different positions along the longitudinal direction (e.g., parallel to the direction of propagation of light in the optical device). In the example shown, the segmented second electrode comprises seven segments within a boundary defined by the envelope 1307. The envelope 1307 can have any shape including a shape that is flared, non-flared, or undulating, along the longitudinal direction.

Optical gain control and tailoring methods described above may be implemented in semiconductor amplifiers used in a LiDAR transmitter or other applications that use a pulsed optical source, e.g., to increase an output optical power, an output peak optical power, and/or an output pulse energy. Methods can be used for other applications as well.

In various implementations, temporal and/or spatial control of the drive current distribution in the optical gain layer of a optical device may allow tuning, improving and/or optimizing a performance, output characteristics stability, and/or reliability of a laser, amplifier, and or a MOPA.

In some implementations, temporal and/or spatial control of the drive current distribution over the optical gain layer of an optical device may allow tuning the astigmatism of the output light beam when the optical device comprises a flared optical gain region, and/or controlling phase noise in the laser (oscillator) and/or the individual sections of the optical amplifier. The latter could be achieved by adjusting the timing of the drive currents provided to the oscillator and multiple gain sections of the optical amplifier. For example, a delay between a drive current provided to the oscillator and a drive current provided to a gain section of the optical amplifier may be adjusted to control of a phase noise and thereby a spectrum of the light output by the light source.

While the systems and designs described above use one or more ASICs (e.g., ASICs 1206) for controlling drive signals (e.g., drive currents) provided to the electrode sections or segments of a semiconductor optical device (e.g., optical device 1202), drive currents may alternatively or additionally (e.g., at least in part) be provided or controlled by other electronic circuits and systems integrated with the optical device 1202 possibly in a common enclosure, or electronic circuits and systems that are connected (e.g., via a wired or wireless link) to the optical system 1200. In some cases, various methods may be used to adjust and control electric drive currents provided to electrode segments of a optical device to improve, adjust, control, stabilize properties of the optical device (e.g., efficiency) and/or an optical beam (e.g., spatial intensity distribution, polarization, optical power, etc.) generated by the optical device or perform any combination of these. These methods can include, for example, controlling a current setting, voltage setting, or power setting of an external electronic circuit or system or an electronic circuit or system included in the optical system (e.g., possibly within a common enclosure). In various implementations, drive signals provided to a semiconductor optical device by an ASIC and/or any other electronic circuit or system, may include constant drive currents (and/or voltages), periodic drive currents (and/or voltages), pulsed drive currents (and/or voltages), time-varying currents (and/or voltages), combination of constant and time-varying currents (and/or voltages), and the like. In some cases, the ASIC and/or any other electronic circuit or system that provides drive signals to a semiconductor light source, may operate based on a range of operational modes and methods having different levels of complexity including but limited to dynamic control and/or adaptive control based on measured conditions of the optical system and/or the optical device therein. Additionally, the ASIC and/or any other electronic circuit or system that provides drive signals to a semiconductor light source, can be pre-programmed (e.g., during manufacturing), programmable in real-time (e.g., by a user), capable of machine learning or any combination thereof.

### Example Embodiments

Example embodiments described herein have several features, no single one of which is indispensable or solely responsible for their desirable attributes. A variety of example systems and methods are provided below.

### Group 1A

Example 1. A semiconductor laser system comprising:
a semiconductor laser comprising:
a front optical reflector,
a back optical reflector,
said front and back optical reflectors disposed with respect to each other to form a laser cavity therebetween,
an active waveguide extending in a longitudinal direction between the front optical reflector and the back optical reflector, wherein said active waveguide comprises a gain layer configured to provide optical gain to light propagating within said active waveguide, said waveguide having a waveguide length along the longitudinal direction and a waveguide width along a lateral direction perpendicular to the longitudinal direction;
an electrode disposed with respect to the active waveguide said electrode comprise a plurality of separate electrically isolated longitudinal segments arranged in the longitudinal direction, wherein an individual longitudinal segment has a length along the longitudinal direction and a width along a lateral direction perpendicular to the longitudinal direction; and
an electronic control system configured to provide individually controlled currents and/or voltages to individual longitudinal segments so as to increase uniformity of a longitudinal distribution of injection current provided to the gain layer.

Example 2. The semiconductor laser system of Example 1, wherein the semiconductor laser is a broad area laser.

Example 3. The semiconductor laser system of Example 1, wherein the semiconductor laser is a Fabry-Perot laser.

Example 4. The semiconductor laser system of any of the Examples above, wherein the reflectivity of the front reflector is smaller than the reflectivity of the back reflector.

Example 5. The semiconductor laser system of any of the Examples above, wherein the electronic control system is configured to provide individually controlled currents and/or voltages to individual longitudinal segments to make the longitudinal distribution of injection current provided to the gain layer more uniform than a longitudinal injection current distribution generated by a non-segmented electrode.

Example 6. The semiconductor laser system of any of the Examples above, wherein the active waveguide comprises a III-V compound semiconductor.

Example 7. The semiconductor laser system of any of the Examples above, wherein the lengths of the longitudinal segments are equal to each other.

Example 8. The semiconductor laser system of any of the Examples above, wherein the widths of the longitudinal segments are equal to each other.

Example 9. The semiconductor laser of any of Examples above, wherein said separate longitudinal segments are equally spaced in the longitudinal direction.

Example 10. The semiconductor laser system of any of Examples above, wherein the lengths of at least two longitudinal sections are not equal.

Example 11. The semiconductor laser system of any of Examples above, wherein the widths of at least two longitudinal sections are not equal.

Example 12. The semiconductor laser system of any of Examples 1-8 and 10-11, wherein a spacing between at least two consecutive longitudinal segments is smaller than the lengths of the at least two longitudinal segments.

Example 13 The semiconductor laser system of any of Examples above, wherein an individual longitudinal segment is extended symmetrically in the lateral direction with respect to a centerline of the active waveguide.

Example 14. The semiconductor laser system of any of Examples above, wherein an individual longitudinal segment comprises a rectangular shape.

Example 15. The semiconductor laser system of any of Examples above, wherein the width of an individual longitudinal segment increases and decreases multiple times with position along the length of the longitudinal segment.

Example 16. The semiconductor laser system of Example 15, wherein the width of the individual longitudinal segment increases and decreases linearly.

Example 17. The semiconductor laser system of Example 15, wherein the width of the individual longitudinal segment increases and decreases nonlinearly.

Example 18. The semiconductor laser system of any of Examples above, wherein a lateral edge of an individual longitudinal segment comprises a shape so as to provide an injection current distribution to the gain layer having an average width equal to the average width of the individual segment.

Example 19. The semiconductor laser system of any of Examples above, wherein an individual longitudinal segment comprises two or more lateral segments.

Example 20. The semiconductor laser system of Example 19, wherein an individual lateral segment has a length in the longitudinal direction, wherein the lengths of individual lateral segments are equal.

Example 21. The semiconductor laser system of Example 19 or 20, wherein the lateral segments extend symmetrically in the lateral direction with respect to a centerline of the active waveguide.

Example 22. The semiconductor laser system of any of Examples 19-21, wherein a lateral segment comprises a rectangular shape.

Example 23. The semiconductor laser system of any of Examples above, wherein the electrode comprises a top electrode.

Example 24. The semiconductor laser system of any of Examples above, wherein the electrode comprises a bottom electrode.

Example 25. The semiconductor laser system of any of Examples above, wherein the electronic control system is configured to provide individually controlled currents and/or voltages to the individual longitudinal segments to increase a slope efficiency of the semiconductor laser.

Example 26. The semiconductor laser system of any of Examples above, further comprising a photodetector configured to receive at least a portion of laser light generated by the semiconductor laser system and generate a signal indicative of an optical power of the laser light.

Example 27. The semiconductor laser system Example 26, wherein the photodetector receives the at least a portion of the laser light via the front reflector.

Example 28. The semiconductor laser of any of Examples 26 and 27, wherein the electronic control system is configured to provide individually controlled currents and/or voltages to the individual longitudinal segments based at least in part on the signal received from the photodetector.

Example 29. The semiconductor laser system of Example 26, wherein the electronic control system is configured to provide a first longitudinal injection current profile below and close to a lasing threshold and dynamically adjust the individually controlled currents and/or voltages to provide a second longitudinal injection current profile above the lasing threshold.

Example 30. The semiconductor laser system of Example 29, wherein the transition from the first to the second longitudinal injection current profile comprises a gradual transition.

Example 31. The semiconductor laser system of Example 29, wherein the transition from the first to the second longitudinal injection current profile comprises a stepwise transition.

Example 32. The semiconductor laser of any of Examples above, wherein the electronic control system is configured to provide individually controlled currents and/or voltages to the individual longitudinal segments to increase the optical power of laser light.

Example 33. The semiconductor laser system of any of Examples above, wherein the active waveguide is flared.

Example 34. The semiconductor laser system of Example 33, wherein an average width of a first longitudinal segment closer to the back reflector is smaller than an average width of a second longitudinal segment closer to the front reflector.

Example 35. The semiconductor laser system of any of Examples 33 and 34, wherein an average width of central lateral segments of the longitudinal segments increases at least along a portion of the waveguide length in the longitudinal direction.

Example 36. The semiconductor laser system of any of Examples above, further comprising a semiconductor optical amplifier configured to receive light output from the front optical reflector via an input port to be guided therein, amplify at least a portion of the input light that is guided in the optical amplifier system, and output at least a portion of the amplified portion of the input light via an output port, wherein the optical amplifier comprises:
a second active waveguide extending in the longitudinal direction between the input port and the output port, wherein the second active waveguide comprises a second gain layer configured to provide optical gain to the light guided in the second active waveguide.

Example 37. The semiconductor system of Example 36, wherein the semiconductor optical amplifier further comprises a second electrode disposed with respect to the second active waveguide, said second electrode comprising a second plurality of separate electrically isolated longitudinal segments arranged in the longitudinal direction, wherein the electronic control system configured to provide second individually controlled currents and/or voltages to individual second longitudinal segments.

Example 38. The semiconductor system of Example 36, wherein the semiconductor optical amplifier further comprises a non-segmented electrode disposed with respect to the second active waveguide.

Example 39. The semiconductor system of Example 37 and 38, wherein the second active waveguide has a second waveguide width along a lateral direction perpendicular to the longitudinal direction, and wherein the second waveguide width increases at least along a portion of the waveguide length in the longitudinal direction.

Example 40. The semiconductor system of any of Example 37 and 38, wherein the second active waveguide has a second waveguide width along a lateral direction perpendicular to the longitudinal direction, and wherein an average value of the second waveguide is does not change along of the waveguide length in the longitudinal direction.

Example 41. A semiconductor laser system comprising:
a semiconductor laser comprising:
a front optical reflector,
a back optical reflector,
said front and back optical reflectors disposed with respect to each other to form a laser cavity therebetween,
an active waveguide extending in a longitudinal direction between the front optical reflector and the back optical reflector, wherein said active waveguide comprises a gain layer configured to provide optical gain to light propagating within said active waveguide, said waveguide having a waveguide length along the longitudinal direction and a waveguide width along a lateral direction perpendicular to the longitudinal direction; and
an electrode disposed with respect to the active waveguide said electrode comprise a plurality of separate electrically isolated longitudinal segments arranged in the longitudinal direction, wherein an individual longitudinal segment has a length along the longitudinal direction and a width along a lateral direction perpendicular to the longitudinal direction, and wherein the width of an individual longitudinal segment does not increase and decrease multiple times along the longitudinal direction.

Example 42. The semiconductor laser system of Example 41 wherein the waveguide width increases at least along a portion of the waveguide length in the longitudinal direction.

Example 43. The semiconductor laser system of Example 42, wherein the width of an individual longitudinal segment increases along the longitudinal direction.

Example 44. The semiconductor laser system of Example 41, wherein an average value of the waveguide width is constant along the waveguide length in the longitudinal direction.

Example 45. The semiconductor laser system of Example 41, 42 or 44, wherein the width of an individual longitudinal segment is constant along the longitudinal direction.

Example 46. The semiconductor laser system of any of Examples 41-45, further comprising an electronic control system configured to provide individually controlled currents and/or voltages to individual longitudinal segments.

Example 47. The semiconductor laser system of any of the Examples 41-46, wherein the individual longitudinal segment does not include a protrusion.

Example 48. The semiconductor laser system of any of the Examples 41-47, wherein the width of an individual longitudinal segment does not increase and decrease in width.

Example 49 The semiconductor laser system of any of Examples 41-48, wherein the width of an individual longitudinal segment does not decrease along the longitudinal direction.

Example 50. A semiconductor laser system comprising:
a semiconductor laser chip comprising:
a front optical reflector,
a back optical reflector,
said front and back optical reflectors disposed with respect to each other to form a laser cavity therebetween,
an active waveguide extending in a longitudinal direction between the front optical reflector and the back optical reflector, wherein said active waveguide comprises a gain layer configured to provide optical gain to light propagating within said active waveguide, said waveguide having a waveguide length along the longitudinal direction and a waveguide width along a lateral direction perpendicular to the longitudinal direction;
an electrode disposed with respect to the active waveguide;
a submount comprising at least two electrically isolated conductive pads wherein a first conductive pad is electrically connected to a first region of the electrode and a second conductive pad is connected to a second region of the electrode separate from the first region, said first region extending in the longitudinal direction between a first end and second end, said second region extending in the longitudinal direction between a third end and a fourth end, and wherein the first end closer to the front reflector compared to the third end; and
an electronic control system configured to at least provide a first current to the first conductive pad and a second current to the second conductive pad so as to increase uniformity of a longitudinal distribution of injection current provided to the gain layer.

Example 51. The semiconductor laser system of Example 50 above, wherein the electrode comprises a top electrode.

Example 52. The semiconductor laser system of Example 51, wherein top electrode is segmented.

Example 53. The semiconductor laser system of Example 51, wherein top electrode is not segmented.

Example 54. The semiconductor laser system of Example 50, wherein the electrode comprises a bottom electrode.

Example 55. The semiconductor laser system of Example 54, wherein the bottom electrode is segmented.

Example 56. The semiconductor laser system of Example 54, wherein the bottom electrode is not segmented.

Example 57. A semiconductor laser system comprising:
a semiconductor laser comprising:
a front optical reflector,
a back optical reflector,
said front and back optical reflectors disposed with respect to each other to form a laser cavity therebetween,
an active waveguide extending in a longitudinal direction between the front optical reflector and the back optical reflector, wherein said active waveguide comprises a gain layer configured to provide optical gain to light propagating within said active waveguide, said waveguide having a waveguide length along the longitudinal direction and a waveguide width along a lateral direction perpendicular to the longitudinal direction;
an electrode disposed with respect to the active waveguide said electrode comprise a plurality of separate electrically isolated longitudinal segments arranged in the longitudinal direction, wherein an individual longitudinal segment has a length along the longitudinal direction and a width along a lateral direction perpendicular to the longitudinal direction; and
an electronic control system configured to provide individually controlled currents and/or voltages to individual longitudinal segments.

Example 58. The semiconductor laser of Example 57, wherein the electrode comprises a top electrode.

Example 59. The semiconductor laser of Example 57, wherein the electrode comprises a bottom electrode.

Example 60. The semiconductor laser of any of Examples 57-59, wherein the electronic control system is configured to provide individually controlled currents and/or voltages to the individual longitudinal segments to increase an optical power of laser light output.

Example 61. The semiconductor laser system of any of Examples 57-59, wherein the electronic control system is configured to provide individually controlled currents and/or voltages to the individual longitudinal segments to increase a slope efficiency of the semiconductor laser.

Example 62. The semiconductor laser system of any of Examples 57-61, further comprising a photodetector configured to receive at least a portion of laser light generated by the semiconductor laser system and generate a signal indicative of an optical power of the laser light.

Example 63. The semiconductor laser system Example 62, wherein the photodetector receives the at least a portion of the laser light via the front reflector.

Example 64. The semiconductor laser of any of Examples 62 and 63, wherein the electronic control system is configured to provide individually controlled currents and/or voltages to the individual longitudinal segments based at least in part on the signal received from the photodetector.

Example 65. The semiconductor laser of any of Examples 57-65, wherein the electronic control system is configured to provide individually controlled currents and/or voltages to individual longitudinal segments so as to tailor a longitudinal distribution of injection current provided to the gain layer.

Example 66. A semiconductor laser system comprising:
a semiconductor laser chip comprising:
a front optical reflector,
a back optical reflector,
said front and back optical reflectors disposed with respect to each other to form a laser cavity therebetween,
an active waveguide extending in a longitudinal direction between the front optical reflector and the back optical reflector, wherein said active waveguide comprises a gain layer configured to provide optical gain to light propagating within said active waveguide, said waveguide having a waveguide length along the longitudinal direction and a waveguide width along a lateral direction perpendicular to the longitudinal direction;
an electrode disposed with respect to the active waveguide;
a submount comprising at least two electrically isolated conductive pads wherein a first conductive pad is electrically connected to a first region of the electrode and a second conductive pad is connected to a second region of the electrode separate from the first region, said first region extending in the longitudinal direction between a first end and second end, said second region extending in the longitudinal direction between a third end and a fourth end, and wherein the first end closer to the front reflector compared to the third end; and
an electronic control system configured to at least provide a first current to the first conductive pad and a second current to the second conductive pad.

Example 67. The semiconductor laser system of Example 66 above, wherein the electrode comprises a top electrode.

Example 68. The semiconductor laser system of Example 67, wherein top electrode is segmented.

Example 69. The semiconductor laser system of Example 67, wherein top electrode is not segmented.

Example 70. The semiconductor laser system of Example 66, wherein the electrode comprises a bottom electrode.

Example 71. The semiconductor laser system of Example 70, wherein the bottom electrode is segmented.

Example 72. The semiconductor laser system of Example 70, wherein the bottom electrode is not segmented.

Example 73. The semiconductor laser system of any of Examples 66-72, wherein the electronic control system is configured to at least provide a first current to the first conductive pad and a second current to the second conductive pad so as to tailor a longitudinal distribution of injection current provided to the gain layer.

Example 74. The semiconductor laser system of any of Examples 1-14, 19-40 and 57-65, wherein the width of an individual longitudinal segment does not increase and decrease multiple times along the longitudinal direction.

Example 75. The semiconductor laser system of any of the Examples 1-14 19-40, 57-65, and 74, wherein the individual longitudinal segment does not include a protrusion.

Example 76. The semiconductor laser system of any of the Examples 1-14 19-40, 57-65, and 74-75, wherein the width of an individual longitudinal segment does not increase and decrease in width.

Example 77. The semiconductor laser system of any of Examples 1-14 19-40, 57-65, and 74-76, wherein the width of an individual longitudinal segment does not decrease along the longitudinal direction.

Example 78. The semiconductor laser system of any of Examples 1-32 36-40, 57-65, and 74-77, wherein the active waveguide is not flared.

### Group 2A

Example 1. A semiconductor laser system comprising:
a semiconductor laser comprising:
a front optical reflector,
a back optical reflector,
said front and back optical reflectors disposed with respect to each other to form a laser cavity therebetween,
an active waveguide extending in a longitudinal direction between the front optical reflector and the back optical reflector, wherein said active waveguide comprises a gain layer configured to provide optical gain to light propagating within said active waveguide, said waveguide having a waveguide length along the longitudinal direction and a waveguide width along a lateral direction perpendicular to the longitudinal direction;
an electrode disposed with respect to the active waveguide, said electrode comprising a plurality of separate electrically isolated longitudinal segments arranged in the longitudinal direction, wherein an individual longitudinal segment has a length along the longitudinal direction and a width along a lateral direction perpendicular to the longitudinal direction, wherein the active waveguide is not flared.

Example 2. The semiconductor laser system of Example 1, wherein the semiconductor laser is a broad area laser.

Example 3. The semiconductor laser system of Example 1, wherein the semiconductor laser is a Fabry-Perot laser.

Example 4. The semiconductor laser system of any of the Examples above, wherein the reflectivity of the front reflector is smaller than the reflectivity of the back reflector.

Example 5. The semiconductor laser system of any of the Examples above, further comprising an electronic control system configured to provide individually controlled currents and/or voltages to individual longitudinal segments to make the longitudinal distribution of injection current provided to the gain layer more uniform than a longitudinal injection current distribution generated by a non-segmented electrode.

Example 6. The semiconductor laser system of any of the Examples above, wherein the active waveguide comprises a III-V compound semiconductor.

Example 7. The semiconductor laser system of any of the Examples above, wherein the lengths of the longitudinal segments are equal to each other.

Example 8. The semiconductor laser system of any of the Examples above, wherein the widths of the longitudinal segments are equal to each other.

Example 9. The semiconductor laser of any of Examples above, wherein said separate longitudinal segments are equally spaced in the longitudinal direction.

Example 10. The semiconductor laser system of any of Examples above, wherein the lengths of at least two longitudinal sections are not equal.

Example 11. The semiconductor laser system of any of Examples above, wherein the widths of at least two longitudinal sections are not equal.

Example 12. The semiconductor laser system of any of Examples 1-8 and 10-11, wherein a spacing between at least two consecutive longitudinal segments is smaller than the lengths of the at least two longitudinal segments.

Example 13. The semiconductor laser system of any of Examples above, wherein an individual longitudinal segment is extended symmetrically in the lateral direction with respect to a centerline of the active waveguide.

Example 14. The semiconductor laser system of any of Examples above, wherein an individual longitudinal segment comprises a rectangular shape.

Example 15. The semiconductor laser system of any of Examples above, wherein the width of an individual longitudinal segment increases and decreases multiple times with position along the length of the longitudinal segment.

Example 16. The semiconductor laser system of Example 15, wherein the width of the individual longitudinal segment increases and decreases linearly.

Example 17. The semiconductor laser system of Example 15, wherein the width of the individual longitudinal segment increases and decreases nonlinearly.

Example 18. The semiconductor laser system of any of Examples above, wherein a lateral edge of an individual longitudinal segment comprises a shape so as to provide an injection current distribution to the gain layer having an average width equal to the average width of the individual segment.

Example 19. The semiconductor laser system of any of Examples above, wherein an individual longitudinal segment comprises two or more lateral segments.

Example 20. The semiconductor laser system of Example 19, wherein an individual lateral segment has a length in the longitudinal direction, wherein the lengths of individual lateral segments are equal.

Example 21. The semiconductor laser system of Example 19 or 20, wherein the lateral segments extend symmetrically in the lateral direction with respect to a centerline of the active waveguide.

Example 22. The semiconductor laser system of any of Examples 19-21, wherein a lateral segment comprises a rectangular shape.

Example 23. The semiconductor laser system of any of Examples above, wherein the electrode comprises a top electrode.

Example 24. The semiconductor laser system of any of Examples above, wherein the electrode comprises a bottom electrode.

Example 25. The semiconductor laser system of any of Examples 1-14, and 19-24, wherein the width of an individual longitudinal segment does not increase and decrease multiple times along the longitudinal direction.

Example 26. The semiconductor laser system of any of the Examples 1-14 and 19-25 wherein the individual longitudinal segment does not include a protrusion.

Example 27. The semiconductor laser system of any of the Examples 1-14 and 19-26 wherein the width of an individual longitudinal segment does not increase and decrease in width.

Example 28. The semiconductor laser system of any of Examples 1-14 and 19-27 wherein the width of an individual longitudinal segment does not decrease along the longitudinal direction.

Example 29. The semiconductor laser system of any of Examples 1˜4 and 6-28 above, further comprising an electronic control system configured to provide individually controlled currents and/or voltages to individual longitudinal segments

Example 30. The semiconductor laser of Example 29, wherein the electronic control system is configured to provide individually controlled currents and/or voltages to the individual longitudinal segments to increase an optical power of laser light.

Example 31. The semiconductor laser system of any of Examples 29-30, wherein the electronic control system is configured to provide individually controlled currents and/or voltages to the individual longitudinal segments to increase a slope efficiency of the semiconductor laser.

Example 32. The semiconductor laser system of any of Examples 29-31, further comprising a photodetector configured to receive at least a portion of laser light generated by the semiconductor laser system and generate a signal indicative of an optical power of the laser light.

Example 33. The semiconductor laser system Example 32, wherein the photodetector receives the at least a portion of the laser light via the front reflector.

Example 34. The semiconductor laser of any of Examples 32 and 33, wherein the electronic control system is configured to provide individually controlled currents and/or voltages to the individual longitudinal segments based at least in part on the signal received from the photodetector.

Example 35. The semiconductor laser of any of Examples 29-34, wherein the electronic control system configured to provide individually controlled currents and/or voltages to individual longitudinal segments so as to tailor a longitudinal distribution of injection current provided to the gain layer.

Example 36. The semiconductor laser system of any of Examples 29-35, wherein the electronic control system configured to provide individually controlled currents and/or voltages to individual longitudinal segments so as to increase uniformity of a longitudinal distribution of injection current provided to the gain layer

### Group 3A

Example 1. An optical amplifier system configured to receive input light via an input port to be guided therein, amplify at least a portion of the input light that is guided in the optical amplifier system, and output at least a portion of the amplified portion of the input light via an output port, wherein the optical amplifier system comprises:
an active waveguide extending in a longitudinal direction between the input port and the output port and having a waveguide width extending in a lateral direction perpendicular to the longitudinal direction, wherein the active waveguide comprises a gain layer configured to provide optical gain to light guided in the active waveguide;
an electrode disposed with respect to the active waveguide said electrode comprise a plurality of separate electrically isolated longitudinal segments arranged in the longitudinal direction, wherein an individual longitudinal segment has a length along the longitudinal direction and an electrode width along the lateral direction; and
an electronic control system configured to provide individually controlled currents and/or voltages to individual longitudinal segments so as to increase uniformity of a longitudinal distribution of injection current provided to the gain layer.

Example 2. The optical amplifier system of Example 1, wherein the electronic control system is configured to provide individually controlled currents and/or voltages to individual longitudinal segments to make the longitudinal distribution of injection current provided to the gain layer more uniform than a longitudinal injection current distribution generated by a non-segmented electrode.

Example 3. The optical amplifier system of any of the Examples above, wherein the active waveguide comprises a III-V compound semiconductor.

Example 4. The optical amplifier system of any of the Examples above, wherein the lengths of the longitudinal segments are equal to each other.

Example 5. The optical amplifier system of any of the Examples above, wherein the widths of the longitudinal segments are equal to each other.

Example 6. The optical amplifier system of any of Examples above, wherein said separate longitudinal segments are equally spaced in the longitudinal direction.

Example 7. The optical amplifier system of any of Examples above, wherein the lengths of at least two longitudinal sections are not equal.

Example 8. The optical amplifier system of Example 1, wherein the widths of at least two longitudinal sections are not equal.

Example 9. The optical amplifier system of any of Examples 1-5 and 7-8, wherein a spacing between at least two consecutive longitudinal segments is smaller than the lengths of the at least two longitudinal segments.

Example 10. The optical amplifier system of any of Examples above, wherein an individual longitudinal segment is extended symmetrically in the lateral direction with respect to a centerline of the active waveguide.

Example 11. The optical amplifier system of any of Examples above, wherein an individual longitudinal segment comprises a rectangular shape.

Example 12. The optical amplifier system of any of Examples above, wherein the width of an individual longitudinal segment increases and decreases multiple times with position along the length of the longitudinal segment.

Example 13. The optical amplifier system of Example 12, wherein the width of the individual longitudinal segment increases and decreases linearly.

Example 14. The optical amplifier system of Example 12, wherein the width of the individual longitudinal segment increases and decreases nonlinearly.

Example 15. The optical amplifier system of any of Examples above, wherein a lateral edge of an individual longitudinal segment comprises a shape so as to provide an injection current distribution to the gain layer having an average width equal to the average width of the individual segment.

Example 16. The optical amplifier system of any of Examples above, wherein an individual longitudinal segment comprises two or more lateral segments.

Example 17. The optical amplifier system of Example 16, wherein an individual lateral segment has a length in the longitudinal direction, wherein the lengths of individual lateral segments are equal.

Example 18. The optical amplifier system of Example 16, wherein the lateral segments extend symmetrically in the lateral direction with respect to a centerline of the active waveguide.

Example 19. The optical amplifier system of any of Examples 16-18, wherein a lateral segment comprises a rectangular shape.

Example 20. The optical amplifier system of any of Examples above, wherein the electrode comprises a top electrode.

Example 21. The optical amplifier system of any of Examples above, wherein the electrode comprises a bottom electrode.

Example 22. The optical amplifier system of any of Examples above, wherein the electronic control system is configured to provide individually controlled currents and/or voltages to the individual longitudinal segments to increase an efficiency of the optical amplifier system.

Example 23. The optical amplifier system of any of Examples above, further comprising a photodetector configured to receive at least a portion of the amplified portion of the input light and generate a signal indicative of an optical power of the amplified portion of the input light.

Example 24. The optical amplifier system of Example 23, wherein the photodetector receives the at least a portion of the amplified portion of the input light from the output port.

Example 25. The optical amplifier system of any of Examples 23 and 24, wherein the electronic control system is configured to provide individually controlled currents and/or voltages to the individual longitudinal segments based at least in part on the signal received from the photodetector.

Example 26. The optical amplifier system of any of Examples above, wherein the electronic control system is configured to provide individually controlled currents and/or voltages to the individual longitudinal segments to increase an optical power of the amplified portion of the input light.

Example 27. The optical amplifier system of any of Examples above, wherein the active waveguide is flared.

Example 28. The optical amplifier system of any of the Examples above, wherein an average width of a first longitudinal segment closer to the input port is smaller larger than an average width of a second longitudinal segment closer to the output port.

Example 29. The optical amplifier system of any of any of the Examples above, wherein an average width of central lateral segments of longitudinal segments increases from the input port to the output port along the longitudinal direction.

Example 30. The optical amplifier system of any of Examples above, further comprising a semiconductor laser configured to generate laser light and provide the laser light to the optical amplifier system via the input port, wherein the semiconductor laser comprises:
a front optical reflector,
a back optical reflector,
said front and back optical reflectors disposed with respect to each other to form a laser cavity therebetween, and
a second active waveguide extending in the longitudinal direction between the front optical reflector and the back optical reflector, wherein the second active waveguide comprises a second gain layer configured to provide optical gain to light propagating within the second active waveguide.

Example 31. The optical amplifier system of Example 30, wherein the semiconductor laser comprises a second electrode disposed with respect to the second active waveguide, said second electrode comprising a second plurality of separate electrically isolated longitudinal segments arranged in the longitudinal direction;
wherein the electronic control system configured to provide second individually controlled currents and/or voltages to individual second longitudinal segments so as to increase uniformity of a second longitudinal distribution of injection current provided to the second gain layer.

Example 32. The optical amplifier system of Example 30, wherein the semiconductor laser further comprises a non-segmented electrode disposed with respect to the second active waveguide.

Example 33. The optical amplifier system of Example 30 and 31, wherein the second active waveguide has a second waveguide width along a lateral direction perpendicular to the longitudinal direction, and wherein the second waveguide width increases at least along a portion of the waveguide length in the longitudinal direction.

Example 34. The semiconductor system of Example 30 and 31, wherein the second active waveguide has a second waveguide width along a lateral direction perpendicular to the longitudinal direction, and wherein an average value of the second waveguide width is constant along the waveguide length in the longitudinal direction.

Example 35. An optical amplifier system configured to receive input light via an input port to be guided therein, amplify at least a portion of the input light that is guided in the optical amplifier system, and output at least a portion of the amplified portion of the input light via an output port, wherein the optical amplifier system comprises:
an active waveguide extending in a longitudinal direction between the input port and the output port and having a waveguide width extending in a lateral direction perpendicular to the longitudinal direction, wherein the active waveguide comprises a gain layer configured to provide optical gain to light guided in the active waveguide;
an electrode disposed with respect to the active waveguide said electrode comprise a plurality of separate electrically isolated longitudinal segments arranged in the longitudinal direction, wherein an individual longitudinal segment has a length along the longitudinal direction and an electrode width along the lateral direction; and wherein the width of an individual longitudinal segment does not increase and decrease multiple times along the longitudinal direction.

Example 36. The optical amplifier system of Example 35, wherein the waveguide width increases at least along a portion of the waveguide length in the longitudinal direction.

Example 37. The optical amplifier system of Example 36, wherein the width of an individual longitudinal segment increases along the longitudinal direction.

Example 38. The optical amplifier system of Example 35, wherein an average value of the waveguide width is constant at least along a portion of the waveguide length in the longitudinal direction.

Example 39. The optical amplifier system of Example 38, wherein the width of an individual longitudinal segment is constant along the longitudinal direction.

Example 40. The optical amplifier system of any of Examples 35-39, further comprising an electronic control system configured to provide individually controlled currents and/or voltages to individual longitudinal segments.

Example 41 The optical amplifier system of any of Examples 35-40, wherein the individual longitudinal segment does not include a protrusion.

Example 42 The optical amplifier system of any of Examples 35-41, wherein the width of an individual longitudinal segment does not increase and decrease in width.

Example 43 The optical amplifier system of any of Examples 35-42, wherein the width of an individual longitudinal segment does not decrease along the longitudinal direction.

Example 44. An optical amplifier system configured to receive input light via an input port to be guided therein, amplify at least a portion of the input light that is guided in the optical amplifier system, and output at least a portion of the amplified portion of the input light via an output port, wherein the optical amplifier system comprises:
an active waveguide extending in a longitudinal direction between the input port and the output port an active waveguide extending in a longitudinal direction between the input port and the output port and having a waveguide width extending in a lateral direction perpendicular to the longitudinal direction, wherein the active waveguide comprises a gain layer configured to provide optical gain to light guided in the active waveguide;
an electrode disposed with respect to the active waveguide;
a submount comprising at least two electrically isolated conductive pads wherein a first conductive pad is electrically connected to a first region of the electrode and a second conductive pad is connected to a second region of the electrode separate from the first region, said first region extending in the longitudinal direction between a first end and second end, said second region extending in the longitudinal direction between a third end and a fourth end, and wherein the first end closer to the output port compared to the third end; and
an electronic control system configured to at least provide a first current to the first conductive pad and a second current to the second conductive pad so as to increase uniformity of a longitudinal distribution of injection current provided to the gain layer.

Example 45. The optical amplifier system of Example 44 above, wherein the electrode comprises a top electrode.

Example 46. The optical amplifier system of Example 45, wherein top electrode is segmented.

Example 47. The optical amplifier system of Example 45, wherein top electrode is not segmented.

Example 48. The optical amplifier system of Example 44, wherein the electrode comprises a bottom electrode.

Example 49. The optical amplifier system of Example 48, wherein the bottom electrode is segmented.

Example 50. The optical amplifier system of Example 48, wherein the bottom electrode is not segmented.

Example 51. An optical amplifier system configured to receive input light via an input port to be guided therein, amplify at least a portion of the input light that is guided in the optical amplifier system, and output at least a portion of the amplified portion of the input light via an output port, wherein the optical amplifier system comprises:
an active waveguide extending in a longitudinal direction between the input port and the output port an active waveguide extending in a longitudinal direction between the input port and the output port and having a waveguide width extending in a lateral direction perpendicular to the longitudinal direction, wherein the active waveguide comprises a gain layer configured to provide optical gain to light guided in the active waveguide;
an electrode disposed with respect to the active waveguide said electrode comprise a plurality of separate electrically isolated longitudinal segments arranged in the longitudinal direction, wherein an individual longitudinal segment has a length along the longitudinal direction and a width along a lateral direction perpendicular to the longitudinal direction; and
an electronic control system configured to provide individually controlled currents and/or voltages to individual longitudinal segments.

Example 52. The optical amplifier system of Example 51, wherein the electrode comprises a top electrode.

Example 53. The optical amplifier system of Example 51, wherein the electrode comprises a bottom electrode.

Example 54. The optical amplifier system of any of Examples 51-53, wherein the electronic control system is configured to provide individually controlled currents and/or voltages to the individual longitudinal segments to increase the optical power of the output portion of the amplified portion of the input light.

Example 55. The optical amplifier system of any of Examples 51-53, wherein the electronic control system is configured to provide individually controlled currents and/or voltages to the individual longitudinal segments to increase a slope efficiency of the semiconductor laser.

Example 56. The optical amplifier system of any of Examples 51-55, further comprising a photodetector configured to receive at least a portion of amplified light produced by the semiconductor laser system and generate a signal indicative of an optical power of the amplified light.

Example 57. The optical amplifier system Example 56, wherein the photodetector receives the at least a portion of the laser light via the output port.

Example 58. The optical amplifier system of any of Examples 56 and 57, wherein the electronic control system is configured to provide individually controlled currents and/or voltages to the individual longitudinal segments based at least in part on the signal received from the photodetector.

Example 59. The optical amplifier system of any of Examples 51-59, wherein the electronic control system is configured to provide individually controlled currents and/or voltages to individual longitudinal segments so as to tailor a longitudinal distribution of injection current provided to the gain layer.

Example 60. An optical amplifier system configured to receive input light via an input port to be guided therein, amplify at least a portion of the input light that is guided in the optical amplifier system, and output at least a portion of the amplified portion of the input light via an output port, wherein the optical amplifier system comprises:
an active waveguide extending in a longitudinal direction between the input port and the output port and having a waveguide width extending in a lateral direction perpendicular to the longitudinal direction, wherein the active waveguide comprises a gain layer configured to provide optical gain to light guided in the active waveguide;
an electrode disposed with respect to the active waveguide;
a submount comprising at least two electrically isolated conductive pads wherein a first conductive pad is electrically connected to a first region of the electrode and a second conductive pad is connected to a second region of the electrode separate from the first region, said first region extending in the longitudinal direction between a first end and second end, said second region extending in the longitudinal direction between a third end and a fourth end, and wherein the first end closer to the output port compared to the third end; and
an electronic control system configured to at least provide a first current to the first conductive pad and a second current to the second conductive pad.

Example 61. The optical amplifier system of Example 60, wherein the electrode comprises a top electrode.

Example 62. The optical amplifier system of Example 61, wherein top electrode is segmented.

Example 63. The optical amplifier system of Example 61, wherein top electrode is not segmented.

Example 64. The optical amplifier system of Example 60, wherein the electrode comprises a bottom electrode.

Example 65. The optical amplifier system of Example 64, wherein the bottom electrode is segmented.

Example 66. The optical amplifier system of Example 64, wherein the bottom electrode is not segmented.

Example 67. The optical amplifier system of any of Examples 60-66, wherein the electronic control system is configured to at least provide a first current to the first conductive pad and a second current to the second conductive pad so as to tailor a longitudinal distribution of injection current provided to the gain layer.

Example 67. The optical amplifier system of any of Examples 1-11, 16-34 and 51-59, wherein the width of an individual longitudinal segment does not increase and decrease multiple times along the longitudinal direction.

Example 68. The optical amplifier system of any of the Examples 1-11 16-34, 51-59, and 67 wherein the individual longitudinal segment does not include a protrusion.

Example 69. The optical amplifier system of any of the Examples 1-11 16-34, 51-59, and 67-68 wherein the width of an individual longitudinal segment does not increase and decrease in width.

Example 70. The optical amplifier system of any of Examples 1-11, 16-34, 51-59, and 67-69 wherein the width of an individual longitudinal segment does not decrease along the longitudinal direction.

Example 71. The optical amplifier system of any of Examples 1-26, 30-34, 51-59, and 67-70 wherein the active waveguide is not flared.

### Group 4A

Example 1. An optical amplifier system configured to receive input light via an input port to be guided therein, amplify at least a portion of the input light that is guided in the optical amplifier system, and output at least a portion of the amplified portion of the input light via an output port, wherein the optical amplifier system comprises:
an active waveguide extending in a longitudinal direction between the input port and the output port and having a waveguide width extending in a lateral direction perpendicular to the longitudinal direction, wherein the active waveguide comprises a gain layer configured to provide optical gain to light guided in the active waveguide;
an electrode disposed with respect to the active waveguide said electrode comprise a plurality of separate electrically isolated longitudinal segments arranged in the longitudinal direction, wherein an individual longitudinal segment has a length along the longitudinal direction and an electrode width along the lateral direction;
wherein the active waveguide is not flared.

Example 2. The optical amplifier system of Example 1, further comprising an electronic control system configured to provide individually controlled currents and/or voltages to individual longitudinal segments to make the longitudinal distribution of injection current provided to the gain layer more uniform than a longitudinal injection current distribution generated by a non-segmented electrode.

Example 3. The optical amplifier system of any of the Examples above, wherein the active waveguide comprises a III-V compound semiconductor.

Example 4. The optical amplifier system of any of the Examples above, wherein the lengths of the longitudinal segments are equal to each other.

Example 5. The optical amplifier system of any of the Examples above, wherein the widths of the longitudinal segments are equal to each other.

Example 6. The optical amplifier system of any of Examples above, wherein said separate longitudinal segments are equally spaced in the longitudinal direction.

Example 7. The optical amplifier system of any of Examples above, wherein the lengths of at least two longitudinal sections are not equal.

Example 8. The optical amplifier system of any of Example 1-4 and 6-7, wherein the widths of at least two longitudinal sections are not equal.

Example 9. The optical amplifier system of any of Examples 1-5 and 7-8, wherein a spacing between at least two consecutive longitudinal segments is smaller than the lengths of the at least two longitudinal segments.

Example 10. The optical amplifier system of any of Examples above, wherein an individual longitudinal segment is extended symmetrically in the lateral direction with respect to a centerline of the active waveguide.

Example 11. The optical amplifier system of any of Examples above, wherein an individual longitudinal segment comprises a rectangular shape.

Example 12. The optical amplifier system of any of Examples above, wherein the width of an individual longitudinal segment increases and decreases multiple times with position along the length of the longitudinal segment.

Example 13. The optical amplifier system of Example 12, wherein the width of the individual longitudinal segment increases and decreases linearly.

Example 14. The optical amplifier system of Example 12, wherein the width of the individual longitudinal segment increases and decreases nonlinearly.

Example 15. The optical amplifier system of any of Examples above, wherein a lateral edge of an individual longitudinal segment comprises a shape so as to provide an injection current distribution to the gain layer having an average width equal to the average width of the individual segment.

Example 16. The optical amplifier system of any of Examples above, wherein an individual longitudinal segment comprises two or more lateral segments.

Example 17. The optical amplifier system of Example 16, wherein an individual lateral segment has a length in the longitudinal direction, wherein the lengths of individual lateral segments are equal.

Example 18. The optical amplifier system of Example 16, wherein the lateral segments extend symmetrically in the lateral direction with respect to a centerline of the active waveguide.

Example 19. The optical amplifier system of Example 16, wherein a lateral segment comprises a rectangular shape.

Example 20. The optical amplifier system of any of Examples above, wherein the electrode comprises a top electrode.

Example 21. The optical amplifier system of any of Examples above, wherein the electrode comprises a bottom electrode.

Example 22. The optical amplifier system of any of Examples above, wherein the electronic control system is configured to provide individually controlled currents and/or voltages to the individual longitudinal segments to increase an efficiency of the optical amplifier system.

Example 23. The optical amplifier system of any of Examples 1-11, and 16-22, wherein the width of an individual longitudinal segment does not increase and decrease multiple times along the longitudinal direction.

Example 24. The optical amplifier system of any of the Examples 1-11 and 16-23 wherein the individual longitudinal segment does not include a protrusion.

Example 25. The optical amplifier system of any of the Examples 1-11 and 16-24 wherein the width of an individual longitudinal segment does not increase and decrease in width.

Example 26. The optical amplifier system of any of Examples 1-11 and 16-25 wherein the width of an individual longitudinal segment does not decrease along the longitudinal direction.

Example 27. The optical amplifier system of any of Examples 1 and 3-26, further comprising an electronic control system configured to provide individually controlled currents and/or voltages to individual longitudinal segments

Example 28. The optical amplifier system of Example 27, wherein the electronic control system is configured to provide individually controlled currents and/or voltages to the individual longitudinal segments to increase an optical power of amplified light

Example 29. The optical amplifier system of any of Examples 27-28, wherein the electronic control system is configured to provide individually controlled currents and/or voltages to the individual longitudinal segments to increase a slope efficiency of the semiconductor laser.

Example 30. The optical amplifier system of any of Examples 27-29, further comprising a photodetector configured to receive at least a portion of laser light generated by the semiconductor laser system and generate a signal indicative of an optical power of the amplified light.

Example 31. The optical amplifier system Example 30, wherein the photodetector receives the at least a portion of the amplified light via the front reflector.

Example 32. The optical amplifier system of any of Examples 30 and 31, wherein the electronic control system is configured to provide individually controlled currents and/or voltages to the individual longitudinal segments based at least in part on the signal received from the photodetector.

Example 33. The optical amplifier system of any of the example above, wherein the electronic control system is configured to provide individually controlled currents and/or voltages to individual longitudinal segments so as to tailor a longitudinal distribution of injection current provided to the gain layer.

Example 34. The optical amplifier system of any of Examples 1, and 2-26, further comprising an electronic control system configured to provide individually controlled currents and/or voltages to individual longitudinal segments so as to increase uniformity of a longitudinal distribution of injection current provided to the gain layer.

### Group 5A

Example 1. A semiconductor laser system comprising:
a semiconductor laser comprising:
a front optical reflector,
a back optical reflector,
said front and back optical reflectors disposed with respect to each other to form a laser cavity therebetween,
an active waveguide extending in a longitudinal direction between the front optical reflector and the back optical reflector, wherein said active waveguide comprises a gain layer configured to provide optical gain to light propagating within said active waveguide, said waveguide having a waveguide length along the longitudinal direction and a waveguide width along a lateral direction perpendicular to the longitudinal direction;
an electrode disposed with respect to the active waveguide to apply an electrical voltage to said gain layer;
an electronic control system configured to provide individually controlled currents and/or voltages to individual longitudinal regions of the electrode via conductive lines distributed across the individual longitudinal regions in number so as to increase uniformity of a longitudinal distribution of injection current provided to the gain layer.

Example 2. The semiconductor laser system of Example 1, wherein the conductive lines comprise a first group of conductive lines having a first number of individual conductive lines and connected to a first longitudinal region, and a second group of conductive lines having a second number of individual conductive lines connected to a second longitudinal region, wherein the first number is different from the second number.

Example 3. The semiconductor laser system of Example 2, wherein the first number is smaller than the second number.

Example 4 The semiconductor laser system of Example 2, wherein the first number is larger than the second number.

Example 5. The semiconductor laser system of any of Examples above, wherein, the electrode is non-segmented.

Example 6. The semiconductor laser system of any of Examples above, further comprising a photodetector configured to receive at least a portion an optical power of laser light and generate a signal indicative of an optical power of laser light.

Example 7. The semiconductor laser of Example 6, wherein the electronic control system is configured to provide individually controlled currents and/or voltages to the individual longitudinal segments based at least in part on the signal received from the photodetector.

Example 8. The semiconductor laser of any of Examples above, wherein the electronic control system is configured to provide individually controlled currents and/or voltages to the individual longitudinal segments to increase the optical power of laser light output via the front reflector.

Example 9. The semiconductor laser system of any of Examples above, wherein the waveguide width increases at least along a portion of the waveguide length in the longitudinal direction.

Example 10. The semiconductor laser system of any of Examples above, wherein the waveguide width is not flared.

Example 11. The semiconductor laser system of any of Examples above, the first longitudinal region in closer to the front optical reflector compared to a second longitudinal region.

### Group 6A

Example 1. An optical amplifier system configured to receive input light via an input port to be guided therein, amplify at least a portion of the input light that is guided in the optical amplifier system, and output at least a portion of the amplified portion of the input light via an output port, wherein the optical amplifier system comprises:
an active waveguide extending in a longitudinal direction between the input port and the output port an active waveguide extending in a longitudinal direction between the input port and the output port and having a waveguide width extending in a lateral direction perpendicular to the longitudinal direction, wherein the active waveguide comprises a gain layer configured to provide optical gain to light guided in the active waveguide; and
an electrode disposed with respect to the active waveguide with respect to the active waveguide to apply an electrical voltage to said gain layer;
an electronic control system configured to provide individually controlled currents and/or voltages to individual longitudinal regions of the electrode via conductive lines distributed across the individual longitudinal regions in number so as to increase uniformity of a longitudinal distribution of injection current provided to the gain layer

Example 2. The optical amplifier system of Example 1, wherein the conductive lines comprise a first group of conductive lines having a first number of individual conductive lines and connected to a first longitudinal region, and a second group of individual conductive lines having a second number of conductive lines connected to a second longitudinal region, wherein the first number is different from the second number, and wherein.

Example 3. The optical amplifier system of Example 2, wherein the first number is smaller than the second number

Example 4. The optical amplifier system of Example 2, wherein the first number is larger than the second number.

Example 5. The optical amplifier system of any of Examples above, wherein, the electrode is non-segmented.

Example 6. The optical amplifier system of any of Examples above, further comprising a photodetector configured to receive at least a portion of the amplified portion of the input light and generate a signal indicative of an optical power of the amplified portion of the input light.

Example 7. The optical amplifier system of any of Examples above, further comprising a photodetector configured to receive at least a portion of light guided in the active waveguide and generate a signal indicative of an optical power of a portion of the amplified portion of the input light, output via the output port.

Example 8. The optical amplifier system of any of Examples 6 and 7, wherein the electronic control system is configured to provide individually controlled currents and/or voltages to individual longitudinal regions of the electrode based at least in part on the signal received from the photodetector.

Example 9. The optical amplifier system of any of the examples above, wherein the electronic control system is configured to provide individually controlled currents and/or voltages to the individual longitudinal regions to increase an optical power of the amplified portion of the input light.

Example 10. The optical amplifier system of any of Examples above, wherein the waveguide width increases at least along a portion of the waveguide length in the longitudinal direction.

Example 11. The optical amplifier system of any of Examples above, wherein the waveguide width is not flared.

Example 12. The optical amplifier system of any of Examples above, the first longitudinal region in closer to the front optical reflector compared to a second longitudinal region.

### Group 7A

Example 1. A semiconductor laser system comprising:
a semiconductor laser comprising:
a front optical reflector,
a back optical reflector,
said front and back optical reflectors disposed with respect to each other to form a laser cavity therebetween,
an active waveguide extending in a longitudinal direction between the front optical reflector and the back optical reflector, wherein said active waveguide comprises a gain layer configured to provide optical gain to light propagating within said active waveguide, said waveguide having a waveguide length along the longitudinal direction and a waveguide width along a lateral direction perpendicular to the longitudinal direction;
an electrode disposed with respect to the active waveguide said electrode comprise a plurality of separate electrically isolated longitudinal segments arranged in the longitudinal direction, wherein an individual longitudinal segment has a length along the longitudinal direction and a width along a lateral direction perpendicular to the longitudinal direction; and
an electronic control system configured to provide individually controlled currents and/or voltages to individual longitudinal segments so as to increase uniformity of a longitudinal distribution of injection current provided to the gain layer.

Example 2. The semiconductor laser of Example 1, wherein the semiconductor laser is a broad area laser.

Example 3. The semiconductor laser of Example 1, wherein the semiconductor laser is a Fabry-Perot laser.

Example 4. The semiconductor laser of any of the Examples above, wherein the reflectivity of the front reflector is smaller than the reflectivity of the back reflector.

Example 5. The semiconductor laser of any of the Examples above, wherein the active waveguide comprises a III-V compound semiconductor.

Example 6. The semiconductor laser of any of the Examples above, wherein the lengths of the longitudinal segments are equal to each other.

Example 7. The semiconductor laser any of the Examples above, wherein the widths of the longitudinal segments are equal to each other.

The semiconductor laser of any of Examples above, Example 8, wherein said separate longitudinal segments are equally spaced in the longitudinal direction.

Example 9. The semiconductor laser of any of Examples above, wherein the lengths of at least two longitudinal sections are not equal.

Example 10. The semiconductor laser of Example 1, wherein the widths of at least two longitudinal sections are not equal.

Example 11. The semiconductor laser of any of Examples 1, 7, 9 and 10 wherein a spacing between at least two consecutive longitudinal segments is smaller than the lengths of the at least two longitudinal segments.

Example 12. The semiconductor laser of any of Examples above, wherein an individual longitudinal segment is extended symmetrically in the lateral direction with respect to a centerline of the active waveguide.

Example 13. The semiconductor laser of any of Examples above, wherein an individual longitudinal segment comprises a rectangular shape.

Example 14. The semiconductor laser of any of Examples 2-8, wherein the width of an individual longitudinal segment increases and decreases multiple times with position along the length of the longitudinal segment.

Example 15. The semiconductor laser of Example 14, wherein the width of the individual longitudinal segment increases and decreases linearly.

Example 16. The semiconductor laser of Example 14, wherein the width of the individual longitudinal segment increases and decreases nonlinearly.

Example 17. The semiconductor laser of any of Examples above, wherein a lateral edge of an individual longitudinal segment comprises a shape so as to provide an injection current distribution to the gain layer having an average width equal to the average width of the individual segment.

Example 18. The semiconductor laser of any of Examples above, wherein an individual longitudinal segment comprises two or more lateral segments.

Example 19. The semiconductor laser of Example 18, wherein an individual lateral segment has a length in the longitudinal direction, wherein the lengths of individual lateral segments are equal.

Example 20. The semiconductor laser of Example 18, wherein the lateral segments extend symmetrically in the lateral direction with respect to a centerline of the active waveguide.

Example 21. The semiconductor laser of Example 18, wherein a lateral segment comprises a rectangular shape.

Example 22. The semiconductor laser of any of Examples above, wherein the electrode comprises a top electrode.

Example 23. The semiconductor laser of any of Examples above, wherein the electrode comprises a bottom electrode.

Example 24. The semiconductor laser of any of Examples above, wherein the electronic control system is configured to provide individually controlled currents and/or voltages to the individual longitudinal segments to increase a slope efficiency of the semiconductor laser.

Example 25. The semiconductor laser of any of Examples above, wherein the electronic control system is configured to provide individually controlled currents and/or voltages to the individual longitudinal segments based at least in part on an optical power of laser light output via the front reflector.

Example 26. The semiconductor laser of Example 25, wherein the electronic control system is configured to provide individually controlled currents and/or voltages to the individual longitudinal segments to increase an optical power of laser light output via the front reflector.

Example 27. A semiconductor laser system comprising:
a semiconductor laser chip comprising:
a front optical reflector,
a back optical reflector,
said front and back optical reflectors disposed with respect to each other to form a laser cavity therebetween,
an active waveguide extending in a longitudinal direction between the front optical reflector and the back optical reflector, wherein said active waveguide comprises a gain layer configured to provide optical gain to light propagating within said active waveguide, said waveguide having a waveguide length along the longitudinal direction and a waveguide width along a lateral direction perpendicular to the longitudinal direction;
an electrode disposed with respect to the active waveguide;
a submount comprising at least two electrically isolated conductive pads wherein a first conductive pad is electrically connected to a first region of the electrode and a second conductive pad is connected to a second region of the electrode separate from the first region, said first region extending in the longitudinal direction between a first end and second end, said second region extending in the longitudinal direction between a third end and a fourth end, and wherein the first end closer to the front reflector compared to the third end; and
an electronic control system configured to at least provide a first current to the first conductive pad and a second current to the second conductive pad so as to increase uniformity of a longitudinal distribution of injection current provided to the gain layer.

Example 28. The semiconductor laser system of Example 27 above, wherein the electrode comprises a top electrode.

Example 29. The semiconductor laser system of Example 28, wherein

top electrode is segmented.

Example 30. The semiconductor laser system of Example 28, wherein

top electrode is not segmented.

Example 31. The semiconductor laser system of Example 27, wherein the electrode comprises a bottom electrode.

Example 32. The semiconductor laser system of Example 31, wherein

the bottom electrode is segmented.

Example 33. The semiconductor laser system of Example 31, wherein the bottom electrode is not segmented.

Example 34. A semiconductor laser system comprising:
a semiconductor laser comprising:
a front optical reflector,
a back optical reflector,
said front and back optical reflectors disposed with respect to each other to form a laser cavity therebetween,
an active waveguide extending in a longitudinal direction between the front optical reflector and the back optical reflector, wherein said active waveguide comprises a gain layer configured to provide optical gain to light propagating within said active waveguide, said waveguide having a waveguide length along the longitudinal direction and a waveguide width along a lateral direction perpendicular to the longitudinal direction;
an electrode disposed with respect to the active waveguide said electrode comprise a plurality of separate electrically isolated longitudinal segments arranged in the longitudinal direction, wherein an individual longitudinal segment has a length along the longitudinal direction and a width along a lateral direction perpendicular to the longitudinal direction; and
an electronic control system configured to provide individually controlled currents and/or voltages to individual longitudinal segments.

Example 35. The semiconductor laser of Example 34, wherein the electrode comprises a top electrode.

Example 36. The semiconductor laser of Example 34, wherein the electrode comprises a bottom electrode.

Example 37. A semiconductor laser system comprising:
a semiconductor laser chip comprising:
a front optical reflector,
a back optical reflector,
said front and back optical reflectors disposed with respect to each other to form a laser cavity therebetween,
an active waveguide extending in a longitudinal direction between the front optical reflector and the back optical reflector, wherein said active waveguide comprises a gain layer configured to provide optical gain to light propagating within said active waveguide, said waveguide having a waveguide length along the longitudinal direction and a waveguide width along a lateral direction perpendicular to the longitudinal direction;
an electrode disposed with respect to the active waveguide;
a submount comprising at least two electrically isolated conductive pads wherein a first conductive pad is electrically connected to a first region of the electrode and a second conductive pad is connected to a second region of the electrode separate from the first region, said first region extending in the longitudinal direction between a first end and second end, said second region extending in the longitudinal direction between a third end and a fourth end, and wherein the first end closer to the front reflector compared to the third end; and
an electronic control system configured to at least provide a first current to the first conductive pad and a second current to the second conductive pad.

Example 38. The semiconductor laser system of Example 37 above, wherein the electrode comprises a top electrode.

Example 39. The semiconductor laser system of Example 38, wherein top electrode is segmented.

Example 40. The semiconductor laser system of Example 38, wherein top electrode is not segmented.

Example 41. The semiconductor laser system of Example 37, wherein the electrode comprises a bottom electrode.

Example 42. The semiconductor laser system of Example 41, wherein the bottom electrode is segmented.

Example 43. The semiconductor laser system of Example 41, wherein the bottom electrode is not segmented.

Example 44. The semiconductor laser system of any of Examples 37-43, wherein the electronic control system is configured to at least provide a first current to the first conductive pad and a second current to the second conductive pad so as to tailor a longitudinal distribution of injection current provided to the gain layer.

Example 45. The semiconductor laser of any of Examples 34-36, wherein the electronic control system is configured to an electronic control system configured to provide individually controlled currents and/or voltages to individual longitudinal segments so as to tailor a longitudinal distribution of injection current provided to the gain layer.

### Group 1B

Example 1. An optical system comprising:
an optical device configured to provide optical gain, the optical device comprising:
an active optical waveguide extending in a longitudinal direction between a first end and a second end, wherein said active waveguide comprises a semiconductor optical gain layer configured to provide optical gain to light propagating within said active optical waveguide, said active optical waveguide having a waveguide length along the longitudinal direction and a waveguide width along a lateral direction perpendicular to the longitudinal direction; and
a segmented electrode disposed with respect to the active optical waveguide said electrode comprising a plurality of separate electrically isolated electrode segments configured to provide individual drive currents to corresponding regions of the optical gain layer; and
an electronic control system configured to provide a plurality of individually controlled drive signals to different electrode segments to generate a controlled distribution of drive currents in the optical gain layer, and
a common enclosure wherein the optical device and the electronic control system are included in the common enclosure.

Example 2. The optical system of Example 1, wherein controlled distribution of drive currents comprises a time varying distribution of drive currents.

Example 3. The optical system of Example 1, wherein the controlled distribution of drive currents is configured to improve an efficiency of light generation or light amplification in the active optical waveguide compared to those of a second active optical waveguide driven by a single drive signal, wherein the second active optical waveguide and a second semiconductor optical gain layer therein are identical to the optical waveguide and the optical gain layer.

Example 4. The optical system of Example 1, wherein the controlled distribution of drive currents is configured to improve a stability of light generation or light amplification in the active optical waveguide compared to those of a second active optical waveguide driven by a single drive current, wherein the second active optical waveguide and a second semiconductor optical gain layer therein are identical to the optical waveguide and the optical gain layer.

Example 5. The optical system of Example 1, wherein the controlled distribution of drive currents is configured to improve a quality of a light beam generated or amplified by the active optical waveguide compared to that of a second light beam generated or amplified by a second active optical waveguide driven by a single drive current, wherein the second active optical waveguide and a second semiconductor optical gain layer therein are identical to the optical waveguide and the optical gain layer.

Example 6. The optical system of Example 4, wherein the stability of light generation or light amplification comprises at least one of:
a stability of a spatial optical intensity distribution in a light beam generated or amplified by the optical device;
a stability of optical power of light output by the optical device;
a stability of polarization of light output by the optical device; and
a stability of a spectrum of light output by the optical device;

Example 7. The optical system of Example 5, wherein improving the quality of the light comprises at least one of:
reducing a difference between a spatial optical intensity distribution of the light beam and a diffraction limited light beam;
reducing a level of astigmatism of the light beam; and
reducing a difference between a spatial optical intensity distribution of the light beam and a target spatial optical intensity distribution.

Example 8. The optical system of any one of above Examples, wherein the segmented electrode comprises at least two longitudinal segments and the electronic control system controls a longitudinal distribution of drive currents along the optical waveguide using the at least two longitudinal segments.

Example 9. The optical system of any one of above Examples, wherein the segmented electrode comprises at least two lateral segments and the electronic control system controls a lateral distribution of drive currents across the optical waveguide using the at least two lateral segments.

Example 10. The optical system of any one of the above Examples, wherein the electronic control system temporally changes the controlled distribution of optical gain by varying an individually controlled drive signal provide to an electrode segment.

Example 11. The optical system of Example 10, wherein at least two individually controlled drive signals comprise different temporal profiles.

Example 12. The optical system of anyone of the above Examples, wherein at least one of the drive signals is dynamically controlled.

Example 13. The optical system of anyone of the above Examples, wherein at least one of the drive signals is modulated.

Example 14. The optical system of Example 13, wherein at least one of the drive signals is modulated with a periodic wave form.

Example 15. The optical system of anyone of the above Examples, wherein the electronic control adaptively controls at least one of the drive signals using a sensor signal.

Example 16. The optical system of Example 15, wherein the optical system comprises a sensor that generates the sensor signal.

Example 17. The optical system of Example 16, wherein the sensor comprises a temperature sensor and the sensor signal indicates a temperature of the optical device or a surrounding medium.

Example 18. The optical system of Example 16, wherein the sensor comprises an optical power detector and the sensor signal indicates an optical power output by the optical device.

Example 19. The optical system of Example 18, wherein the sensor signal indicates a stability of the optical power output by the optical device.

Example 20. The optical system of Example 18, wherein optical device further comprises a polarizer and the sensor signal indicates a polarization of light output by the optical device.

Example 21. The optical system of Example 16, wherein the sensor comprises a plurality of optical detectors and the sensor signal indicates a spatial optical intensity distribution in a light beam output by the optical device.

Example 22. The optical system of Example 21, wherein the sensor signal indicates a variation of spatial optical intensity distribution in the light beam output by the optical device.

Example 23. The optical system of Example 16, wherein the sensor and the optical device are enclosed in the common enclosure.

Example 24. The optical system of any one of the above Examples, wherein at least one individually controlled drive signal is constant.

Example 25. The optical system of any of Examples above, wherein a volume of the common enclosure in less than 500 cubic centimeter.

Example 26. The optical system of any one of the above Examples, wherein the electronic control system comprises one or more Application Specific Integrated Circuit (ASIC).

Example 27. The optical system of any one of the above Examples, wherein the optical device comprises a semiconductor optical amplifier.

Example 28. The optical system of any one of the above Examples, wherein the optical device comprises a semiconductor laser.

Example 29. The optical system of Example 28, wherein the optical device comprises a MOPA comprising the semiconductor laser extending from the first end to a third end and the optical amplifier extending from the third end to the second end.

Example 30. The optical system of any one of Examples 28-29, wherein the semiconductor laser comprises a pulsed laser and at least one of the drive currents is pulsed.

Example 31. The optical system of any one of Examples 28-29, wherein the optical device comprises a continues-wave (CW) laser and at least one of the drive currents is constant.

Example 32. The optical system of any one of Examples 28-31, wherein the active optical waveguide comprises an optical cavity formed by a front optical reflector and a back optical reflector, disposed with respect to each other.

Example 33. The optical system of any one of the above Examples, wherein the active optical waveguide comprises a non-flared region extending from the first end to a third end and a flared region and the waveguide width in the flared region increases from the third end to the second end.

Example 34. The optical system of any one of the above Example 28-32, wherein a total width of the segmented electrode increases the third end to the second end.

Example 35. The optical system of any one of the above Examples, wherein the optical device comprises an optical amplifier.

Example 36. The optical system of Example 35, wherein the active optical waveguide comprises a flared region and the waveguide width increases from the first end to the second end.

Example 37. The optical system of Example 35, wherein a total width of the segmented electrode increases from the first end to the second end.

Example 38. The optical system of Example 33, wherein the no-flared region does not provide optical gain.

Example 39. The optical system of any of Examples 1-32, wherein the active optical waveguide comprises a non-flared waveguide.

Example 40. The optical system of Example 39, wherein the active optical waveguide comprises a flared optically pumped region within the optical gain layer.

Example 41. The optical system of Examples 40, wherein the segmented electrode is configured to generate the flared optically pumped region by providing a flared distribution of drive currents to the optical gain layer.

Example 42. The optical system of any one of the above Examples, wherein the optical device further comprises a passive optical waveguide optically connected to the first end of the active optical waveguide.

Example 43. The optical system of any one of the above Examples, wherein the controlled distribution of drive currents comprises a non-uniform distribution along the longitudinal direction.

Example 44. The optical system of any one of the above Examples, wherein the controlled distribution of drive currents comprises a non-uniform distribution along the lateral direction.

Example 45. The optical system of Example 29, wherein the segmented electrode comprises a first electrode segment disposed on the semiconductor laser and a second electrode segment disposed on the optical amplifier, wherein the first and second electrode segments are electrically isolated and each receive one of the two different individually controlled drive signals.

Example 46. The optical system of Example 45, wherein the second electrode segment comprises a plurality of electrode segments.

Example 47. The optical system of Example 45, wherein the first electrode segment comprises a plurality of electrode segments.

Example 48. The optical system of any one of the above Examples, wherein at least two different electrode segments each receive one of the two different individually controlled drive signals.

Example 49. The optical system of any one of the above Examples, wherein at least two different electrode segments receive a single drive signal.

### Group 2B

Example 1. An optical system comprising:
an optical device configured to provide optical gain, the optical device comprising:
an active optical waveguide extending in a longitudinal direction between a first end and a second end, wherein said active waveguide comprises a semiconductor optical gain layer configured to provide optical gain to light propagating within said active optical waveguide, said active optical waveguide having a waveguide length along the longitudinal direction and a waveguide width along a lateral direction perpendicular to the longitudinal direction; and
a segmented electrode disposed with respect to the active optical waveguide said electrode comprising a plurality of separate electrically isolated electrode segments configured to provide individual drive currents to corresponding regions of the optical gain layer; and
an electronic control system configured to provide a plurality of individually controlled drive signals to different electrode segments to generate a controlled distribution of drive currents in the optical gain layer, and
wherein a magnitude of a first drive signal is above a first threshold level during a first period and a magnitude of a second drive signal is above a second threshold level during a second period after the first period.

Example 2. The optical system of Example 1, wherein the first and the second drive signals are provided to a first and a second electrode segments respectively, and wherein the electronic control system determines a delay between the first and the second periods based at least in part on a longitudinal distance between the first and the second electrode segments.

Example 3. The optical system of Example 1, wherein the controlled distribution of drive currents is configured to improve an efficiency of light generation or light amplification in the active optical waveguide compared to those of a second active optical waveguide driven by a single drive signal, wherein the second active optical waveguide and a second semiconductor optical gain layer therein are identical to the optical waveguide and the optical gain layer.

Example 4. The optical system of Example 1, wherein the controlled distribution of drive currents is configured to improve a stability of light generation or light amplification in the active optical waveguide compared to those of a second active optical waveguide driven by a single drive current, wherein the second active optical waveguide and a second semiconductor optical gain layer therein are identical to the optical waveguide and the optical gain layer.

Example 5. The optical system of Example 1, wherein the controlled distribution of drive currents is configured to improve a quality of a light beam generated or amplified by the active optical waveguide compared to that of a second light beam generated or amplified by a second active optical waveguide driven by a single drive current, wherein the second active optical waveguide and a second semiconductor optical gain layer therein are identical to the optical waveguide and the optical gain layer.

Example 6. The optical system of Example 4, wherein the stability of light generation or light amplification comprises at least one of:
a stability of a spatial optical intensity distribution in a light beam generated or amplified by the optical device;
a stability of optical power of light output by the optical device;
a stability of polarization of light output by the optical device; and
a stability of a spectrum of light output by the optical device.

Example 7. The optical system of Example 5, wherein improving the quality of the light comprises at least one of:
reducing a difference between a spatial optical intensity distribution of the light beam and a diffraction limited light beam;
reducing a level of astigmatism of the light beam; and
reducing a difference between a spatial optical intensity distribution of the light beam and a target spatial optical intensity distribution.

Example 8. The optical system of any one of above Examples, wherein the segmented electrode comprises at least two longitudinal segments and the electronic control system controls a longitudinal distribution of drive currents along the optical waveguide using the at least two longitudinal segments.

Example 9. The optical system of any one of above Examples, wherein the segmented electrode comprises at least two lateral segments and the electronic control system controls a lateral distribution of drive currents across the optical waveguide using the at least two lateral segments.

Example 10. The optical system of any one of the above Examples, wherein the electronic control system temporally changes the controlled distribution of optical gain by varying an individually controlled drive signal provide to an electrode segment.

Example 11. The optical system of Example 10, wherein at least two individually controlled drive signals comprise different temporal profiles.

Example 12. The optical system of anyone of the above Examples, wherein at least one of the drive signals is dynamically controlled.

Example 13. The optical system of anyone of the above Examples, wherein at least one of the drive signals is modulated.

Example 14. The optical system of Example 13, wherein at least one of the drive signals is modulated with a periodic wave form.

Example 15. The optical system of anyone of the above Examples, wherein the electronic control adaptively controls at least one of the drive signals using a sensor signal.

Example 16. The optical system of Example 15, wherein the optical system comprises a sensor that generates the sensor signal.

Example 17. The optical system of Example 16, wherein the sensor comprises a temperature sensor and the sensor signal indicates a temperature of the optical device or a surrounding medium.

Example 18. The optical system of Example 16, wherein the sensor comprises an optical power detector and the sensor signal indicates an optical power output by the optical device.

Example 19. The optical system of Example 18, wherein the sensor signal indicates a stability of the optical power output by the optical device.

Example 20. The optical system of Example 18, wherein optical device further comprises a polarizer and the sensor signal indicates a polarization of light output by the optical device.

Example 21. The optical system of Example 16, wherein the sensor comprises a plurality of optical detectors and the sensor signal indicates a spatial optical intensity distribution in a light beam output by the optical device.

Example 22. The optical system of Example 21, wherein the sensor signal indicates a variation of spatial optical intensity distribution in the light beam output by the optical device.

Example 23. The optical system of Example 16, wherein the sensor and the optical device are enclosed in a common enclosure.

Example 24. The optical system of any one of the above Examples, wherein at least one individually controlled drive signal is constant.

Example 25. The optical system of Example 23, wherein the electronic control system and the optical device are enclosed in a common enclosure.

Example 26. The optical system of any one of the above Examples, wherein the electronic control system comprises one or more Application Specific Integrated Circuit (ASIC).

Example 27. The optical system of any one of the above Examples, wherein the optical device comprises a semiconductor optical amplifier.

Example 28. The optical system of any one of the above Examples, wherein the optical device comprises a semiconductor laser.

Example 29. The optical system of Example 28, wherein the optical device comprises a MOPA comprising the semiconductor laser extending from the first end to a third end and the optical amplifier extending from the third end to the second end.

Example 30. The optical system of any one of Examples 28-29, wherein the semiconductor laser comprises a pulsed laser and at least one of the drive currents is pulsed.

Example 31. The optical system of any one of Examples 28-29, wherein the optical device comprises a continues-wave (CW) laser and at least one of the drive currents is constant.

Example 32. The optical system of any one of Examples 28-31, wherein the active optical waveguide comprises an optical cavity formed by a front optical reflector and a back optical reflector, disposed with respect to each other.

Example 33. The optical system of any one of the above Examples, wherein the active optical waveguide comprises a non-flared region extending from the first end to a third end and a flared region and the waveguide width in the flared region increases from the third end to the second end.

Example 34. The optical system of any one of the above Example 28-32, wherein a total width of the segmented electrode increases the third end to the second end.

Example 35. The optical system of any one of the above Examples, wherein the optical device comprises an optical amplifier.

Example 36. The optical system of Example 35, wherein the active optical waveguide comprises a flared region and the waveguide width increases from the first end to the second end.

Example 37. The optical system of Example 35, wherein a total width of the segmented electrode increases from the first end to the second end.

Example 38. The optical system of Example 33, wherein the no-flared region does not provide optical gain.

Example 39. The optical system of any of Examples 1-32, wherein the active optical waveguide comprises a non-flared waveguide.

Example 40. The optical system of Example 39, wherein the active optical waveguide comprises a flared optically pumped region within the optical gain layer.

Example 41. The optical system of Examples 40, wherein the segmented electrode is configured to generate the flared optically pumped region by providing a flared distribution of drive currents to the optical gain layer.

Example 42. The optical system of any one of the above Examples, wherein the optical device further comprises a passive optical waveguide optically connected to the first end of the active optical waveguide.

Example 43. The optical system of any one of the above Examples, wherein the controlled distribution of drive currents comprises a non-uniform distribution along the longitudinal direction.

Example 44. The optical system of any one of the above Examples, wherein the controlled distribution of drive currents comprises a non-uniform distribution along the lateral direction.

Example 45. The optical system of Example 2, wherein the first threshold level and second threshold levels can be threshold levels for generating drive currents sufficient for providing an optical gain larger than 1 in the corresponding regions of the gain layer below the first and the second electrode segments respectively.

Example 46. The optical system of Example 45, wherein the first threshold level is larger than the second threshold.

Example 47. The optical system of Example 29, wherein the segmented electrode comprises a first electrode segment disposed on the semiconductor laser and a second electrode segment disposed on the optical amplifier, wherein the first and second electrode segments are electrically isolated and each receive one of the two different individually controlled drive signals.

Example 48. The optical system of Example 47, wherein the second electrode segment comprises a plurality of electrode segments.

Example 49. The optical system of Example 47, wherein the first electrode segment comprises a plurality of electrode segments.

Example 50. The optical system of any one of the above Examples, wherein at least two different electrode segments each receive one of the two different individually controlled drive signals.

Example 51. The optical system of any one of the above Examples, wherein at least two different electrode segments receive a single drive signal.

### Group 2C

Example 1. An optical system comprising:
an optical device configured to provide optical gain, the optical device comprising:
an active optical waveguide extending in a longitudinal direction between a first end and a second end, wherein said active waveguide comprises a semiconductor optical gain layer configured to provide optical gain to light propagating within said active optical waveguide, said active optical waveguide having a waveguide length along the longitudinal direction and a waveguide width along a lateral direction perpendicular to the longitudinal direction; and
a segmented electrode disposed with respect to the active optical waveguide said electrode comprising a plurality of separate electrically isolated electrode segments configured to provide individual drive currents to corresponding regions of the optical gain layer; and
an application specific integrated circuit (ASIC) configured to provide a plurality of individually controlled drive signals to different electrode segments to generate a controlled distribution of drive currents in the optical gain layer.

Example 2. The optical system of Example 1, wherein controlled distribution of drive currents comprises a time varying distribution of drive currents.

Example 3. The optical system of Example 1, wherein the controlled distribution of drive currents is configured to improve an efficiency of light generation or light amplification in the active optical waveguide compared to those of a second active optical waveguide driven by a single drive signal, wherein the second active optical waveguide and a second semiconductor optical gain layer therein are identical to the optical waveguide and the optical gain layer.

Example 4. The optical system of Example 1, wherein the controlled distribution of drive currents is configured to improve a stability of light generation or light amplification in the active optical waveguide compared to those of a second active optical waveguide driven by a single drive current, wherein the second active optical waveguide and a second semiconductor optical gain layer therein are identical to the optical waveguide and the optical gain layer.

Example 5. The optical system of Example 1, wherein the controlled distribution of drive currents is configured to improve a quality of a light beam generated or amplified by the active optical waveguide compared to that of a second light beam generated or amplified by a second active optical waveguide driven by a single drive current, wherein the second active optical waveguide and a second semiconductor optical gain layer therein are identical to the optical waveguide and the optical gain layer.

Example 6. The optical system of Example 4, wherein the stability of light generation or light amplification comprises at least one of:
a stability of a spatial optical intensity distribution in a light beam generated or amplified by the optical device;
a stability of optical power of light output by the optical device;
a stability of polarization of light output by the optical device; and
a stability of a spectrum of light output by the optical device;

Example 7. The optical system of Example 5, wherein improving the quality of the light comprises at least one of:
reducing a difference between a spatial optical intensity distribution of the light beam and a diffraction limited light beam;
reducing a level of astigmatism of the light beam; and
reducing a difference between a spatial optical intensity distribution of the light beam and a target spatial optical intensity distribution.

Example 8. The optical system of any one of above Examples, wherein the segmented electrode comprises at least two longitudinal segments and the electronic control system controls a longitudinal distribution of drive currents along the optical waveguide using the at least two longitudinal segments.

Example 9. The optical system of any one of above Examples, wherein the segmented electrode comprises at least two lateral segments and the electronic control system controls a lateral distribution of drive currents across the optical waveguide using the at least two lateral segments.

Example 10. The optical system of any one of the above Examples, wherein the electronic control system temporally changes the controlled distribution of optical gain by varying an individually controlled drive signal provide to an electrode segment.

Example 11. The optical system of Example 10, wherein at least two individually controlled drive signals comprise different temporal profiles.

Example 12. The optical system of anyone of the above Examples, wherein at least one of the drive signals is dynamically controlled.

Example 13. The optical system of anyone of the above Examples, wherein at least one of the drive signals is modulated.

Example 14. The optical system of Example 13, wherein at least one of the drive signals is modulated with a periodic wave form.

Example 15. The optical system of anyone of the above Examples, wherein the electronic control adaptively controls at least one of the drive signals using a sensor signal.

Example 16. The optical system of Example 15, wherein the optical system comprises a sensor that generates the sensor signal.

Example 17. The optical system of Example 16, wherein the sensor comprises a temperature sensor and the sensor signal indicates a temperature of the optical device or a surrounding medium.

Example 18. The optical system of Example 16, wherein the sensor comprises an optical power detector and the sensor signal indicates an optical power output by the optical device.

Example 19. The optical system of Example 18, wherein the sensor signal indicates a stability of the optical power output by the optical device.

Example 20. The optical system of Example 18, wherein optical device further comprises a polarizer and the sensor signal indicates a polarization of light output by the optical device.

Example 21. The optical system of Example 16, wherein the sensor comprises a plurality of optical detectors and the sensor signal indicates a spatial optical intensity distribution in a light beam output by the optical device.

Example 22. The optical system of Example 21, wherein the sensor signal indicates a variation of spatial optical intensity distribution in the light beam output by the optical device.

Example 23. The optical system of Example 16, wherein the sensor and the optical device are enclosed in a common enclosure.

Example 24. The optical system of any one of the above Examples, wherein at least one individually controlled drive signal is constant.

Example 25. The optical system of Example 23, wherein the electronic control system and the optical device are enclosed in a common enclosure.

Example 26. The optical system of any one of the above Examples, wherein the electronic control system comprises at least a second ASIC.

Example 27. The optical system of any one of the above Examples, wherein the optical device comprises a semiconductor optical amplifier.

Example 28. The optical system of any one of the above Examples, wherein the optical device comprises a semiconductor laser.

Example 29. The optical system of Example 28, wherein the optical device comprises a MOPA comprising the semiconductor laser extending from the first end to a third end and the optical amplifier extending from the third end to the second end.

Example 30. The optical system of any one of Examples 28-29, wherein the semiconductor laser comprises a pulsed laser and at least one of the drive currents is pulsed.

Example 31. The optical system of any one of Examples 28-29, wherein the optical device comprises a continues-wave (CW) laser and at least one of the drive currents is constant.

Example 32. The optical system of any one of Examples 28-31, wherein the active optical waveguide comprises an optical cavity formed by a front optical reflector and a back optical reflector, disposed with respect to each other.

Example 33. The optical system of any one of the above Examples, wherein the active optical waveguide comprises a non-flared region extending from the first end to a third end and a flared region and the waveguide width in the flared region increases from the third end to the second end.

Example 34. The optical system of any one of the above Example 28-32, wherein a total width of the segmented electrode increases the third end to the second end.

Example 35. The optical system of any one of the above Examples, wherein the optical device comprises an optical amplifier.

Example 36. The optical system of Example 35, wherein the active optical waveguide comprises a flared region and the waveguide width increases from the first end to the second end.

Example 37. The optical system of Example 35, wherein a total width of the segmented electrode increases from the first end to the second end.

Example 38. The optical system of Example 33, wherein the no-flared region does not provide optical gain.

Example 39. The optical system of any of Examples 1-32, wherein the active optical waveguide comprises a non-flared waveguide.

Example 40. The optical system of Example 39, wherein the active optical waveguide comprises a flared optically pumped region within the optical gain layer.

Example 41. The optical system of Examples 40, wherein the segmented electrode is configured to generate the flared optically pumped region by providing a flared distribution of drive currents to the optical gain layer.

Example 42. The optical system of any one of the above Examples, wherein the optical device further comprises a passive optical waveguide optically connected to the first end of the active optical waveguide.

Example 43. The optical system of any one of the above Examples, wherein the controlled distribution of drive currents comprises a non-uniform distribution along the longitudinal direction.

Example 44. The optical system of any one of the above Examples, wherein the controlled distribution of drive currents comprises a non-uniform distribution along the lateral direction.

Example 45. The optical system of Example 29, wherein the segmented electrode comprises a first electrode segment disposed on the semiconductor laser and a second electrode segment disposed on the optical amplifier, wherein the first and second electrode segments are electrically isolated and each receive one of the two different individually controlled drive signals.

Example 46. The optical system of Example 45, wherein the second electrode segment comprises a plurality of electrode segments.

Example 47. The optical system of Example 45, wherein the first electrode segment comprises a plurality of electrode segments.

Example 48. The optical system of any one of the above Examples, wherein at least two different electrode segments each receive one of the two different individually controlled drive signals.

Example 49. The optical system of any one of the above Examples, wherein at least two different electrode segments receive a single drive signal.

Example 50. The optical system of any one of the above Examples, wherein at least two drive signals have different magnitudes or temporal profiles.

### Terminology

Conditional language, such as “can,” “could,” “might,” or “may,” unless specifically stated otherwise, or otherwise understood within the context as used, is generally intended to convey that certain embodiments, implementations, or examples include, while other embodiments, implementations, examples do not include, certain features, elements, and/or steps. Thus, such conditional language is not generally intended to imply that features, elements, and/or steps are in any way required for one or more embodiments.

Conjunctive language such as the phrase “at least one of X, Y, and Z,” unless specifically stated otherwise, is to be understood within the context used in general to convey that an item, term, etc. may be either X, Y, or Z. Thus, such conjunctive language is not generally intended to imply that certain embodiments require the presence of at least one of X, at least one of Y, and at least one of Z.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within ±10% of, within ±5% of, within ±2% of, within ±1% of, or within ±0.1% of the stated amount. As another example, the terms “generally parallel” and “substantially parallel” refer to a value, amount, or characteristic that departs from exactly parallel by ±10 degrees, by ±5 degrees, by ±2 degrees, by ±1 degree, or by ±0.1 degree, and the terms “generally perpendicular” and “substantially perpendicular” refer to a value, amount, or characteristic that departs from exactly perpendicular by ±10 degrees, by ±5 degrees, by ±2 degrees, by ±1 degree, or by ±0.1 degree.

Various configurations have been described above. Although this invention has been described with reference to these specific configurations, the descriptions are intended to be illustrative of the invention and are not intended to be limiting. Various modifications and applications may occur to those skilled in the art without departing from the true spirit and scope of the invention. Thus, for example, in any method or process disclosed herein, the acts or operations making up the method/process may be performed in any suitable sequence and are not necessarily limited to any particular disclosed sequence. Features or elements from various embodiments and examples discussed above may be combined with one another to produce alternative configurations compatible with embodiments disclosed herein. Various aspects and advantages of the embodiments have been described where appropriate. It is to be understood that not necessarily all such aspects or advantages may be achieved in accordance with any particular embodiment. Thus, for example, it should be recognized that the various embodiments may be carried out in a manner that achieves or optimizes one advantage or group of advantages as taught herein without necessarily achieving other aspects or advantages as may be taught or suggested herein.

What is claimed is:

1. An optical system comprising:
an optical device configured to provide optical gain, the optical device comprising:
an active optical waveguide extending in a longitudinal direction between a first end and a second end, wherein said active waveguide comprises a semiconductor optical gain layer configured to provide optical gain to light propagating within said active optical waveguide, said active optical waveguide having a waveguide length along the longitudinal direction and a waveguide width along a lateral direction perpendicular to the longitudinal direction; and
a segmented electrode disposed with respect to the active optical waveguide said electrode comprising a plurality of separate electrically isolated electrode segments configured to provide individual drive currents to corresponding regions of the semiconductor optical gain layer; and
an electronic control system configured to provide a plurality of individually controlled drive signals to different electrode segments to generate a controlled distribution of drive currents in the semiconductor optical gain layer, and
controlling a magnitude of a first drive signal provided to a first electrode segment to be above a first threshold level during a first period and a magnitude of a second drive signal provided to a second electrode segment to be above a second threshold level during a second period after the first period.

2. The optical system of claim 1, further comprising a common enclosure wherein the optical device and the electronic control system are included in the common enclosure.

3. The optical system of claim 1, wherein the electronic control system is further configured to determine a delay between the first and the second periods based at least in part on a longitudinal distance between the first and the second electrode segments.

4. The optical system of claim 1, the first threshold level and second threshold levels are threshold levels for generating drive currents for providing an optical gain larger than 1 in the first and second regions of the semiconductor optical gain layer, respectively.

5. The optical system of claim 1, wherein the controlled distribution of drive currents is configured to improve one or all of an efficiency, stability, or quality of light generation or light amplification in the active optical waveguide compared to those of a second active optical waveguide driven by a single drive signal, wherein the second active optical waveguide and a second semiconductor optical gain layer therein are identical to the active optical waveguide and the semiconductor optical gain layer.

6. The optical system of claim 5, wherein the stability of light generation or light amplification comprises at least one of:
a stability of a spatial optical intensity distribution in a light beam generated or amplified by the optical device;
a stability of optical power of light output by the optical device;
a stability of polarization of light output by the optical device; or
a stability of a spectrum of light output by the optical device.

7. The optical system of claim 5, wherein improving the quality of the light generation or light amplification comprises at least one of:
reducing a difference between a spatial optical intensity distribution of a light beam generated or amplified by the optical device and a diffraction limited light beam;
reducing a level of astigmatism of the light beam; or
reducing a difference between a spatial optical intensity distribution of the light beam and a target spatial optical intensity distribution.

8. The optical system of claim 1, wherein the segmented electrode comprises at least two longitudinal segments and the electronic control system controls a longitudinal distribution of drive currents along the active optical waveguide using the at least two longitudinal segments.

9. The optical system of claim 1, wherein the segmented electrode comprises at least two lateral segments and the electronic control system controls a lateral distribution of drive currents across the active optical waveguide using the at least two lateral segments.

10. The optical system of claim 1, wherein the electronic control system temporally changes the controlled distribution of optical gain by varying an individually controlled drive signal provide to an electrode segment.

11. The optical system of claim 9, wherein at least two individually controlled drive signals comprise different temporal profiles.

12. The optical system of claim 1, wherein at least one of the drive signals is dynamically controlled or is modulated.

13. The optical system of claim 1, wherein the electronic control system configured to adaptively control at least one of the drive signals using a sensor signal received from a sensor, the sensor signal indicative of:
a optical power output by the optical device,
a temperature of the optical device,
a temperature of a surrounding medium,
a polarization of light output by the optical device, or
a spatial optical intensity distribution in a light beam output by the optical device.

14. The optical system of claim 1, wherein the electronic control system comprises one or more Application Specific Integrated Circuit (ASIC).

15. The optical system of claim 1, wherein the optical device comprises a semiconductor optical amplifier.

16. The optical system of claim 1, wherein the optical device comprises a MOPA comprising a semiconductor laser extending from the first end to a third end and an optical amplifier extending from the third end to the second end.

17. The optical system of claim 1, wherein the controlled distribution of drive currents comprises a non-uniform distribution along the longitudinal direction.

18. The optical system of claim 1, wherein the controlled distribution of drive currents comprises a non-uniform distribution along the lateral direction.

19. The optical system of claim 16, wherein the segmented electrode comprises first and second electrode segments disposed on the semiconductor laser and third and fourth electrode segments disposed on the optical amplifier, wherein the first, second, third, and fourth electrode segments are electrically isolated and each receive an individually controlled drive signal.

20. A method of providing drive signals to an optical device configured to provide optical gain, the optical device comprising an active optical waveguide and a segmented electrode disposed with respect to the active optical waveguide, said segmented electrode comprising a plurality of separate electrically isolated electrode segments; the method comprising, by a processor of an electronic system:
providing a plurality of individually controlled drive signals to different electrode segments to generate a controlled distribution of drive currents in a semiconductor optical gain layer of the active optical waveguide, and
controlling a magnitude of a first drive signal provided to a first electrode segment to be above a first threshold level during a first period and a magnitude of a second drive signal provided to a second electrode segment to be above a second threshold level during a second period after the first period.
